(19) United States
(12) Patent Application Publication
(10) Pub. No.: US 2015/0028195 A1
(43) Pub. Date: Jan. 29, 2015

(54) Optical Apparatus And Method

(71) Applicants: Knowles Electronics, LLC, Itasca, IL (US); Optotune AG, Dietikon (CH)

(72) Inventors: Charles King, Oak Park, IL (US); Chauncey Graetzel, Stallikon (CH); Laurent Davoine, St. Louis (FR); Christopher Monti, Elgin, IL (US); Thomas Schmidhaeusler, Duernten (CH); MIchael Bueeler, Vogelsang AG (CH); Martin Salt, Adliswil (CH); Natalia Kukaleva, Zurich (CH); Peter Liebetraut, Dietikon (CH)

(21) Appl. No.: 14/339,523

(22) Filed: Jul. 24, 2014

Related U.S. Application Data
(60) Provisional application No. 61/858,706, filed on Jul. 26, 2013.

(51) Int. Cl. G02B 3/14; G02B 17/08; G02B 7/04; F04B 17/00; H01L 27/146; H01L 31/0232; F04B 17/03; G02B 3/12; B29D 11/00

(52) U.S. Cl. CPC G02B 3/14; G02B 3/12; G02B 17/08; G02B 7/04; B29D 11/0073; H01L 27/14625; H01L 27/14629; H01L 31/02325; F04B 17/03; F04B 17/003
USPC 250/216; 359/667; 359/726; 359/665; 359/355; 359/811; 359/666; 156/308.2; 156/309.3; 257/432; 417/410.1

(57) ABSTRACT

A deformable optical lens with a lens membrane having an optically active portion that is configured to be shaped over an air-membrane interface according to a spherical cap and Zernike polynomials is provided. The spherical cap and the Zernike polynomials comprise a Zernike[4,0], (Noll[11]) polynomial and are sufficient to model the deformable optical lens to within approximately 2 micrometers.

### CROSS REFERENCE TO RELATED APPLICATION

This application claims benefit under 35 U.S.C. §119 (e) to U.S. Provisional Application No. 61/858,706 entitled “Method and Apparatus Pertaining to a Deformable Optical Lens,” filed Jul. 26, 2013, the content of which is incorporated herein by reference in its entirety.

### TECHNICAL FIELD

This application relates to optical lenses including optical systems having selectively deformable optical lenses.

### BACKGROUND OF THE INVENTION

A lens is an optical device that transmits and refracts light to (typically) converge or diverge incoming light in a desired manner. Lenses are typically made of glass or transparent plastic. Many lenses are spherical lenses and hence have surfaces that are parts of the surfaces of spheres. Such surfaces can be convex (bulging outwards from the lens), concave (depressed into the lens), or planar (flat). Other lenses are aspheric lenses.

Devices such as cameras (including digital cameras) typically utilize one or more lenses to focus incoming light from a corresponding field of view onto an image-capture surface (such as film, an active pixel sensor (APS), and so forth) of choice. There are times when it can be advantageous to adjust one or more lens-based parameters of such an optical path. For example, it is known to physically axially move a lens (or groups of lenses) along the optical path in order to zoom in to or out from the subject and to focus the image on the image-capture surface.

Physical limitations that characterize the application setting do not always readily accommodate such movement, however. Lack of available space, friction, slip-stick, or issues with establishing initial lens alignment, or lens shape, for example, may prevent use of a traditional moving-lens zoom assembly. Further devices experience a broad range of environmental conditions and can be dropped causing high accelerations when impacting a hard surfaces.

### BRIEF DESCRIPTION OF THE DRAWINGS

For a more complete understanding of the disclosure, reference should be made to the following detailed description and accompanying drawings wherein:

FIG. 1 comprises a side-elevational block diagram schematic representation of a deformable optical lens assembly in accordance with various embodiments of the present invention;

FIG. 2 a top plan view of a deformable optical lens in accordance with in accordance with various embodiments of the present invention;

FIG. 3 is a view of a number of Zernike polynomial representations;

FIG. 4 is a side elevational schematic view in accordance with various embodiments of the present invention;

FIGS. 5-8 comprise various views pertaining to deformable optical lens, barrel details, lens shapers and alignment techniques in accordance with various embodiments of the present invention;

FIG. 9 comprises detailed views of the assembly shown in FIGS. 5-8 showing shape of cross section of lens shaper and pull back of the membrane in accordance with various embodiments of the present invention;

FIG. 10A is a description of a spherical cap and how the membrane applies to this in accordance with various embodiments of the present invention;

FIG. 10B is a graph showing the magnitude of a Zernike polynomial and its dependence on the deflection of the deformable lens in accordance with various embodiments of the present invention;

FIG. 10C is a diagram showing lens shaper attachment to the membrane and details of the lens shaper mechanics in accordance with various embodiments of the present invention;

FIGS. 10D and 10E are graphs showing aspects of membrane shape, the membrane shapes relation to a spherical cap, the changing coordinate system, in accordance with various embodiments of the present invention;

FIG. 10F is a schematic diagram of an edge based lens shaper in accordance with various embodiments of the present invention;

FIG. 10G is a schematic diagram of a surface based lens shaper in accordance with various embodiments of the present invention;

FIG. 10H is a schematic diagram of an apparatus that provides barometric relief in accordance with various embodiments of the present invention;

FIG. 11 is an external view of parts of an optical apparatus in accordance with various embodiments of the present invention;

FIG. 12 is cutaway view of the parts of a optical apparatus of FIG. 11 in accordance with various embodiments of the present invention;

FIG. 13 is a half section view of the parts of optical apparatus of FIG. 11 and FIG. 12 11 in accordance with various embodiments of the present invention;

FIGS. 14-16 comprise half section views of an optical apparatus showing optical elements and the membrane in various stages of deflection in accordance with various embodiments of the present invention;

FIG. 17A is a side view showing the optical path from the sensor to the object being imaged used herein in accordance with various embodiments of the present invention;

FIG. 17B is a side view of a reflective surface showing the θ angle and direction in accordance with various embodiments of the present invention;

FIG. 17C is a perspective view of a reflective surface showing the Φ angle and direction in accordance with various embodiments of the present invention;

FIG. 18 is a side view showing the coordinate system used herein in accordance with various embodiments of the present invention;

FIGS. 19 and 20 is a side view showing the coordinate system used herein with rays of light coming from the image and impacting the sensor in accordance with various embodiments of the present invention;

FIG. 21A is a side view of an optical apparatus showing deformable optical lens, sensor, and reflector, optical elements in accordance with various embodiments of the present invention;

FIG. 21B is a perspective view of a reflective surface pad contact points in accordance with various embodiments of the present invention;

FIG. 21C is a schematic view showing alignment mechanism in the in r-direction and the z-direction in accordance with various embodiments of the present invention;

FIG. 22A is diagram showing an example of a D-cut in accordance with various embodiments of the present invention;

FIG. 22B is an example of D-cuts used in an optical apparatus that are angularly offset from D-cuts in the barrel that hold the lens shaper, with features shown scaled to example physical parts in accordance with various embodiments of the present invention;

FIG. 22C is a diagram showing an example of the device of FIG. 22B, which has an angular offset shown to scale in accordance with various embodiments of the present invention;

FIG. 22D is a diagram showing another example of the device of FIG. 22B, which has an angular offset shown to scale in accordance with various embodiments of the present invention;

FIG. 22E is an example of offset between successive z axis contact points in accordance with various embodiments of the present invention;

FIG. 23 is a perspective cutaway view of an optical alignment structure according to various embodiments of the present invention;

FIG. 24 is a side cutaway view of an optical alignment structure according to various embodiments of the present invention;

FIG. 25 is a side cutaway view of an optical alignment structure according to various embodiments of the present invention;

FIG. 26 is an end view showing an optical apparatus according to various embodiments of the present invention;

FIG. 27 is a perspective cutaway view showing the apparatus of FIG. 26 according to various embodiments of the present invention;

FIG. 28 is a block diagram showing an optical apparatus according to various embodiments of the present invention;

FIG. 29 is a perspective view showing a camera module of FIG. 28 according to various embodiments of the present invention;

FIG. 30 are external side and top views showing the camera module of FIG. 29 according to various embodiments of the present invention;

FIGS. 31 and 32 is a side cutaway view showing the camera module of FIG. 30 highlighting fluid location according to various embodiments of the present invention;

FIG. 33 is a perspective cutaway view showing the camera module of FIG. 32 according to various embodiments of the present invention;

FIG. 34 is a perspective view of the camera module without its shield view showing the camera module of FIG. 33 according to various embodiments of the present invention;

FIG. 35 is a perspective view showing portions of the camera module of FIG. 34 according to various embodiments of the present invention;

FIG. 36 is a perspective view showing portions of the camera module of FIG. 34 according to various embodiments of the present invention;

FIG. 37 are views of the various fluid volumes according to various embodiments of the present invention;

FIG. 38 are views of the various fluid volumes according to various embodiments of the present invention;

FIG. 39 and FIG. 40 are force diagrams showing internally generated forces and reactions to these forces according to various embodiments of the present invention;

FIGS. 41-44 illustrate various optical topologies according to various embodiments of the present invention;

FIGS. 45-50 show examples of image stabilization achieved using the present approaches according to various embodiments of the present invention;

FIG. 51A and FIG. 51B show examples of image stabilization achieved using the present approaches according to various embodiments of the present invention;

FIGS. 52A-52E show splitting the optical housing into multiple portions according to various embodiments of the present invention;

FIGS. 53A-D show diagrams show an in-line optical apparatus according to various embodiments of the present invention;

FIGS. 54A-54N show various aspects of pumps and motor according to various aspects of the present invention;

FIG. 55 shows a block diagram of an optical system according to various embodiments of the present invention.

Skilled artisans will appreciate that elements in the figures are illustrated for simplicity and clarity. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION

One aspect to the functioning of imaging optics is that the lenses have a well-defined shape and that the lens is in the correct position and that this is maintained over the life of the product. The shape of a deformable optical lens is a function of the membranes material properties, how the membrane is mounted, how the system is treated in processing the parts to the final state and of course the pressure being applied to it. Modifying these processes as described herein can allow a user to obtain a desired shape and have this shape maintained over the life of the product.

The optical function of deformable optical lens system is determined at least in part by the shape of the flexible membrane at the air membrane interface, the properties of the optical fluid, the shape and optical properties of the fixed solid lens serving to contain the fluid. The approaches to control the deformable optical lens membrane/air shape described herein then further define this shape with a model so as to be usable within a complex optical system.

In some aspects, a deformable optical lens that is configured to have a shape that is to shapeable or modelable using a spherical cap and one or more Zernike polynomials is provided. More particularly the deformable optical lens is shapeable or modelable using only axisymmetric representations. By one approach the deformable optical lens is configured to be modelable using only a spherical cap and one or more axisymmetric Zernike polynomials.

The spherical cap is inherently an axisymmetric representation. Pursuant to the foregoing approach the Zernike polynomial(s) is (are) also an axisymmetric representation. Useful examples in these regards include Zernike [0,0], Zernike [2,0], Zernike [4,0] (Noll [11]), Zernike [6,0], Zernike [8,0], Zernike [2*n,0] (where n is an integer) and so forth.

By one approach, the deformable optical lens 101 is modeled using only such representations that are sufficient to model the deformable lens to within, for example, 2 microns of a true, measured physical form. In particular the optical model can define the Zernike [4,0] shape over the deflection range of the deformable optical lens.

In one particular example, a deformable optical lens configured to be modelable using a spherical cap and Zernike polynomials is provided. The spherical cap and the Zernike polynomials comprise a Zernike[4,0], (Noll[11]) polynomial and are sufficient to model the deformable optical lens to within approximately 2 micrometers. In another example, the Zernike polynomials further include a Zernike[0,0], (Noll[1]) polynomial. In another example, the Zernike polynomials further comprise a Zernike[2,0], (Noll[4]) polynomial. Other examples are possible.

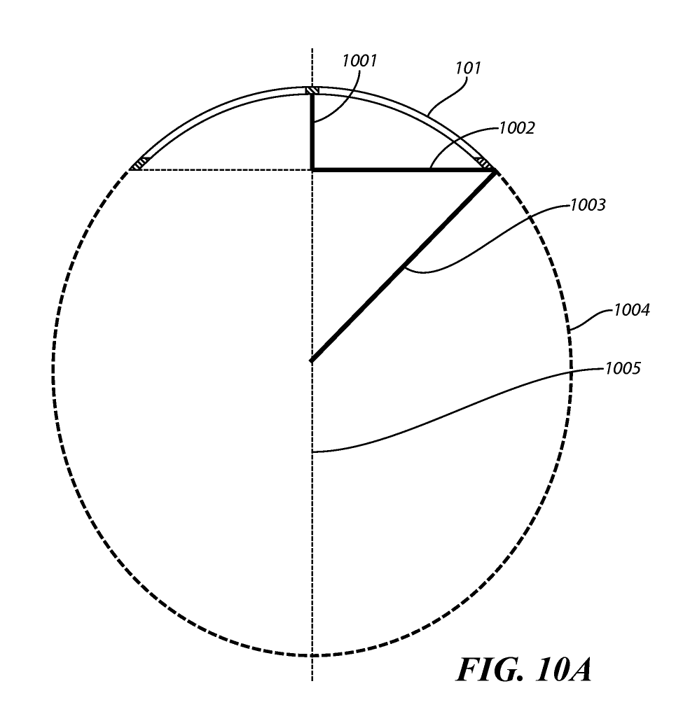

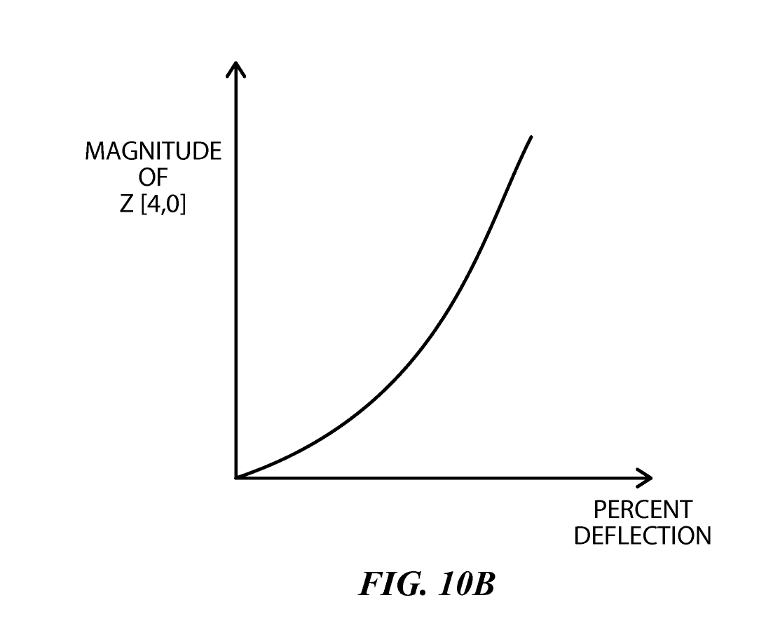

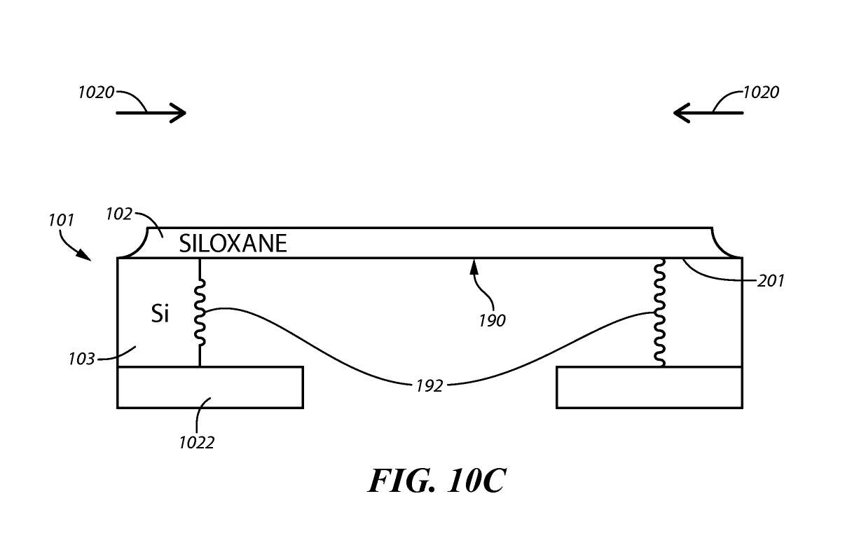

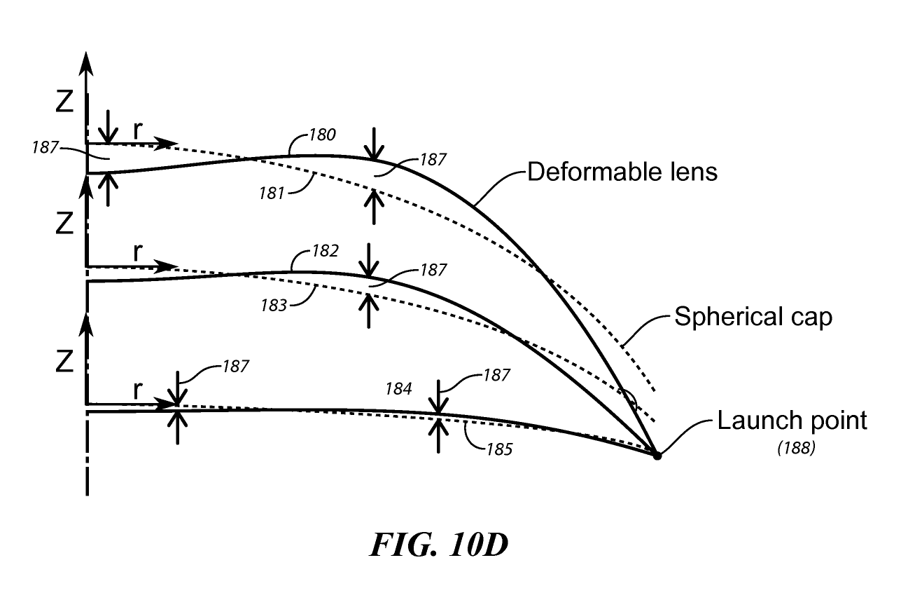

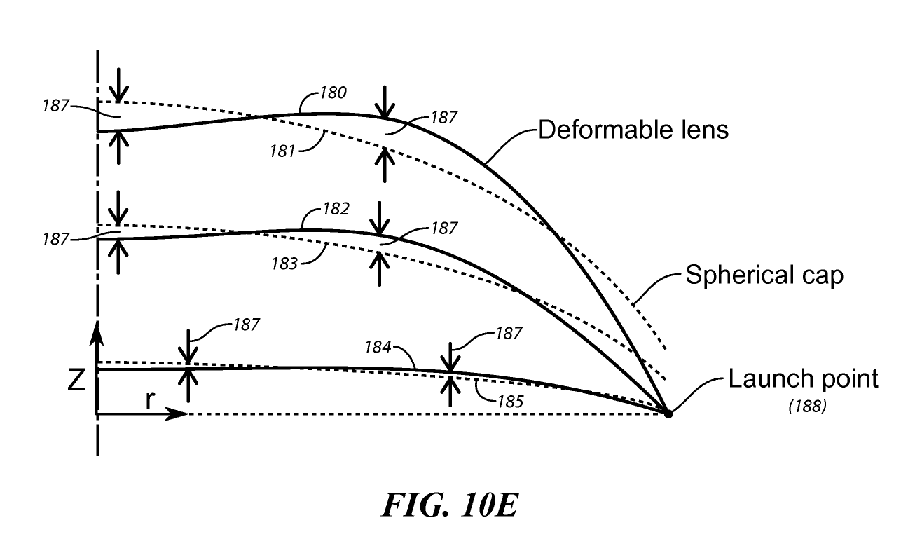

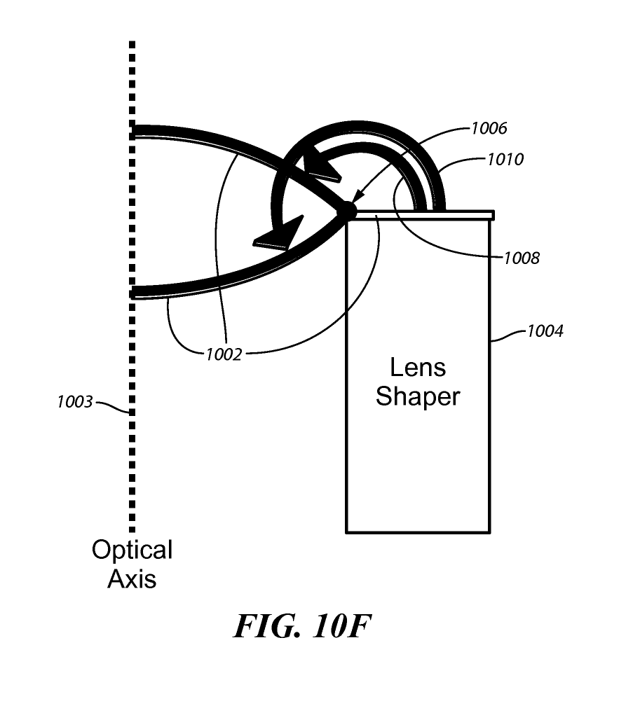

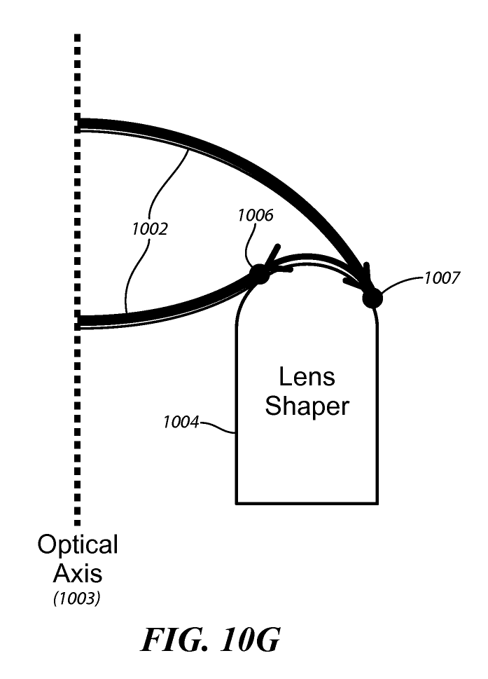

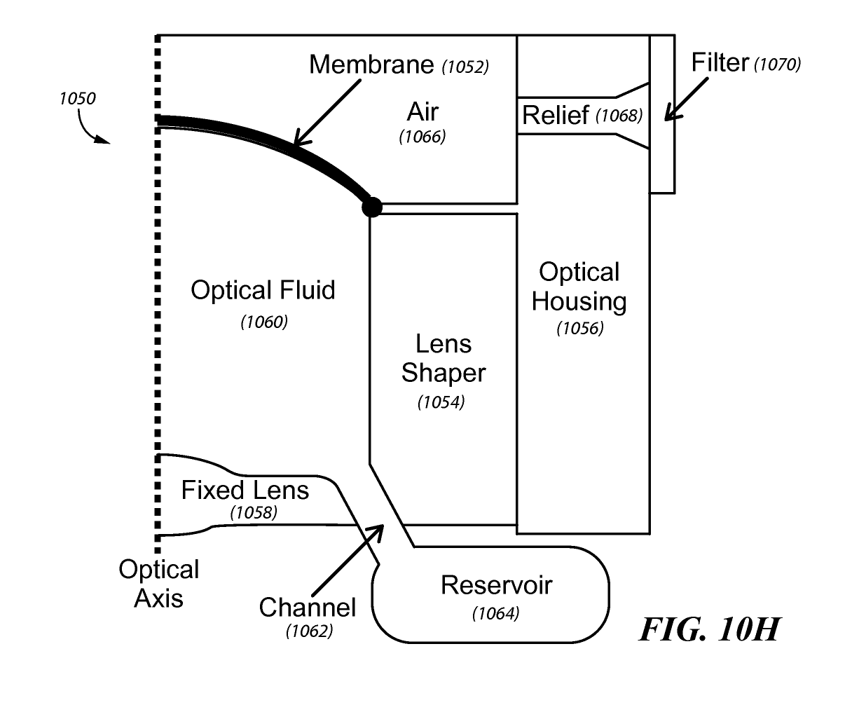

Making momentary reference to FIG. 10A, percent deflection is defined as the ratio of lens height 1001 (typically denoted as h and in-line with the optical axis 1005) to lens semi-diameter 1002 (typically denoted by a), multiplied by 100. The sphere 1004 will have a radius 1003 (typically denoted by R) of length R=(Â2+ĥ2)/(2 h). 0% deflection is therefore flat with a radius of the sphere equal to infinity, whilst 100% is when height h and semi-diameter A are equal. Observing this convention, a positive deflection number corresponds to a convex lens and a negative deflection corresponds to a concave lens.

The magnitude of the Zernike[4,0] coefficient generally increases as a function of percent deflection. Further, the magnitude is a function of the inner diameter of the lens shaper. Making momentary reference to FIG. 10B, it can be seen that the magnitude of the Zernike[4,0] coefficient (shown on the y-axis) generally increases as a function of percent deflection (shown on the x-axis).

In another example, a deformable optical lens configured to be modelable using a spherical cap and Zernike polynomials is provided. The magnitude of each of the Zernike polynomials depends upon a deflection of the deformable optical lens. In one other example, the spherical cap and the Zernike polynomials comprise a Zernike[4,0], (Noll[11]) polynomial and are sufficient to model the deformable optical lens to within approximately 2 micrometers. In another example, the magnitude of the Zernike[4,0], (Noll[11]) polynomial increases with the magnitude of percent deflection of the deformable optical lens. In another aspect, rate of increase of a magnitude of the Zernike[4,0], (Noll[11]) polynomial depends upon the lens diameter. For miniaturized designs, the lens would often have a lens diameter between the ranges of 1 mm to 10 mm. In yet another example, the magnitude of the Zernike[0], (Noll[1]) polynomial increases with the magnitude of percent deflection of the deformable optical lens and the rate of increase of the magnitude of the Zernike[4,0], (Noll[11]) polynomial depends upon the lens shaper edge diameter.

Such models are readily employed to design surrounding optics (such as one or more specific lenses) that will be suitably optimized for sending light to and receiving light from the deformable lens as per the shape at any given moment of the deformable optical lens.

Accordingly, by constraining the deformable optical lens to shapes that are modelable as described above, one or more lenses are more readily defined and designed to yield, in the aggregate, an optical pathway and lens assembly that can provide useful performance over a range of shapes for the deformable optical lens. For example, these teachings can be employed to yield an extremely small and relatively inexpensive zoom lens for a small camera capable of, but not limited to, focusing, 3× magnification as well as enhanced macro performance.

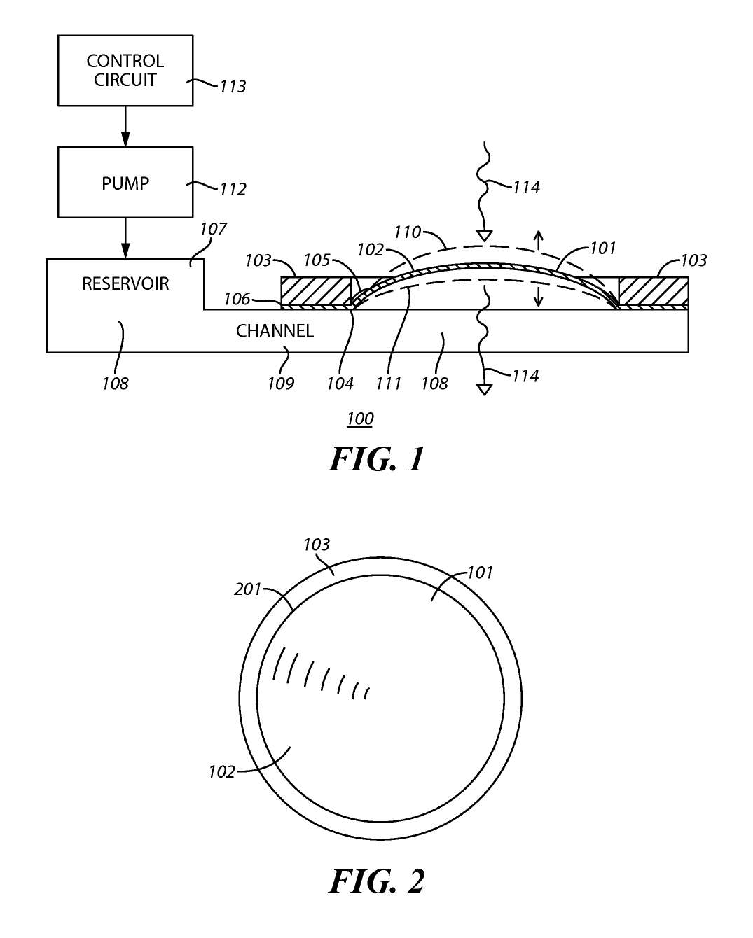

FIGS. 1 and 2 present a deformable optical lens assembly 100. A portion of a deformable optical lens 101 comprises a deformable lens membrane 102 that secures directly to a lens shaper 103 that comprises a circumferential frame to define the outer boundary of the deformable optical lens 101.

By one approach, the deformable lens membrane 102 comprises transparent siloxane and the lens shaper 103 comprises silicon. Various other materials may be used to construct these elements.

The lens shaper 103 could be constructed of metals, metalloids, metal and metalloid oxides and alloys. As examples for metal oxides and metalloid oxides TiO₂, CaTiO₃ and SiO₂ are given; GaIn, InGaAs, GaTe or GeTeSb and steel(s) are examples of alloys that can be used. Other examples of materials are possible.

By one approach lens shaper comprises silicon formed using modified semiconductor processes or other etching techniques. The lens shaper forms a silicon dioxide layer. This silicone dioxide layer then bonds directly to the siloxane membrane, i.e., in the absence of an adhesive or other attachment mechanism such as a clip, tack, or the like. Various other materials may be used to construct these elements.

Surface treatment can be employed to enhance bonding of the membrane to the shaper and extent the variety of materials used. Any material that forms an oxide layer that will bond directly to the membrane by activation. The aforementioned materials and other materials can be further exposed to a promoter, plasma, or other treatment and that will enhance the bond of the shaper directly to the membrane. In the case of a promoter, a very thin layer, possibly a monolayer of material will exist between the base shaper and the membrane, but this is not a glue with significant thickness.

The membrane may also be constructed of various materials such as a polyurethane, ethylene vinyl copolymer (EVAL), n-butylacrylates/PMMA copolymer, ethylene propylene diene copolymer (EPDM), styrene-butadiene copolymers, siloxane copolymer, grafted siloxane, or any other transparent or translucent flexible membrane. Other examples of materials are possible.

The siloxane material family is understood to include silicones (of which the siloxane functional group forms the so-called backbone). In addition, the material could include additives such as but not limited to SiO₂ filler, MQ-resin filler, transition metal oxide fillers (such as but not limited to TiO₂) and calcite compounds, as well as an adhesion promoter for hydrophilic surfaces. In one aspect, a siloxane membrane could have one side that is smoother than the opposite side. In this illustrative example the rougher side 104 faces away from the lens shaper 103 (and towards the optical fluid described below). Accordingly, the smoother side 105 of the siloxane membrane faces towards the lens shaper 103. In other examples, the sides have approximately the same level of smoothness.

In this example, the siloxane membrane is attached to a flat surface of the silicon lens shaper 103 and coextensively (having the same spatial or temporal scope or boundaries) therewith. In this particular illustrative the siloxane membrane attaches directly to a layer of silicon dioxide on the silicon lens shaper 103, i.e., in the absence of an adhesive or other attachment mechanism such as a clip, tack, or the like. For example, following a plasma exposure of one or both components the lens shaper 103 and the siloxane membrane are brought into intimate contact with one another at an elevated temperature (such as 60 to 200 degrees Centigrade) to create a siloxane-to-silicon dioxide bond that adheres the one component to the other.

It is also possible to initiate the bonding mechanism via other forms of surface preparation, such as exposure of either the membrane, or the lens shaper, substrate and/or aperture to an auxiliary chemical preparation. In all such cases the nature of the final bond is the same (and, in particular, “direct”) and no adhesive or other attachment mechanism is used or required.

It will be appreciated that in on aspect the bonding can be dominated by the surface roughness compared to the chemical composition. In one example, aluminum and siloxane films may be bonded when optimum parameters for the plasma (and the surface roughness which is inherently higher in aluminum) are used.

By one approach, the pre-tensioned membrane is held flat while the lens shaper 103 is brought into the aforementioned contact therewith. In a typical application setting the membrane will extend beyond the periphery of the lens shaper 103. By one approach the bottom corner/edge 106 of the lens shaper 103 is square and sharp enough such that the edge 106 can serve as a cutting tool to cleanly and precisely sever the membrane along that edge 106 (by pulling the membrane in opposition to that edge 106, for example). Cutting control and pretensioning of the membrane will cause the membrane to pull back 901 from the edge. Such an approach avoids leaving any of the membrane extending beyond the outer periphery of the lens shaper 103, improving the quality of the contact point 902 between the lens shaper 103 and the barrel 500 thereby making it easier to precisely yet easily dispose the completed deformable optical lens assembly 100 in a corresponding barrel as disclosed herein. This allows for better tolerance control of the siloxane/silicon assembly within the optical apparatus.

Making momentary reference to FIG. 10C, the deformable optical lens 101 comprises a deformable lens membrane 102 that secures directly to a lens shaper 103. The edge of the membrane has been cut and retracts along the lens shaper in the direction of the arrows labeled 1020. An aperture 1022 also is deployed as shown. In this embodiment, surface 190 is the surface at which there is an air siloxane interface and determines the shape of the lens and contributes greatly to optical performance. The surface 191 will be at the fluid membrane interface and have little impact on the optical function of the lens.

As noted above, the membrane can be directly attached to the lens shaper 103. Using such an approach helps ensure that the optical portion of the membrane 102 is “launched” from the precise, well-defined lens shaper edge 201 (as denoted in FIGS. 2 and 1006 in FIG. 10F), rather than from some variable glue surface or clamp. This in turn helps ensure axial symmetry for the deformable optical lens 101 and valid modelability of the resultant lens as per these teachings and particularly as the lens deforms as designed. By controlling the manufacturing process, the surface on the inside edge of the shaper 103 can be produced with scalloping 192 in such a way as to reduce image degradation caused by stray light. Roughening or matt blackening may also be used. Other approaches are possible. In one aspect, when creating any of these effects one must be certain not to effect the quality of the well-defined lens shaper edge 201. The well-defined lens shaper edge 201 is between approximately 1.0 and 10 mm in diameter in some examples.

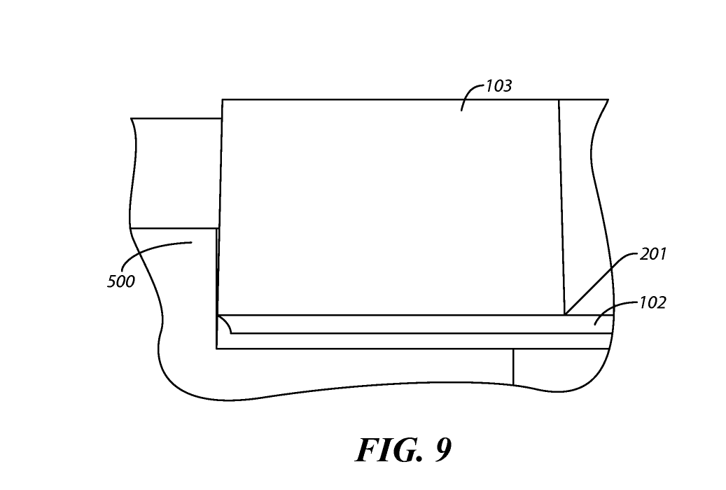

Direct attachment of the membrane 102 to the lens shaper 103 while maintaining the quality of the mating surfaces also helps to ensure dimensions with respect to the position of the lens shaper and attached membrane relative other components of the overall assembly. Piston, tilt, decenter, and randomized edge errors created by irregular gluing, clamping, or membrane cutting processes are avoided, thus ensuring that alignment precision with respect to other optical elements is dictated mainly by the precision of the lens shaper 103 and the membrane 102. FIG. 8 depicts the above-described deformable optical lens 101 proximal to but not yet installed in the barrel 500. And FIG. 9 depicts certain details as regards the deformable optical lens 101 when installed in the barrel 500.

The deformable optical lens assembly 100 includes a reservoir 107. This reservoir 107 is hydraulically coupled with the fluid 108 to the lens 101 via one or more channels 109. So configured, the optical fluid 108 can be urged into the lens 101 to thereby outwardly-deform the aforementioned membrane (as represented by the phantom line denoted by reference numeral 110) or can be urged back towards the reservoir 107 to thereby inwardly deform the membrane (as represented by the phantom line denoted by reference numeral 111). A pump 112 that operably couples to the reservoir 107 can control this movement of the optical fluid 108 and a control circuit 113 of choice can, in turn, control the pump 112. In many implementations the movement of the lens 101 can be such that the shape of phantom line 111 can change from convex to concave. This process is reversible and repeatable. The rest position of the lens 101 can be tuned from convex, to flat, to concave by adjusting the volume of the optical fluid in the system. Tuning of this volume to change the initial state of the lens serves to maximize the efficiency of the pump 112. One can also choose to overfill the system such that the lens and reservoir are pressurized when the system is powered off, and this will keep the lens curvature in a convex state. Large overfills of the system can be used so that only single direction actuators and drive circuits are required even though the lens may move from convex to concave.

The deformable membrane 102 and the optical fluid 108 can have a range of indices of refraction. The deformable membrane 102, for example, can have an index of refraction of about 1.35 to about 1.65 (such as, for example, 1.4). The optical fluid 108 can have an index of refraction of about 1.25 to about 1.75 (such as, for example, 1.3). Dispersions could be added as a new class of fluids, especially with high RI. By mixing an optical fluid and adding sub-wavelength sized components with different optical properties you can create a dispersion fluid. By using a dispersion the refractive index of the fluid can be modified and increased to values as high as 1.95. Abbe number of the dispersion fluid can also be modified in this approach. The solvents for these dispersions can also be perfluoroethers or siloxanes. Additionally, the fluids could be synthesized. Other examples of fluids are possible. By one membrane/fluid approach, a difference of 0.1 or less is preferred for the index of refraction as between these two lens components. With the rougher side of the membrane having contact with the optical fluid 108, there will be a negligible impact on the optical performance. The optical fluid 108 can comprise any of a variety of materials. For many application settings perfluoropolyethers or perfluorocarbons or partially fluorinated ethers or hydrocarbons will serve well in these regards. In one aspect, any fluid can be used as long as the vapor pressure is next to zero and the fluid will not swell the membrane.

So configured, light 114 passing through the deformable optical lens assembly 100 can be refracted in various selective ways by selective control of the amount of optical fluid 108 in the deformable optical lens 101 itself. That said, it may be expected that such a deformable optical lens assembly 100 will serve best in many application settings in conjunctive use with one or more other lenses.

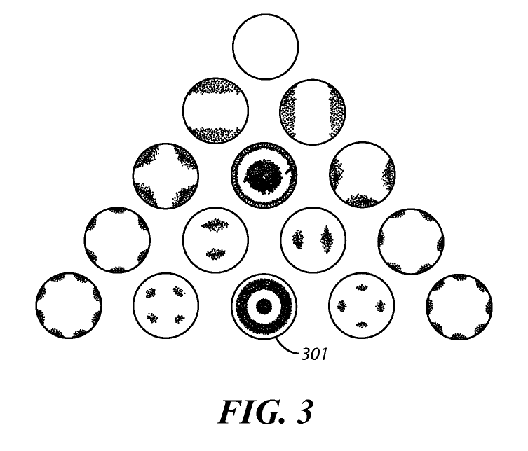

With that need in mind, these teachings support using the aforementioned spherical cap and axisymmetric Zernike polynomial of choice (or choices) to provide a model of the deformable optical lens 101 and then using that model to optimize the surrounding optical design to serve in combination with that deformable optical lens. As mentioned above, the axisymmetric Zernike polynomial can comprise polynomials represented as Zernike [4,0] as well as Noll [11] (denoted in FIG. 3 by reference numeral 301). As used herein, “axisymmetric” means to be symmetric about an axis and hence rotationally invariant. Viewed in perspective, this particular Zernike polynomial is somewhat reminiscent of a sombrero hat or, viewed from the side, as being somewhat reminiscent of an uppercase letter “M.”. While an “M” shape is the preferred embodiment it should be noted that the Zernike coefficients can be both positive and negative. It would be possible, for example, to have both “M” and “W” shapes in the general case. The material choices, pre-tensioning, and processing used to bond the membrane to the lens shaper will influence and help control the shape of the lens.

This axisymmetric Zernike polynomial in fact represents the deviation of the deformable optical lens 101 from the surface of a perfect spherical cap. Per these teachings one controls the sphere shape and the M shape by choice of the employed materials, conditioning processes, and the manner of joining the membrane to the lens shaper 103 to thereby minimize the variation of the M-shape from part to part. Accordingly, one can design the aforementioned optical model to define that M-shape over the expected deformation range of the deformable optical lens 101 and then design corresponding optics that take that optical model into account.

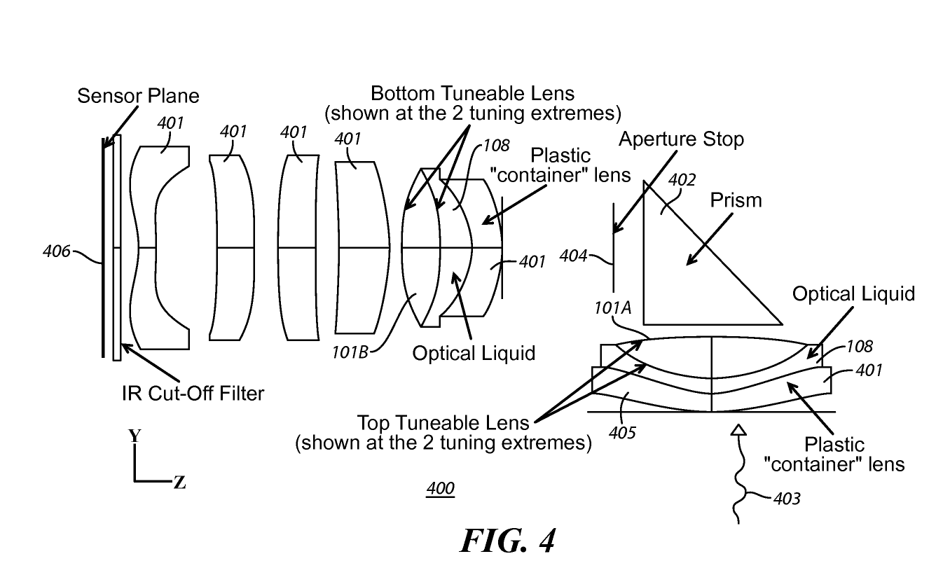

FIG. 4 presents an assembly 400 that employs two such deformable optical lenses 101 (101A and 101B) in combination with a plurality of other lenses 401 and a prism 402. This assembly 400 can serve as a small camera such as a camera disposed within a modern smart phone or pad/tablet-styled computer. Light 403 from a scene of interest enters the assembly 400 via a first container lens 405 and a first one of the deformable optical lenses 101A before entering a prism 402 that angles the light through a succeeding series of lenses that include the second deformable optical lens 101B before arriving at a sensor plane 406 that captures the corresponding image.

So configured, one or both of the deformable optical lenses 101A and 101B can be selectively deformed to provide an optical zoom, focus and macro capability to the assembly 400. It will be appreciated that this optical zoom capability does not require a lens to mechanically extend outwardly of the corresponding housing nor otherwise require the external dimensions of the assembly 400 to be variable in order to accommodate such a capability. Accordingly, such an assembly is very well suited to match the typical operating circumstances and limitations of devices such as smart phones and the like.

The precise form, size, and relative location of each lens 401 will of course vary with the specific needs of the corresponding application setting. That said, for many application settings it will serve well to have at least many of these lens 401 be at least aspheric if not bi-aspheric. Generally speaking, those skilled in the art will understand that such parameters are selected to provide a best image possible at the sensor plane 406. That said, and to reiterate a point made above, one or more of these lenses 401 can be designed to accommodate the range of lens shapes expected of the deformable optical lenses 101A and 101B using the aforementioned models. Since these models accurately represent the refractive behavior of these deformable optical lenses 101A and 101B in such regards, basing the size, form, and position of these other lenses 401 upon those models yields, over all, high quality image results over the operating magnification range of the overall assembly 400.

These various lenses 401 as well as the prism 402 can be formed of any suitable material including, for example, glass or plastic. By one approach the prism is configured to use total internal reflection to offer high reflectivity without a need for any reflective coating on the surfaces. Other reflective surfaces such as mirrors could also be used. These reflective surfaces can be actively moved or even be another adaptive surface.

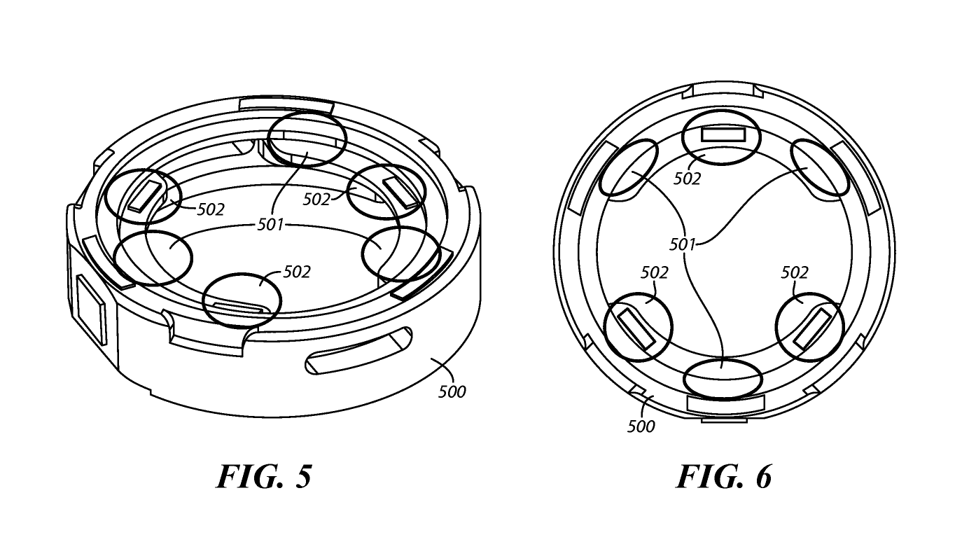

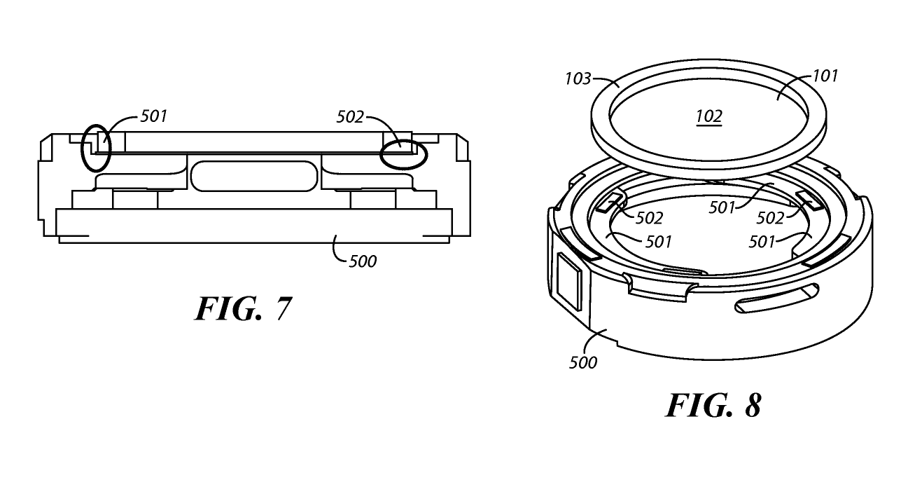

The deformable optical lenses described herein are preferably contained in barrels and the barrels disposed within an optical housing. FIGS. 5-9 provide various views pertaining to details pertaining to barrels that can serve well in these regards. FIGS. 5-7, for example present a barrel 500 having a three spaced radial centering D-cuts that are highlighted by corresponding ovals that are denoted by reference numeral 501. In this example the barrel 500 also includes three spaced tip/tilt and Z-axis positioning pads that are highlighted by corresponding ovals that are denoted by reference numeral 502.

These three pads effectively serve as a tripod to support the deformable lens shaper 103, which due to the precision of the assembly shown in FIG. 2 precisely positions the membrane 102 through its range of operation. In particular, the designer can effect later changes by making appropriate modifications to one or more of these pads. Somewhat similarly the D-cuts serve to center the lens 101 the sides where again downstream modifications make it considerably easier to achieve a perfect fit. In this illustrative example the pads do not vertically align with the D-cuts (side pads). So configured, the radius in the barrel mold never directly interacts with the lens 101 and hence fewer problems are experienced with respect to appropriately aligning and orienting the deformable optical lenses 101.

These teachings can be characterized in a variety of ways. In one aspect, a deformable optical lens is configured to be modelable using a spherical cap and Zernike polynomials.

In some aspects, a spherical cap and Zernike[4,0], (Noll[11]) polynomials are sufficient to model the deformable optical lens to within 2 micrometers. In other aspects, the two Zernike polynomials comprise axisymmetric Zernike polynomials. In still other aspects, the two Zernike polynomials comprise Noll's indices 1 and 11.

In other examples, a deformable optical lens subsystem includes a lens shaper and a deformable lens membrane. The membrane is directly attached to the lens shaper in the absence of an adhesive. In some aspects, the lens shaper is comprised of silicon and the deformable lens membrane is comprised of siloxane.

In other examples, a deformable optical lens configured to be modelable using two Zernike polynomials is provided. The two Zernike polynomials are used to provide a model of the deformable optical lens. The model of the deformable optical lens is used to configure at least a first fixed lens to serve in combination with the deformable optical lens. In other aspects, the model of the deformable optical lens is used to configure at least a second fixed lens to serve in combination with the first fixed lens.

In yet other examples, a deformable optical lens includes a deformable membrane having an index of refraction of about 1.4 and an optical fluid. The optical fluid at least partially contains by the deformable membrane and having an index of refraction of about 1.3. In some aspects, the optical fluid comprises perfluoropolyether.

In other examples, cleaning and surface preparation of both a lens shaper and a deformable lens membrane are accomplished. The deformable lens membrane is directly bonded to the lens shaper without use of third material such as adhesive. In some aspects, a smoother side of the deformable lens membrane is directly bonded to the lens shaper.

In still other examples, a multi-optical element assembly includes a first deformable optical lens, a second deformable optical lens, and a prism. The prism is disposed between the first and second deformable optical lenses.

In one aspect, at least two fixed lenses are disposed between the second deformable optical lens and an image sensor. In another aspect, the two fixed lenses comprise correction lenses are configured as a function of a model of at least one of the deformable optical lenses. In other aspects, the model characterizes the at least one deformable optical lens using two Zernike polynomials. In some examples, the two Zernike polynomials comprise axisymmetric Zernike polynomials. In some other examples, the two Zernike polynomials comprise Noll's indices 1 and 11.

It will be appreciated that the present approaches provide lens that are configured to be shaped according to or to conform to various mathematical representation, relationships, equations, and principles. One such representation is now described.

The following are used in this example description:

R=Radius of curvature,

r=radial position,

C=curvature c=1/R,

A=Semi-diameter of lens defined by the lens shaper edge. This is the launch point of the membrane,

r/A=normalized radial position,

Aref=Semi-diameter of reference lens aperture,

Z=sag of lens,

a1=piston term (Zernike 0 term),

a11=primary spherical aberration term,

p1-p7=curvature dependency terms of spherical aberration,

k1-k2=diameter dependency terms of spherical aberration,

The spherical component (C=1/R) to describe the membrane shape is:

$${Z}_{sphere} = \frac{{Cr}^{2}}{1 + \sqrt{1 - {C}^{2} {r}^{2}}}$$

The piston term (the Zernike 0 term) can be described as:

Zₚᵢₛₜₒₙ=a₁

And, the term representing primary spherical aberration is:

$${Z}_{SA} = {a}_{11} \cdot \sqrt{5} \cdot ( 6 \cdot {( \frac{r}{A} )}^{4} - 6 \cdot {( \frac{r}{A} )}^{2} + 1 )$$

Then, the deformable lens can be defined from its vertex as:

Z_{LensVertex}=Zₛₚₕₑᵣₑ(r,C)+Z_{SA}(r,a11,A)

Putting this together gives:

$${Z}_{LensVertex} = \frac{{Cr}^{2}}{1 + \sqrt{1 - {C}^{2} {r}^{2}}} + {a}_{11} \cdot \sqrt{5} \cdot ( 6 \cdot {( \frac{r}{A} )}^{4} - 6 \cdot {( \frac{r}{A} )}^{2} + 1 )$$

However, the lens vertex position of a spherical cap changes as the shape changes (i.e., tuning occurs). As shown in FIG. 10D, the shape of a membrane in a high state of deflection is represented by the curve labeled 180 and the corresponding spherical cap is labeled 181. The shape of a membrane in middle state of deflection is represented by the curve labeled 182 and the corresponding spherical cap is labeled 183. The shape of a membrane in a lowest shown state of deflection is represented by the curve labeled 184 and the corresponding spherical cap is labeled 185. By “spherical cap,” it is meant a sphere is cut completely across both sections are a spherical cap. It can be seen the vertex moves up and down the z-axis with movement of the membrane. For example, the vertex of the sphere is lower down the axis when the membrane is flatter, than when the membrane is more deflected.

Residual effects 187 are also present and are the difference between the position of the lens and the spherical cap curves. A launch point 188 represents the point from which deflection of the membrane occurs. In a two dimensional view this looks like a point, however those skilled in the art will recognize that this represents a circle in three dimensional space. In an edge based lens shaper, this point fixed and the circle has a constant radius. In a surface based lens shaper, the point can move and while still well defined will have a radius that is dependent on the deflection of the lens.

The equation above can be rewritten using the launch point as the Z reference. The graphs shown in FIG. 10E show this transformation and fit the Zernike terms to the residual. In this case, the sag at the launch point is simply subtracted from the vertex equation:

Z_{Lens}=Z_{LensVertex}(r)−Z_{LensVertex}(A)

The equation then becomes:

$${Z}_{Lens} = \frac{{Cr}^{2}}{1 + \sqrt{1 + {C}^{2} {r}^{2}}} - \frac{{CA}^{2}}{1 + \sqrt{1 - {C}^{2} {A}^{2}}} + {a}_{11} \cdot 6 \cdot \sqrt{5} \cdot ( {( \frac{r}{A} )}^{4} - {( \frac{r}{A} )}^{2} )$$

The third term in this equation corresponds to the sum of the piston and primary spherical aberration contributions, given that the piston term is chosen to be:

$${a}_{1} = - \sqrt{5} \cdot {a}_{11}$$

$$\underbrace{{a}_{11} \cdot \sqrt{5} \cdot ( 6 \cdot {( \frac{r}{A} )}^{4} - 6 \cdot {( \frac{r}{A} )}^{2} + 1 )}_{Spherical aberration contribution} \underbrace{- \sqrt{5} \cdot {a}_{11}}_{Piston contribution} = {a}_{11} \cdot 6 \cdot \sqrt{5} \cdot ( {( \frac{r}{A} )}^{4} - {( \frac{r}{A} )}^{2} )$$

The spherical aberration term all is not constant, but is rather dependent on deflection and aperture of lens:

a₁₁=f(C,A)

and the form of the dependency has been identified to be:

$${a}_{11} = \underbrace{( {p}_{1} \cdot C + {p}_{3} \cdot {C}^{3} + {p}_{5} \cdot {C}^{5} + {p}_{7} \cdot {C}^{7} )}_{Curvature dependency} \cdot \underbrace{( 1 + {k}_{1} \cdot ( A - {A}_{ref} ) + {k}_{2} \cdot {( A - {A}_{ref} )}^{2} )}_{Diameter dependency}$$

Referring now to FIG. 10F one example of an edge based lens shaper is described. A membrane 1002 is siloxane bonded to a silicon lens shaper 1004. As shown, an optical axis 1003 (e.g., the folded optical axis, the object axis, or the sensor axis described elsewhere herein) extends through the optical apparatus in which the membrane 1002 and lens shaper 1004 are disposed. A launch point 1006 is fixed and is the point from which the membrane 1002 launches. Although the point 1006 is fixed, a launch angle changes. For example, at one time a first launch angle 1008 exists. At a second time, a second launch angle 1010 exists. Other launch angles are possible.

Referring now to FIG. 10G, one example of a surface based lens shaper is described. A membrane 1002 is siloxane bonded to a silicon lens shaper 1004. As shown, an optical axis 1003 (e.g., the folded optical axis, the object axis, or the sensor axis described elsewhere herein) extends through the optical apparatus in which the membrane 1002 and lens shaper 1004 are disposed. A first launch point 1006 is the point from which the membrane 1002 launches at one point in time depending upon the deflection. A second launch point 1007 is the point from which the membrane 1002 launches at another point in time depending upon the membrane deflection. In contrast to the example of FIG. 10F, the launch angle remains fixed because the membrane is always normal to the lens shaper at the launch point. The lens shaper 1004 may be constructed/implemented by an approach that can create a smooth axisymmetric shape such as by molding, turning, or soft lithography.

Both systems, shown in FIG. 10B and FIG. 10C can be configured and controlled to produce the desired optical function.

Referring now to FIG. 10H, one example of an apparatus 1050 that provides barometric relief is described. The apparatus includes a membrane 1052, a lens shaper 1054, an optical housing 1056, and a fixed lens 1058. Optical fluid 1060 is exchanged with a reservoir 1064 via a channel 1062. Air 1066 is one side of the membrane 1052. A barometric relief channel 1068 extends through the optical housing 1056. A filter 1070 protects the interior of the optical apparatus 1050 from contaminants that might otherwise pass through the barometric relief channel 1068.

The air 1066 in one aspect is pumped out through the barometric relief channel 1068. In effect, the air reservoir is located outside the apparatus 1050. In this way, space is saved, less backpressure is present on the membrane and the nominal atmospheric pressure can be maintained within the module 1050.

FIG. 10H represents a schematic view of the system. In aspects, there is air in front of both the membranes within a 2 deformable lens system. The some examples, the system is configured so that both air chambers in front of the membrane will vent through the optical housing and through a single filter for both systems. This has the advantage of reducing costs and because the optical system is configured so that there is a tendency to have the membranes moving in opposite directions relative to the air it also shared filter will see less air flow than completely parallel systems would.

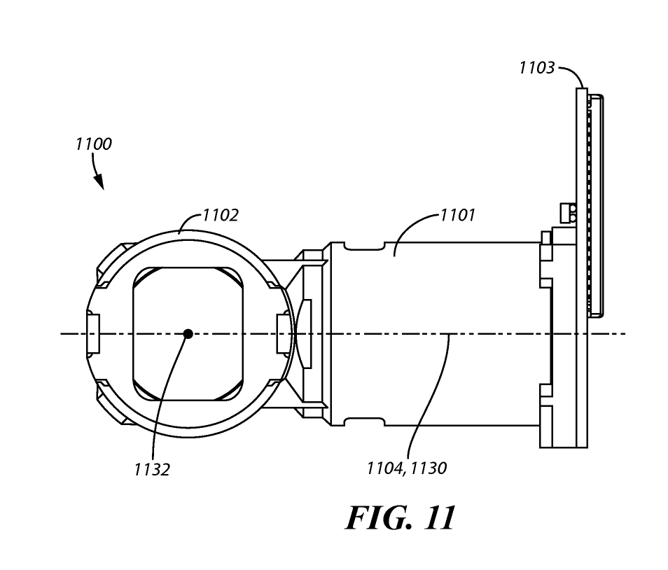

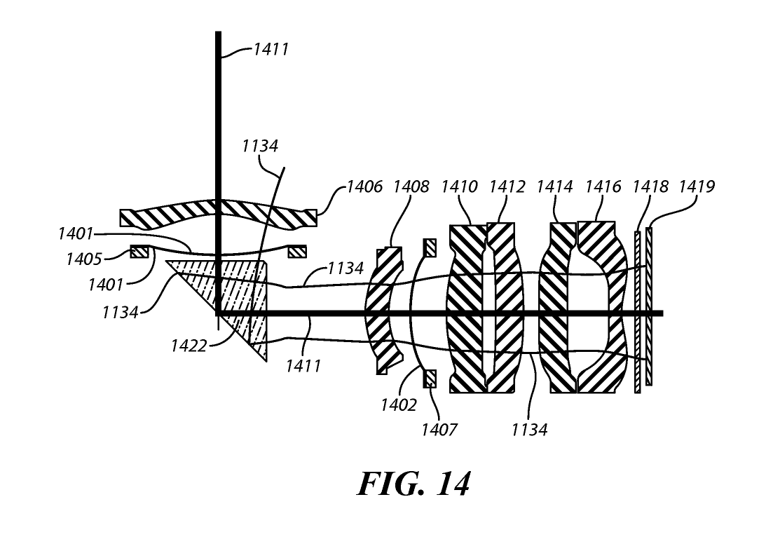

Referring now to FIGS. 11-16, one example of an optical apparatus is described. For clarity, FIGS. 11-13 show the path of light through the axis while FIGS. 14-16 show the optical components within the optical apparatus.

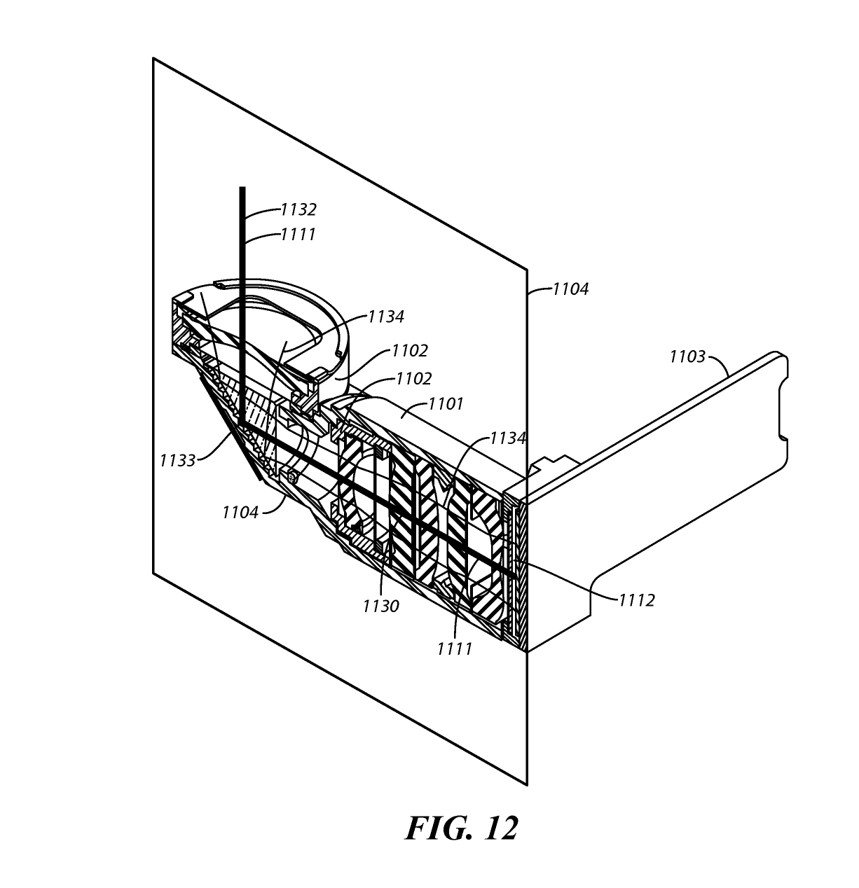

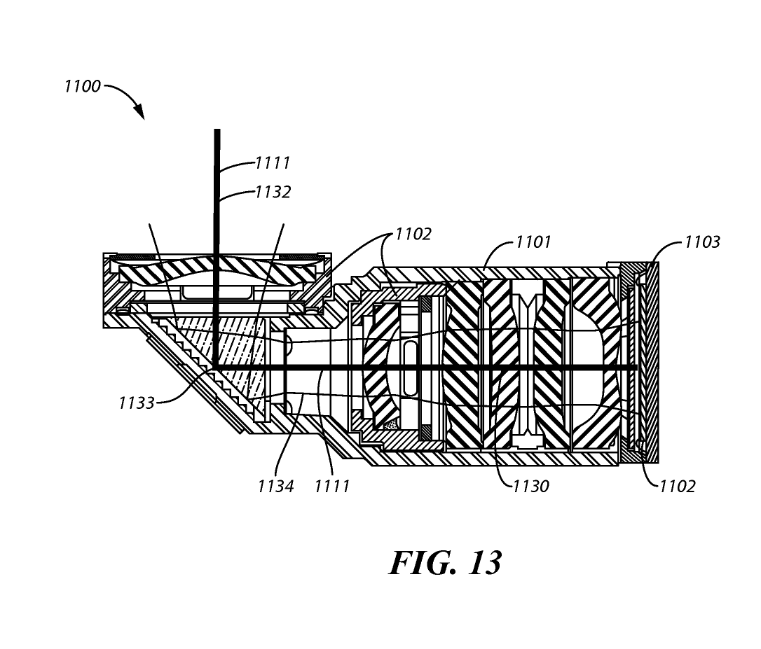

Referring now especially to FIG. 11, FIG. 12, and FIG. 13, an optical apparatus 1100 is described. The optical apparatus 1100 includes an optical housing 1101, a barrel 1102, and a circuit board 1103. A folded optical axis 1111 extends through the optical apparatus 1100 and, more specifically, through the optical elements in the optical apparatus 1100. The folded optical axis 1111 includes a sensor axis 1130 and an object axis 1132. The optical components are described in detail below with respect to FIGS. 14-16. Generally speaking, the barrel 1102 is a hollow cylindrical component and can be constructed of a material such as plastic. Other examples of materials are possible. Similarly, the optical housing 1101 is a hollow cylindrical component and can also be constructed of a material such as plastic. Although shown here as separate components, it will be understood that the optical housing 1101 and the barrel 1102 can be formed as a single, integrated component. Additionally, although one optical housing is shown here it will be appreciated that split optical housings can be used to hold other components.

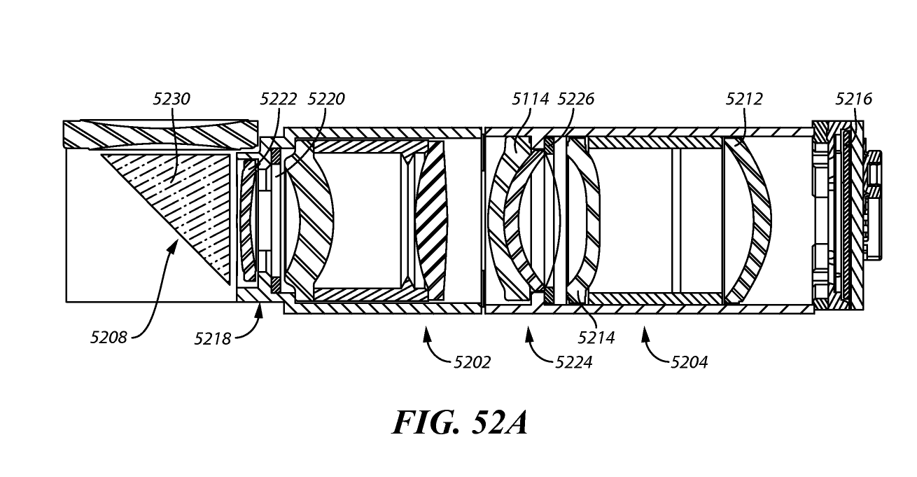

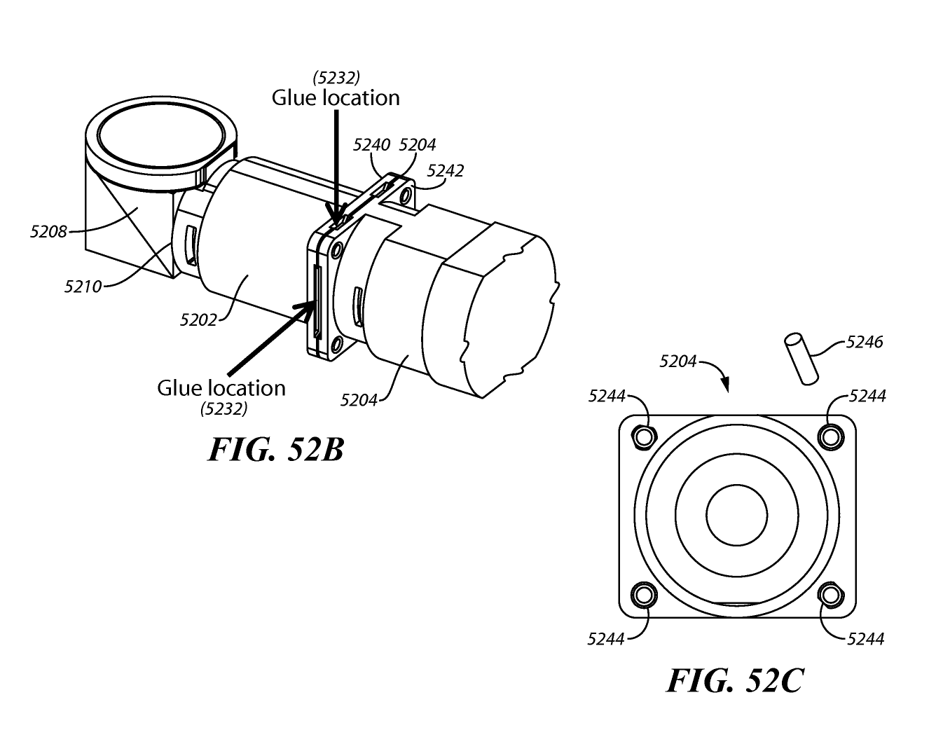

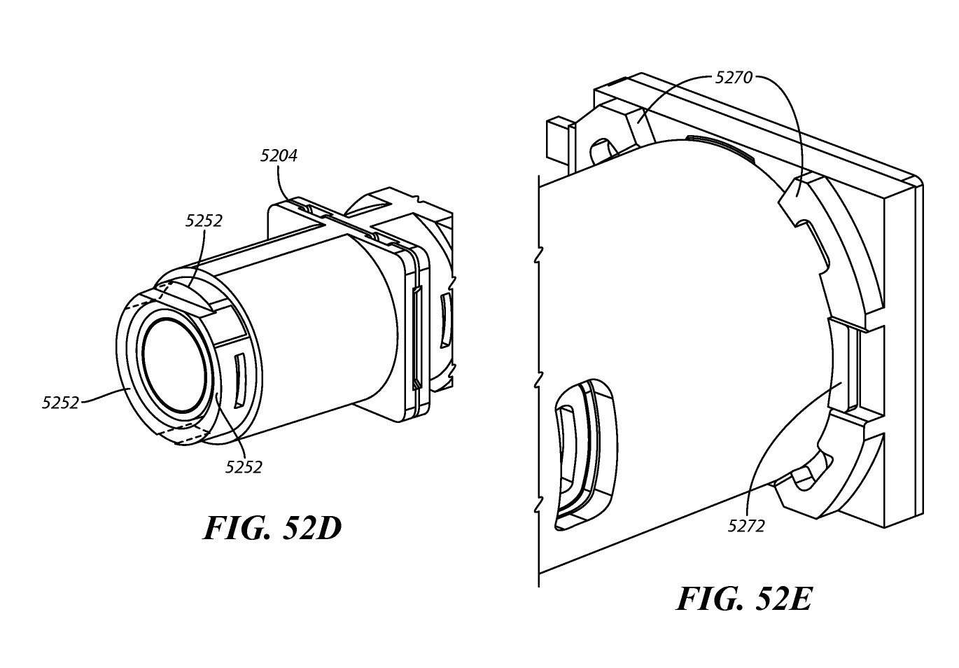

The optical housing and the barrel form at least part of an optical alignment structure, and the optical alignment structure is predominantly symmetric about a plane 1104. As shown, the plane 1104 extends through the object axis 1132 and the sensor axis 1130. The object axis 1132 and the sensor axis 1130 are non-parallel, are disposed in the plane 1104, and intersect at a single point 1133. The plane 1104 is the plane used to cut the assembly in FIGS. 4, 12, 13, 14, 15, 16, 19, 20, 21A, 21C, 51A, and 49, and, very similarly in FIG. 52A.

A sensor 1112 is coupled to the circuit board 1103. The sensor 1112 converts optical information from the sensed light into electrical signals. The sensor 1112 is disposed in a sensor housing that, in one example, is constructed of plastic. Other materials may also be used. The circuit board 1103 processes the electrical signals received from the sensor 1112. A sensor protector or glass cover (shown in FIGS. 14-16) may cover and protect the sensor. In one aspect, the sensor protector is an infrared filter. The circuit board 1103 may have a combination of electronic components performing a variety of processing functions. For example, processing functions may include image stabilization, image processing functions, and control functions for motors. Other examples of functions are possible. The circuit board 1103 may include thermal sensors, accelerometers, and interconnects to a pump (used to move fluid in and out of the deformable lenses). Other examples of components are possible. The cutting plane 1104 extends through the apparatus 1100. In these regards, FIG. 12 shows a cross-sectional view at the cutting plane 1104.

A ray bundle envelope 1134 is shown disposed within the apparatus 1100. The ray bundle envelop 1134 shows the extent of light that passes through the optical apparatus 1100 in the cutting plane 1132. This does not include all rays used to form the optical image, but does include the rays that define the outer diameter of those rays. In these regards, the ray bundle envelop 1134 has a surface that defines the outer most ray of light when considering all lens fields of view and all object distances. In other words, the ray bundle envelop 1134 is not a single ray of light, but is the outermost ray at any given location that is used to form an image. The ray bundling envelop 1134 defines an optically active portion or area of the membrane. That is, all portions of the membrane that contact the ray bundle envelop 1134 constitute the optically active part of the membrane. The membranes and other optical components of the system are now described. The shape of the ray bundle envelope 1134 is a function of lenses both fixed and variable, apertures, baffles and sensor geometry.

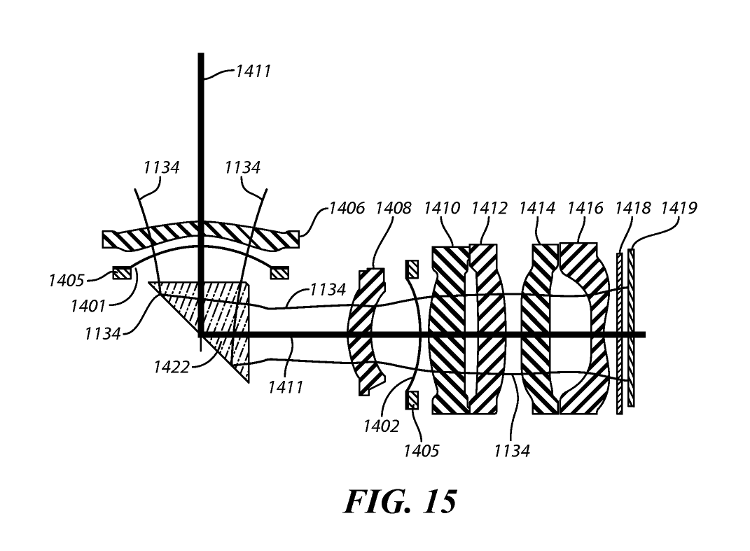

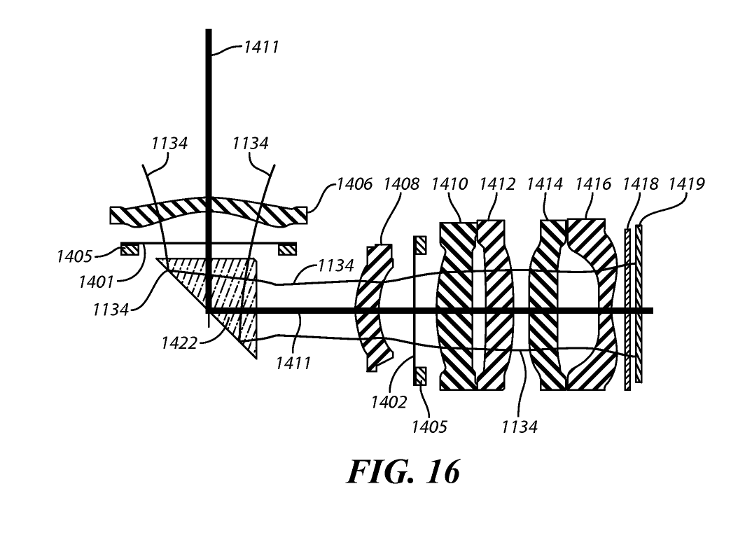

Referring now to FIG. 14, FIG. 15, and FIG. 16, one example of the optical elements of the optical apparatus of FIG. 11, FIG. 12, and FIG. 13, is described. The optical elements include a first membrane 1401, a second membrane 1402, a first lens shaper 1405, a second lens shaper 1407, a first fixed rigid lens 1406, a second fixed rigid lens 1408, a third fixed rigid lens 1410, a fourth fixed rigid lens 1412, a fifth fixed rigid lens 1414, a sixth fixed rigid lens 1416, sensor glass 1418, and a reflective surface 1422. The sensor glass 1418 covers and protects a sensor 1419. In some examples, the sensor glass 1418 includes an infrared filter.

The moving portions of the membranes 1401 and 1402 are delimited by an edge of a lens shaper (described elsewhere herein) and have an optical portion through which pass rays of light. In one example, the membranes 1401 and 1402 are constructed of siloxane. Other examples of materials are possible.

The first membrane 1401 and the second membrane 1402 are components of a first deformable optical lens and a second deformable optic lens, respectively. The second membrane 1402 is part of a second deformable optical lens. The ray bundle envelop 1134 includes rays of light from an incoming object image. As mentioned, the envelop 1134 is not a single ray and the outermost ray at any given location is used to form an image.

The image and light rays pass along the folded optical axis 1311 through the first fixed rigid lens 1406, through membrane 1401, are reflected by the reflective surface 1422, pass through the second fixed rigid lens 1408, through the second membrane 1402, and then pass sequentially through fixed rigid lenses 1410, 1412, 1414, 1416, through sensor glass 1418 and are then sensed by the sensor 1419. The other components of the deformable optical lenses will be described in greater detail below.

In other words and now also referring to FIG. 11, FIG. 12, and FIG. 13, an optical path is disposed within the optical housing and generally follows the folded optical axis. More specifically, the optical path follows the object axis 1132 from an object external to the apparatus to the reflective surface 1422. The optical path bends or is otherwise redirected at the reflective surface 1422 and then follows the sensor axis 1130 to the sensor 1419 at the end of the optical housing. The optical path passes through the various deformable optical lenses and the fixed lenses. The ray bundle envelop generally follows this path.

The optical housing 1101 is configured and arranged to align the deformable optical lenses (described in greater detail below) along the sensor axis 1130 and also align the deformable optical lenses in a direction that extends radially outward from the sensor axis 1130.

In some aspects, the optical housing 1101 has a multiplicity of contact points with the inner components of the device such as the lenses. In one example, three contact points between the optical housing 1101 are used to align radially each lens. When five lenses are used, 15 contact points (in one example) exist on the inside of optical housing 1101. Because a molded part of this complexity, particularly on that contains a reflective surface mounting feature, the natural axis of the optical housing 1101 will warp. For good optical performance the lenses must be optically aligned to the folded optical axis 1111. As such, the individual contact points are positioned such that when each lens is brought into contact with the contact points, each lens axis is aligned to be in line with the folded optical axis 1111. Alternately, eccentric mold pins could be used so that when the optical housing deforms the final alignment of the lens mating surfaces brings lenses into place. In other examples, multiple mold cavities could be made for each part and through a process of matching the lens could be brought into alignment with the folded optical axis 1111.

The fixed rigid lenses 1406, 1408, 1410, 1412, 1414, and 1416 are constructed of plastic, for example. Glasses and other materials may also be used. These lenses are solid and have shapes that do not change our time. Each of the fixed rigid lenses includes an optical portion and a mechanical portion. The mechanical portion includes a radial alignment surface and a first z-axis alignment surface. The z-axis is aligned along the folded axis. Mounting features to mount the fixed rigid lens to the optical housing or the barrel are also provided. The optical portion may be spherical or aspherical in shape. In one example, the Young's modulus will generally be greater than 1 Gpa. In another aspect, the refractive index range is from approximately 1.45 to 1.7. In still another aspect, the Abbe number is 15 and 65. Other values for these parameters may also be used.

The first deformable optical lens includes the first lens shaper 1405, the first membrane 1401, the fixed rigid lens 1406, and fluid between the first membrane 1401 and the fixed rigid lens 1406. In some aspects, the first deformable optical lens also includes and is delimited by the barrel (e.g., the barrel 1102).

The second deformable optical lens includes a second lens shaper 1407, the second membrane 1402, the fixed rigid lens 1408, and fluid between the second membrane 1402 and the fixed rigid lens 1408. In some aspects, the second deformable optical lens also includes and is delimited by the barrel (e.g., the barrel 1102).

The reflective surface 1422 reflects the incoming light rays of ray bundle envelop 1134, in one example at an approximately 90 degree angle. The reflective surface 1422 may be a prism, a mirror, or an adaptive element to mention a few examples.

The membranes 1401 and 1402 move depending upon the mode of operation of the optical apparatus. As shown in FIG. 14, the membranes 1401 and 1402 are shown in position that is indicative that the apparatus is in telephoto mode and focused at infinity. As shown in FIG. 15, membranes 1401 and 1402 are in position that is indicative the apparatus is in wide mode and focused at infinity. By “wide mode” it is meant the field of view is generally around 60 to 70 degrees. By “telephoto mode” it is meant the field of view is generally between 15 and 25 degrees. Larger values of zoom give smaller angles and wider angles give larger angles. Other values are possible. For reference, in FIG. 16, the membranes are shown in flat, unpressurized state.

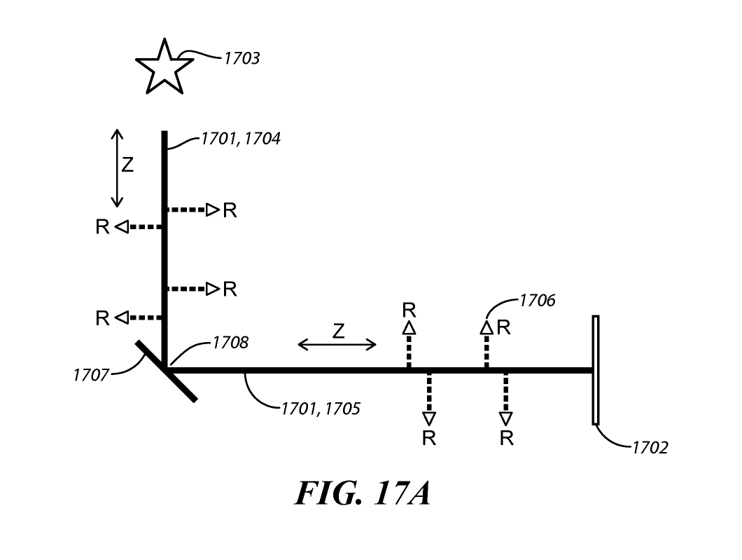

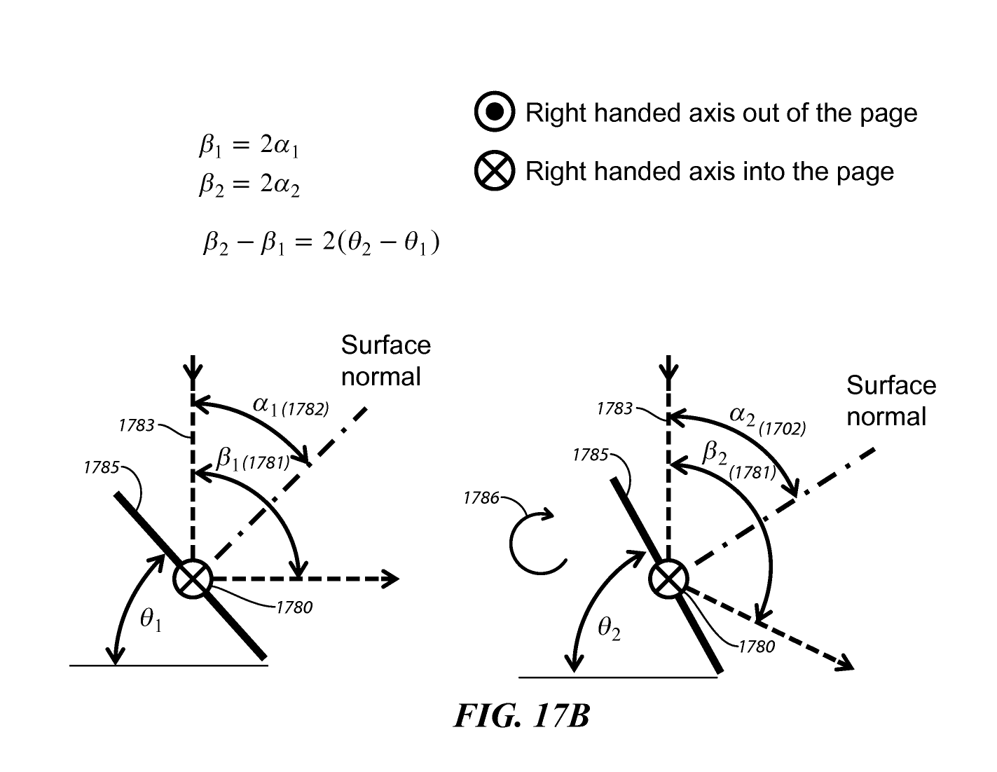

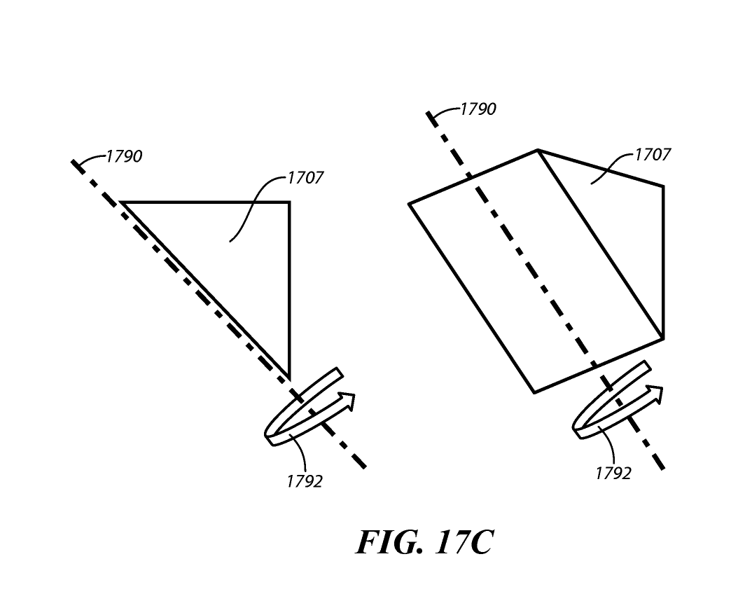

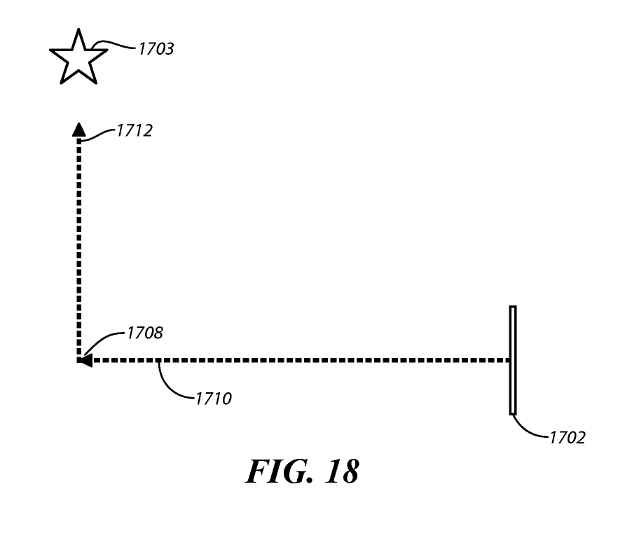

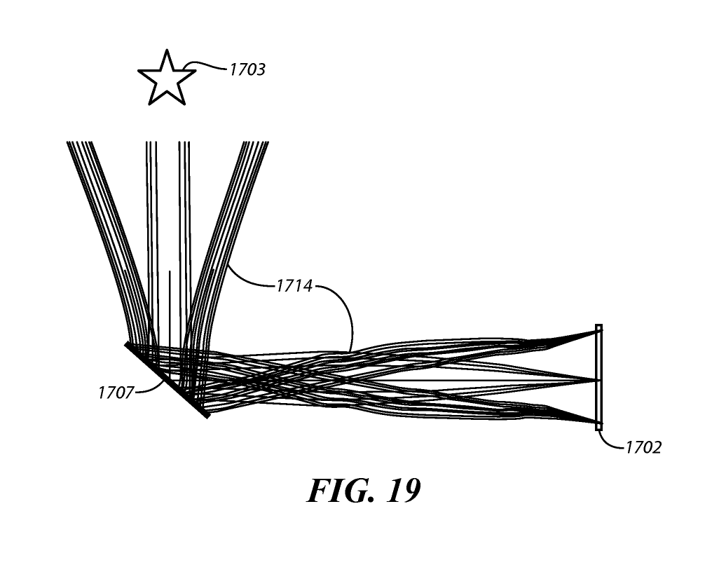

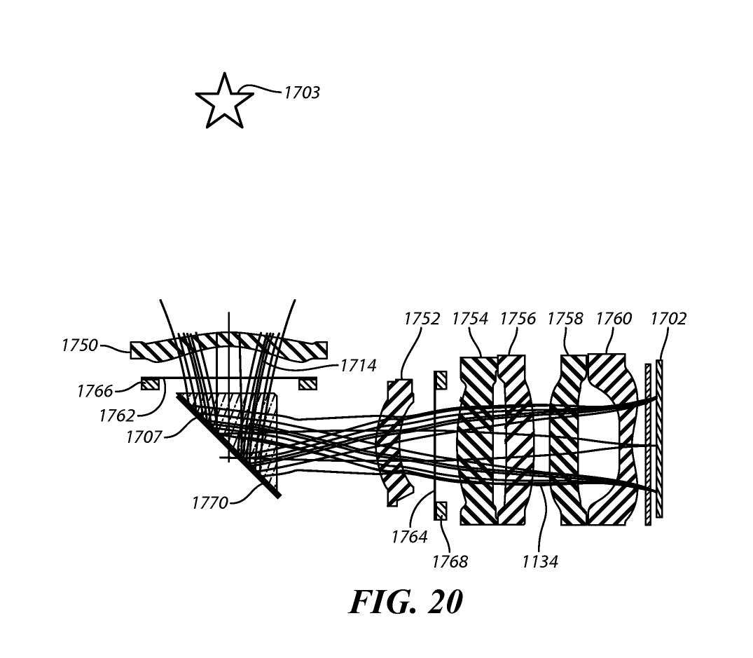

Referring now to FIG. 17A-C, FIG. 18, FIG. 19, and FIG. 20 examples of the coordinate system by the optical apparatus described herein are described. It will be understood that the coordinate system can be applied to any of the optical apparatus structures described herein and the relative positioning of the elements within this structure.

Rays of light extend from an object 1703. An object axis 1704 extends from the object 1703 and extends to a reflective surface 1707, in one example, a prism. A sensor axis 1705 extends from the reflective surface 1707 to the sensor 1702 and is at an approximately 90 degree angle to the object axis 1704. Together, the object axis 1704 and the sensor axis 1705 form the folded optical axis 1701. The fold 1708 is where the folded axis bends, and in one aspect is approximately 90 degrees. Other angles are possible. Radial direction vectors (R-direction) 1704 extend outwardly in a radial direction from the folded optical axis 1701.

As shown in FIG. 17A, Z-direction vector 1710 extends from the sensor 1702. Another Z-direction vector extends from the reflective surface to object 1703. The Z-direction is the direction of the folded optical axis while R-direction is the direction perpendicular to the folded optical axis.

Referring now to FIG. 19, ray bundle 1714 extends from the object 1703, to the reflective surface 1707, then to the sensor 1702. As shown in FIG. 20, the optical sensor and alignment elements are introduced. More specifically, a first fixed lens 1750, a second fixed lens 1752, a third fixed lens 1754, a fourth fixed lens 1756, a fifth fixed lens 1758, a sixth fixed lens 1760, a first membrane 1762, a second membrane 1764, a first lens shaper 1766, a second lens shaper 1768, and a reflective surface 1770 are shown. The ray bundle is a subset of all the rays used to form an image.

Referring now especially to FIG. 17B, movements of components in a direction are shown. A reflective surface 1707 has a pivot axis 1780 that extends out of the page. An angle of incidence 1782 (α1) is measured from an incoming ray 1783 and is relative to a vector that is normal to a surface 1785 of the reflective surface 1707. Angle 781 (β1) and θ1 are two times the angle of incidence. θ1 defines the angular separation between the sensor axis 1705 and the object axis 1704. In a first positioning, the angle of incidence 1782 is 45 degrees and θ is 90 degrees. However, the reflective surface 1707 can be rotated about the pivot axis 1780 in the direction indicated by the arrow labeled 1786. The angle of incidence 1702 increases to α2 thereby increasing θ to a second value, θ2. In this case, θ2 is increased to above 90 degrees. Angle 1781 (β2) and θ2 are two times the angle of incidence. Also, β2−β1=2(θ2−θ1). In other examples, the rotation is opposite to the direction of the arrow labeled 1786 and the angles decrease.

Referring now especially to FIG. 17C, movements of components in a Φ direction are shown. A Φ axis 1790 extends through the reflective surface 1707. The entire reflective surface 1707 can be rotated about the Φ axis 1790 in the direction indicated by the arrow labeled 1792.

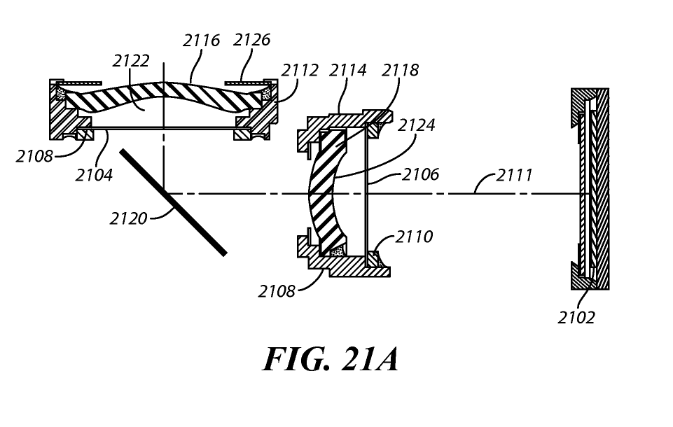

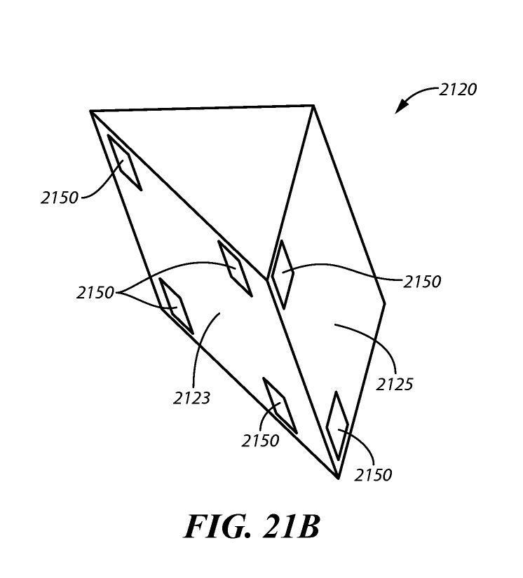

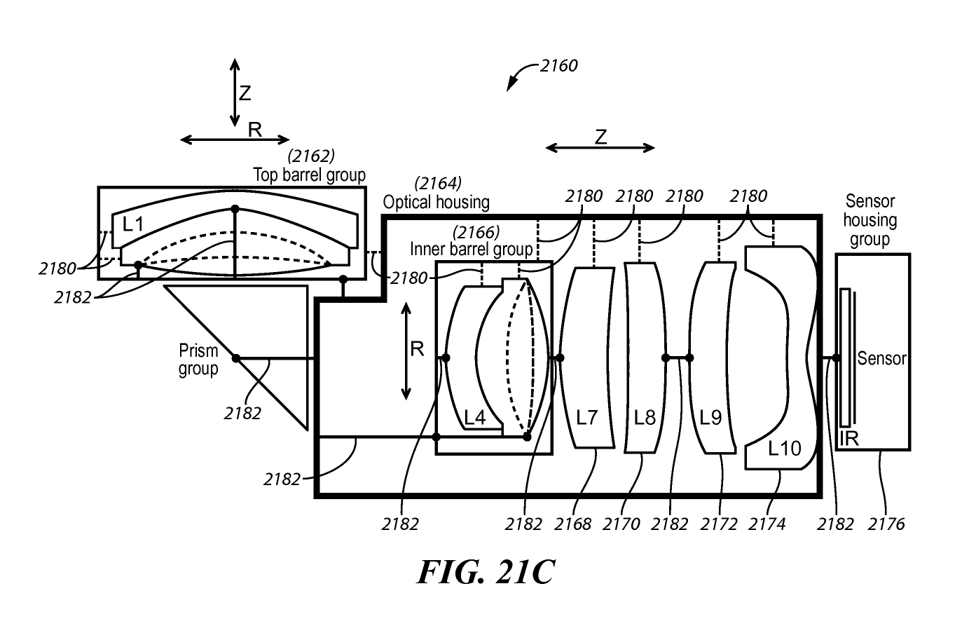

Referring now to FIG. 21A, the optical apparatus 2100 is described especially showing the deformable optical lenses and their operation. The apparatus 2100 includes a first (top) deformable optical lens 2126 and a second (bottom) deformable optical lens 2125.

The top deformable optical lens 2126 includes a first barrel 2112, a first lens shaper 2108, a first membrane 2104, a first rigid fixed lens 2116, and first optical fluid 2122.

The bottom deformable optical lens 2128 includes a second barrel 2114, a second lens shaper 2110, and a second membrane 2106, a second rigid fixed lens 2118, and second optical fluid 2124. An optical housing (not shown in FIG. 21A but shown in FIG. 21C) encloses these components. In other words, the deformable optical lenses reside in barrels that are themselves disposed in an optical housing. In some examples, the barrels are separate and distinct elements from the optical housing. In other examples, the barrels and optical housing are the same, contiguous, integrated element.

The membranes 2104 and 2106 are delimited by an edge of the lens shaper (by a lens shaper edge that has a diameter) and have an optically active portion through which pass rays of light. In one example, the membranes 2104 and 2106 are constructed of siloxane. Other examples of materials are possible.

The membranes 2104 and 2106 each form a membrane-air boundary on one side of the lens and a membrane-fluid boundary on another side of the lens. In one aspect, the membrane is smoother at the membrane-air boundary than at the membrane-fluid boundary so as to scatter light. The lens shapers 2108 and 2110 constructed of a non-plastic material and in some examples the non-plastic material is steel or silicon. Other examples of materials may also be used. The lens shapers 2108 and 2110 may include or be associated with an aperture (either fixed or variable/adjustable). Depending on the shape and material a variety of manufacturing processes may be used, semi-conductor style processing, grinding, molding growing may all be viable production techniques for the various forms of the material.

The fixed rigid lenses 2116 and 2118 are in contact with and help contain the fluid 2122 and 2124. The fixed rigid lenses 2116 and 2118 are constructed of plastic, for example. Other materials may also be used. The fixed rigid lenses 2116 and 2118 are solid and have shapes that do not change over time. Each of the fixed rigid lenses 2116 and 2118 include an optical portion and a mechanical portion. The mechanical portion includes a radial alignment surface and a first z-axis alignment surface. Mounting features to mount the fixed rigid lens to the optical housing or the barrel are also provided. The optical portion may be spherical or aspherical in shape. In one example, the Young's modulus will generally be greater than 1 Gpa. In another aspect, the refractive index range is from approximately 1.45 to 1.7. In still another aspect, the Abbe number is 15 and 65. Other values for these parameters may also be used.

As mentioned, the deformable optical portion includes the active optical portions of the deformable optical lens. The active optical portion includes the optical fluid and an optical “bucket.” And more specifically, the deformable optical portion includes the optically active portion of the membrane. This optically active portion of the membrane is delimited by the outer rays in a ray bundle envelope and is dependent upon state. Also included in the deformable optical portion is the optical fluid (that changes depending upon deflection). A portion of the fixed rigid lens (“the fixed rigid lens optical portion”) is also included in the deformable optical portion. The fixed rigid lens optical portion includes a first side of the fixed rigid lens (in contact with the fluid) and a second side of the fixed rigid lens (in contact with air). The fixed rigid lens optical portion is delimited by the outer rays in the ray bundle.

As described elsewhere herein, first optical fluid 2122 moves between a first reservoir and the first deformable optical lens 2126 via a first fluid channel. Similarly, second optical fluid 2124 moves between a second reservoir and the first deformable optical lens 2128 via a second fluid channel. The movement of fluid alters the shape of the corresponding membrane and thereby the optical properties of the lenses.

A sensor 2102 and a reflective surface 2120 are also included in the apparatus 2100. The reflective surface 2120 may be a prism, a mirror, or some other reflective deformable optical element. A folded optical axis 2111 extends from an object, and extends through the apparatus as shown.

The lens shapers 2108 and 2110 include a lens shaper edge (that contacts the corresponding membrane), a radial mounting feature (such as a D-cut on the barrel holding the lens shaper) and a z-axis mounting feature (such as pads). The lens shapers 2108 and 2110 may include an aperture and may also include one or more addition structures for scattering light. The function of the lens shapers 2108 and 2110 is to shape and position the corresponding membrane. These edges may also be considered launch points from which movement of the membrane launches or begins. It should also be noted that the edges need not be edges (static linear elements FIG. 10F), and could be surfaces (dynamic area element shown as FIG. 10G).

In one aspect, these approaches can be deployed in a camera module that includes an optical portion. The optical portion of the camera module includes an optical housing (e.g., optical housing 1101 of FIGS. 11-13) and at least one deformable lens (e.g., lenses 2126 or 2128). The deformable lens includes a lens shaper (e.g., lens shapers 2108 or 2110). The optical portion of the camera module also includes at least one fixed rigid lens (e.g., fixed rigid lens 2116 or 2118), a reflective surface (e.g., reflective surface 2120), and a first axis (sometimes described as the “object axis” herein) extending between an object external to the optical portion and the reflective surface, a second axis extending from the reflective surface and through the at least one deformable lens and the at least one fixed rigid lens to the sensor (sometimes described as a “sensor axis” herein). The first axis and the second axis are generally perpendicular to each other and together form the folded axis as described herein. Light incident from the object traverses a path according to the folded axis. The lens shaper and the fixed rigid lens are stationary and fixed with respect to the optical housing. The optical housing serves as a primary alignment device for alignment of these components.

In some aspects, the deformable lens and the reflective surface are directly supported by the optical housing without any intervening structure. In other examples, a barrel (e.g., the barrel 1102) is disposed in the optical housing and wherein the at least one deformable lens is coupled to the barrel. Adhesive may be used to secure the components in location. In some examples, the reflective surface comprises a prism or mirror. Other examples of reflective surfaces are possible.

As mentioned, the optical devices provided herein may also include various apertures and baffles. More specifically, these may include aperture stops, which are a main aperture and defines a ray bundle envelop circularly. In another example, a vigneting aperture is a square-cut aperture that defines a ray bundle envelope in a rectangular (or other) shape. Baffles, which stop stray light from reflecting within the structure may also be used. The baffles may be non-transparent (e.g., blackened) ring. Other examples of baffles are possible and other structures may also be used. Aligning these parts according to the optical design requirements is another function performed in part by the optical housing.

Referring now to FIG. 21B, one example of a reflective surface 2120 that has contact points 2150 is described. The contact points 2150 may be extrusions from the optical housing, glue spots, or other arrangements used to mount, secure, and/or align the reflective surface. In FIG. 21B, the reflective surface 2120 is a prism having a surface of reflection 2123 and an anti-reflective coated surface 2125 that allows light to pass through the prism. Surface 2123 may be coated like a mirror or may rely on total internal reflection to bend the light.

Referring now to FIG. 21C, an example of an optical apparatus 2160 is described that shows alignment in the R direction and the Z-direction. The optical apparatus 2160 includes a top barrel group 2162 (including a deformable optical lens), an optical housing 2164, an inner barrel group 2166 (including a deformable optical lens), fixed solid lenses 2168, 2170, 2172, and 2174, a sensor housing group 2176 (including a sensor), and a prism group 2178. The operation of these components has been described elsewhere herein.

Radial alignment features 2180 (e.g., D-cuts) align the various elements in the R-direction. Z-axis alignment features (e.g., pads) align the elements in the z-direction. In other words, use of radial alignment features 2180 and z-axis alignment features 2182 allows the positions of the various elements to be shifted, adjusted, or changed to optimize system performance and improve (optimize) image quality.

While D-cuts and pads are the preferred alignment features others are possible. Eccentric parts and shims, among other processes for alignment can be used. The optical housing and barrels within the optical housing are coupled together. The coupling arrangement aligns the various optical components in the barrel along an axis. If the components are not aligned, the apparatus will not function properly and image quality will be degraded

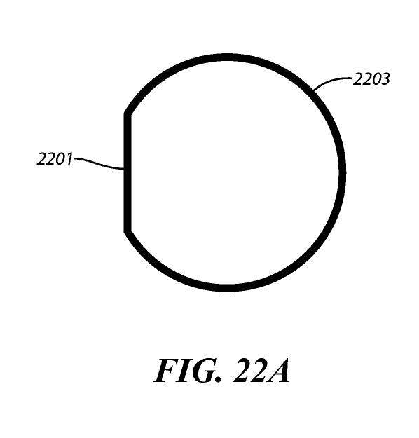

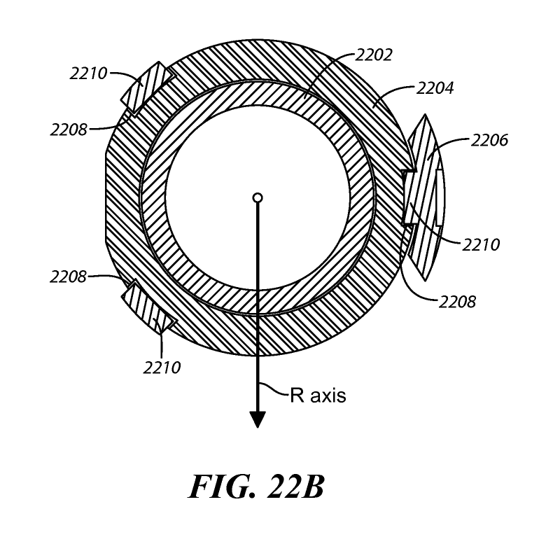

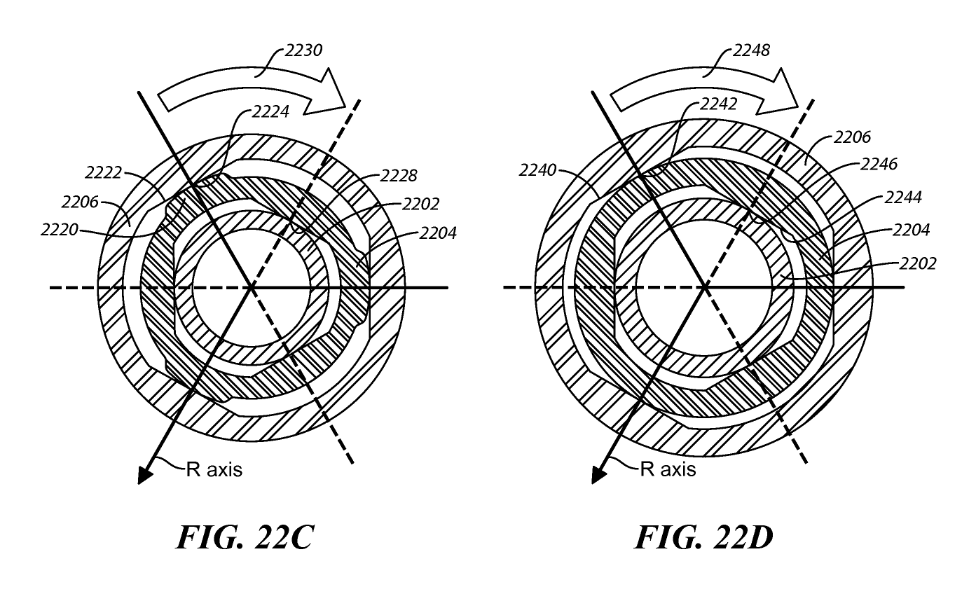

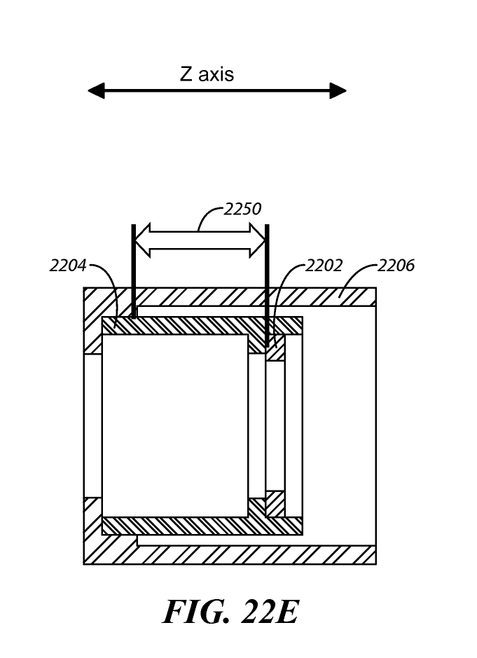

Referring now to FIG. 22A, one example of a D-cut (as used in some of the components discussed herein) is described. As shown, a cylindrical tube shown in the cross section includes a flat side 2201 and a circular side 2203 the optical housing uses a D-cut. D-cuts are used in some of the examples described below to achieve alignment in the R-direction as has been described elsewhere herein. D-cuts can be both inside D-cuts where the image represents the outside radius of the part and outside D cuts were the image represents the inside of the part. Some parts as described in FIG. 22C (e.g., barrel 2204) could have both present.

As shown in FIG. 22B, one example of a D-cut (as used in some of the components discussed herein) is described. A lens shaper 2202 is disposed radially within a barrel 2204 that is disposed radially within an optical housing 2206. The barrel 2204 includes clocking features (or indents) 2208 in which protrusions 2210 from the optical housing extend. The protrusions 2210 have flat surfaces. As shown, a cylindrical tube (shown in the cross section) includes a flat side 2202 and a circular side 2204 the optical housing uses a D-cut. D-cuts are used in some of the examples described below to achieve alignment in the R-direction as has been described elsewhere herein.

The size, shape, and position of the D-cuts the position of the lens shaper 2202 (and the optics within the lens shaper i.e., deformable or fixed optical lenses) within the inner barrel 2204 can be adjusted in the R-direction. FIG. 22B, FIG. 22C, and FIG. 22D are cross sectional views showing the components along the R-axis.

FIG. 22C includes a lens shaper 2202 that is disposed radially within a barrel 2204 that is disposed radially within an optical housing 2206. In this example protrusions 2220 from the barrel 2204 contact D-cuts 2222 from the optical housing 2206 at contact points 2224 and D-cuts 2226 of the barrel 2204 contact the lens shaper 2202 at contact points 2228. The contact points are at different radial positions and are separated by an angular distance 2230. The nature of the radial spacing in one aspect involves the inside and outside contact points. This allows for stress relief to occur in 2204 and protect the lens shaper 2202.

FIG. 22D includes a lens shaper 2202 that is disposed radially within a barrel 2204 that is disposed radially within an optical housing 2206. In this example, D-cuts 2240 on the optical housing 2206 contact the barrel 2204 at contact points 2242. D-cuts 2244 on the barrel 2204 contact the lens shaper 2202 at contact points 2246. The contact points 2242 and 2246 are at different radial positions and are separated by a distance 2248. Similarly, the nature of the radial spacing in inside and outside contact points. This allows for stress relief to occur in 2204 and protect the lens shaper 2202.

FIG. 22E includes a lens shaper 2202 that is disposed radially within a barrel 2204 that is disposed radially within an optical housing 2206. This view shows a cross sectional view along the Z-axis. In this axis there is z-axis separation in contact points creating a length 2250 that can be used for stress relief. This is similar to what is described is FIG. 22D and FIG. 22C.

In the deformable optical lens presented herein, a lens shaper (e.g., lens shaper 2202) is typically used and typically made of a material with a different coefficient of thermal expansion then of the material used in barrel. It is also a part which must have precision in shape and position to achieve good optical performance. In one example, silicon is used as lens shaper and has a coefficient of expansion of approximately 2.6*10̂-6 m/m per degree Celsius change and polycarbonate in the barrel may have a coefficient of expansion of approximately 70*10̂-6 m/m per Celsius. Still another material may be used in the optical housing. The difference between coefficients of expansion can cause stress to build as the temperature of the module changes. This can potentially cause a failure and can also potentially cause a degradation in optical performance. By creating a system shown, for example, in FIGS. 22B, 22C and 22D the stress in the parts can be allowed to be relieved to some extent. In the examples of FIG. 22B, FIGS. 22C, and 22D an angular separation 2230 or 2248 exists between the contact points of the optical housing 2206 and of the lens shaper 2202 so that the barrel 2204 is allowed to bend freely without being stiffened by the optical housing 2206. In the example of FIG. 22E, there is z-axis spacing 2250 between the contact points of the optical housing 2206 and of the lens shaper 2202 which similarly allows for the barrel 2204 to bend more freely. These systems allow for increased flexibility of the barrel structure that is holding the lens shaper 2202 and therefore lower stress within the optically critical lens shaper 2202.

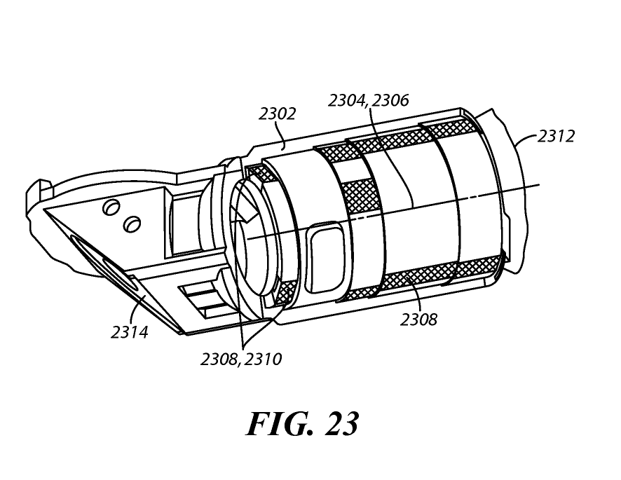

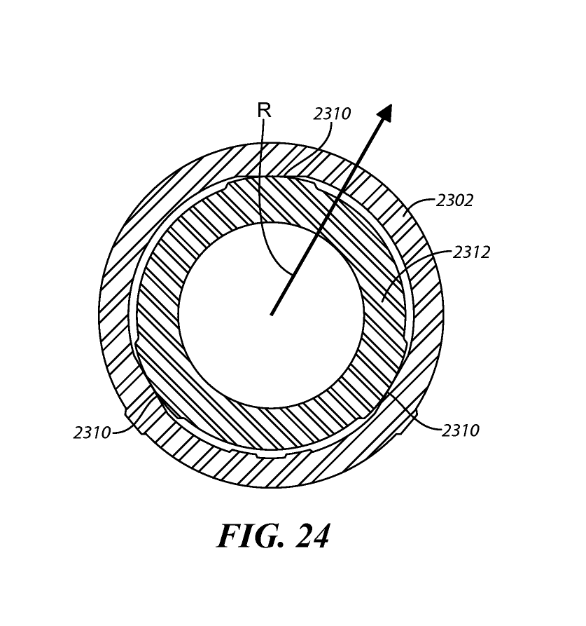

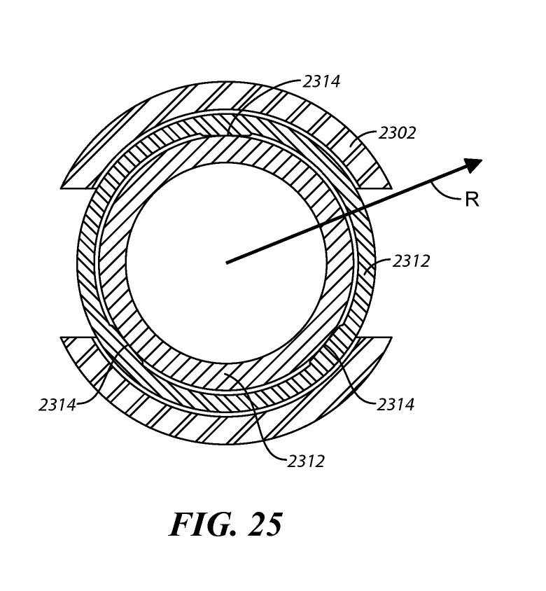

Referring now to FIG. 23, FIG. 24, and FIG. 25, further examples of D-cuts usage in an optical apparatus of the present approaches is described. Some of these figures illustrate a cutaway of an optical alignment structure showing various D-cuts made in different elements of the structure. The D-cuts align the lens in the R-direction (as described elsewhere herein). Because the shape of the optical alignment structure is complex, it can warp and deform in the molding process. D-cuts are configured, dimensioned, shaped, and made so that all optical elements can be aligned to the folded optical axis 2304 despite imperfections in the mold process (that is used to construct or form the optical housing). In other words, the barrel and optical housing contact the other at a predetermined and limited number of contact points providing a first alignment of the deformable optical lens along the sensor axis and providing a second alignment in a direction radially outward from an axis extending through the deformable optical lens.

An optical housing 2302 has a folded optical axis 2304, and a sensor optical axis 2306 as shown. The optical housing 2302 includes a barrel 2312. The barrel 2312 and optical housing 2302 contact the other at a predetermined and limited number of contact points or surfaces providing a first alignment of the deformable optical lens along the sensor axis 2306 (that extends from a sensor 2312 to a reflective surface 2314) and provides a second alignment in a direction radially outward from the sensor axis 2306.

D-cuts 2308 and 2310 are shown made in the optical housing 2302. D-cuts 2308 and 2310 and are provided for maintaining centration of the barrel. By “centration”, it is meant aligning the lens axis to the folded optical axis.

A barrel 2312 resides and is disposed within the optical alignment structure 2302. D-cuts 2310 maintain centration of the barrel 2312 because they are adjusted in the molding process to achieve good optical quality.

As shown in FIG. 25, the D-cuts 2314 align the lens in the R-direction. In this example, a lens shaper 2309 is also shown. The barrel 2312 transfers the alignment of the optical alignment structure to the lens shaper 2309. In other words, since the barrel is aligned so is the lens shaper 2309 and, consequently, the components of the deformable optical lens.

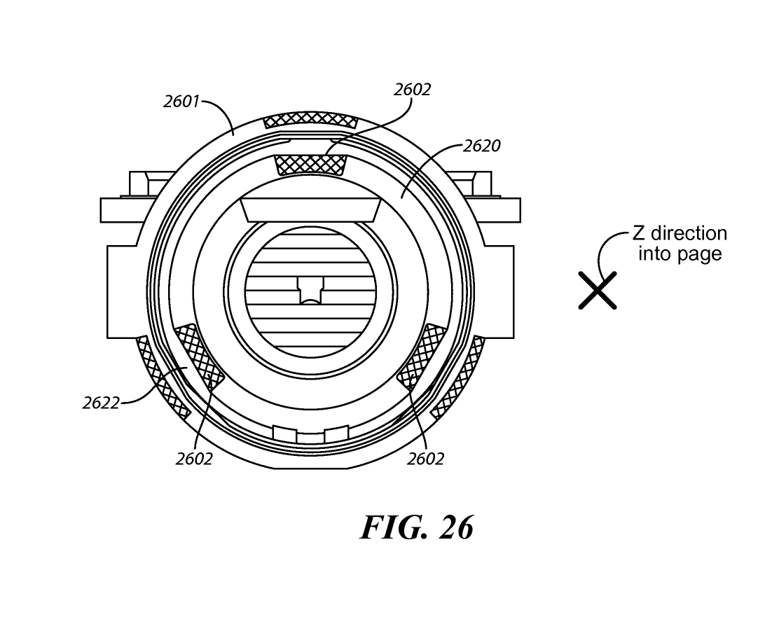

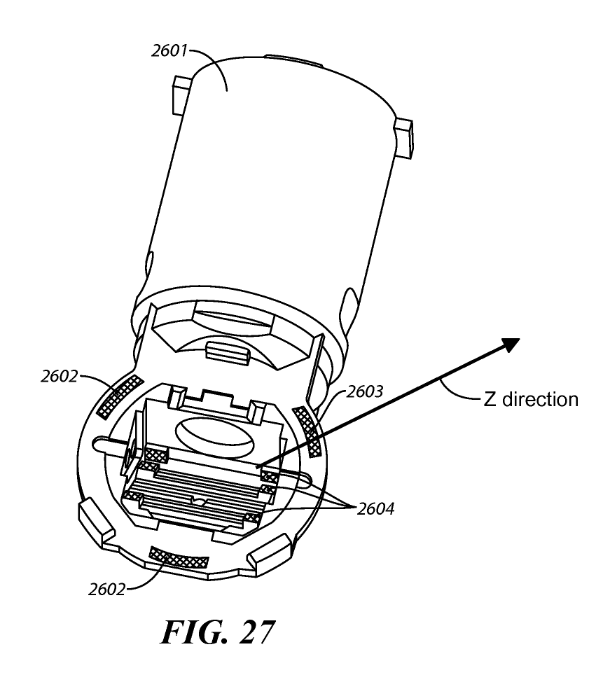

Referring now to FIG. 26 and FIG. 27, another example of an optical alignment structure is described. It will be appreciated that FIG. 26 and FIG. 27 are alternative views of the device shown in FIGS. 11-13. The view shown in FIG. 26 is an end, cross-sectional view of the device looking into the optical alignment structure from the sensor-end of the structure towards the reflective surface (e.g., a prism). An optical housing 2601 encloses a barrel 2622. The barrel 2622 includes a deformable optical lens. Because the shape of the alignment structure is complex, it can warp and deform in the mold process. Tip/tilt pads 2602 align the optical components (e.g., the deformable optical lens) in the z-axis direction (that is, the direction along the sensor axis). The pads 2602 are disposed between a lens shaper 2620 and another component internal to the optical housing 2601.

Referring now to FIG. 27, it can be seen that the optical housing is a complex mechanical part. Not only are the circular D-cuts present in the tubular section of the part, but tip/tilt pads 2603 are also present to align in the z-direction the top deformable optical lens. Tip/tilt pads 2604 align a reflective surface 2606 with the other optical elements in the optical apparatus. As shown in FIG. 27, the tip/tilt pads 2603 and 2604 align the components in the z-direction because the pads move the components in the direction with the amount of movement (distance) being the adjustment. The pads 2603 and 2604 are aligning the prism and barrel. By aligning, it is meant that the pads are dimensioned so that the prism and barrel are aligned and positioned to allow light to pass. Turning now to other aspects of the present approaches, it is advantageous to prevent mechanical energy, thermal energy or other forces originating from external sources from reaching the optical portions of the system (e.g., from reaching the various lenses both fixed and deformable). As will be described, surround structures and various elastomeric structures or pads (or other structures) are used to prevent mechanical or thermal energy from reaching the optical portions of the system. They are also used to minimize the effect of the remaining energy that does get through. In one aspect, the surround structure and pads form a channel through which fluid moves from a reservoir to the deformable optical lenses. The surround structure and the pads act to absorb mechanical energy. Further, the surround structure and the pads act as a barrier to thermal energy transfer. By choosing correct materials, the parts can also be designed to expand and minimize the effect of fluid expansion.

In one aspect, two pieces (a surround structure and pads, defined by their material more than their physical separateness) are used because of manufacturability concerns. As will be appreciated, it is difficult (if not impossible) to construct a single part with a winding, crooked channel with injection molding approaches. If a single part were somehow used, the single part, it would not act as a satisfactory thermal or mechanical barrier. It should be noted that two-shot injection molded parts with the two different materials are found in the same part is possible. This is considered to be two parts in this context, though it would arrive from a vender as a single item. The winding or crooked part is needed because the motor (the component that moves the fluid) should be kept close to the optical parts (e.g., the lenses) to loss due to the viscosity of the fluid. The surround structure and pads work together to provide a channel from reservoir to the variable lenses.

By “surround structure,” it is meant a support structure that surrounds portions of the apparatus. It may be constructed of various types of materials such as plastics. By “elastomeric pad or structure,” it is meant an elastomeric structure that may also be used to align the optical components but may also be utilized to provide isolation functions for an optical apparatus.

By “reservoir,” it is meant a bucket that holds a fluid. The reservoir bucket may be constructed from a number of different parts such as the actuator seal (e.g., a membrane), a surround structure, and the entrance to the fluid channel. A fluid channel is open to the reservoir and open to the deformable optical lens, and connects the reservoir to the deformable optical lens. The fluid channel may have multiple portions, may be constructed of various components such as the surround structure or an elastomeric membrane, the optical portion, and the entrance of the reservoir.

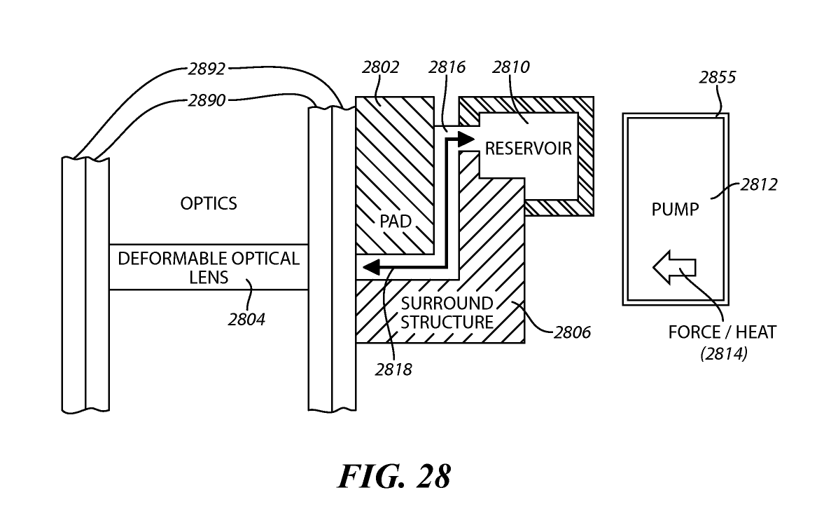

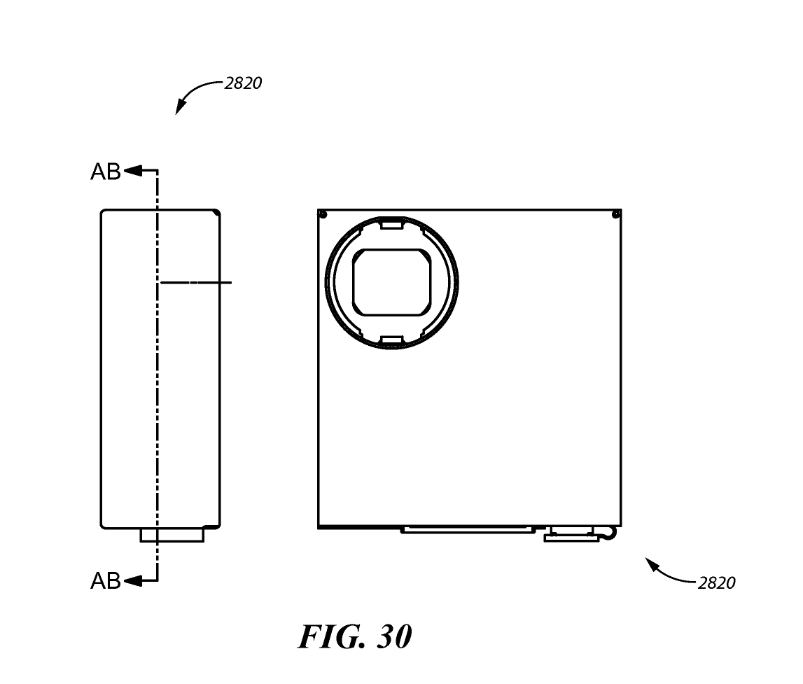

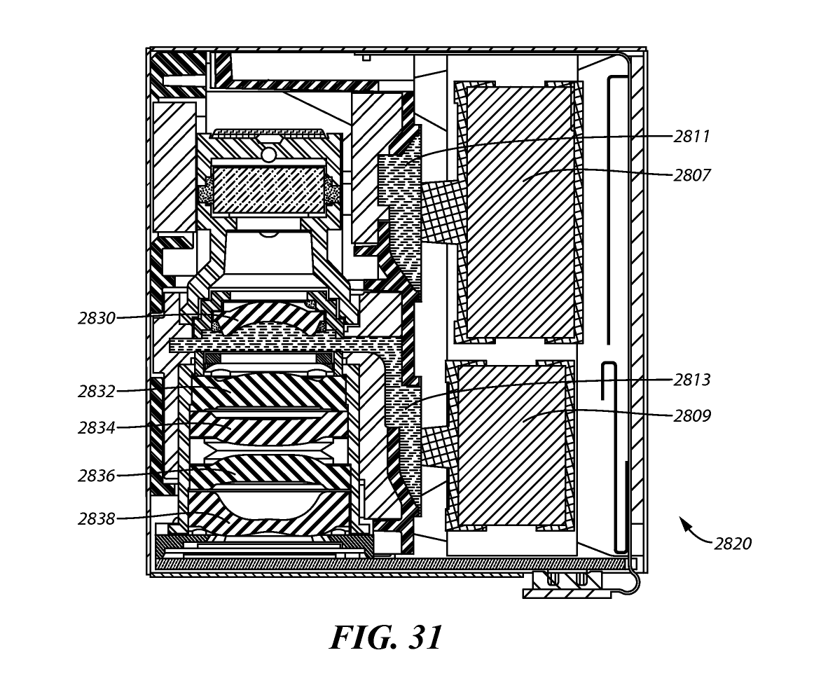

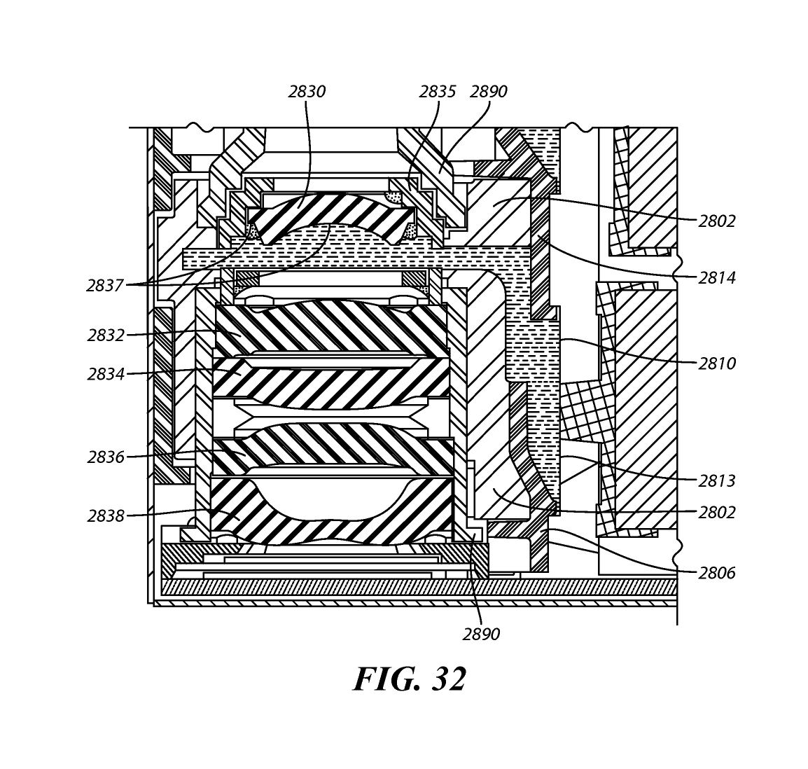

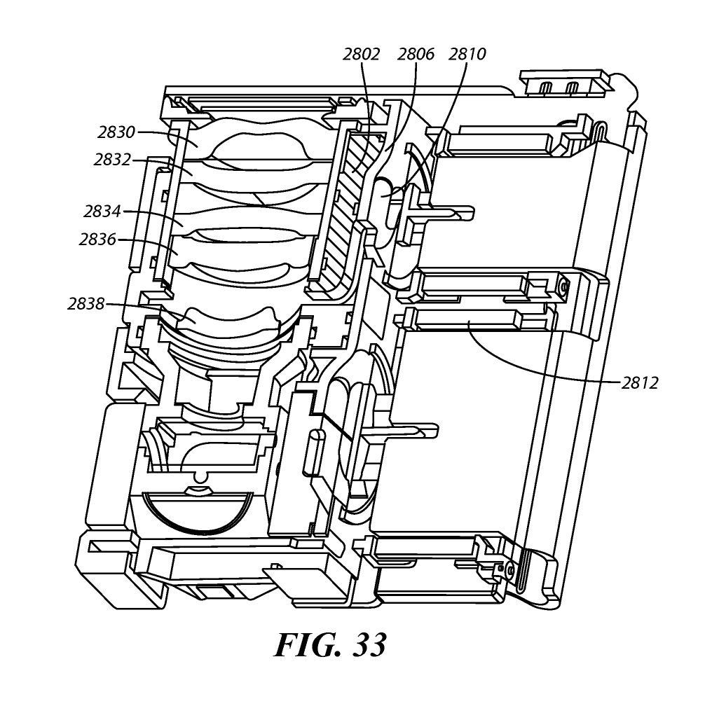

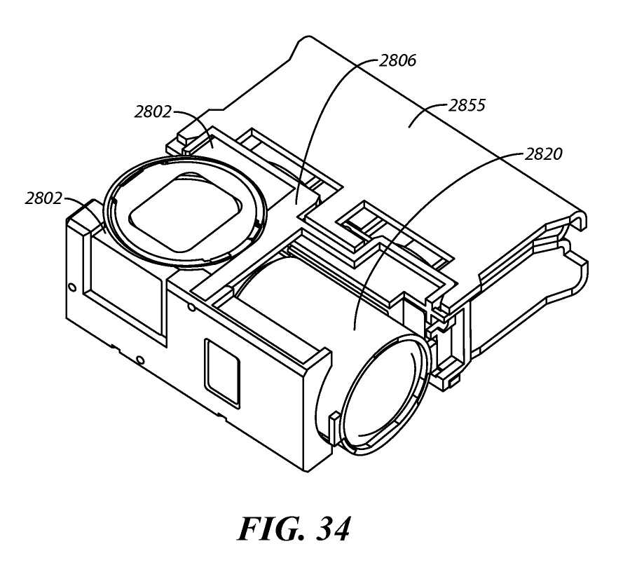

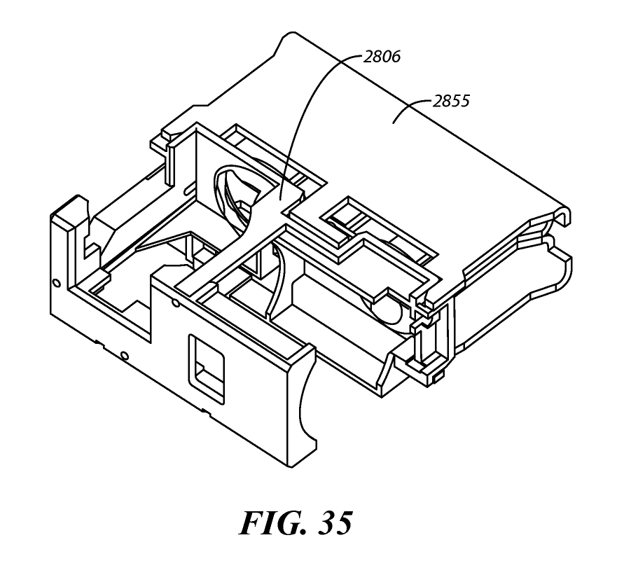

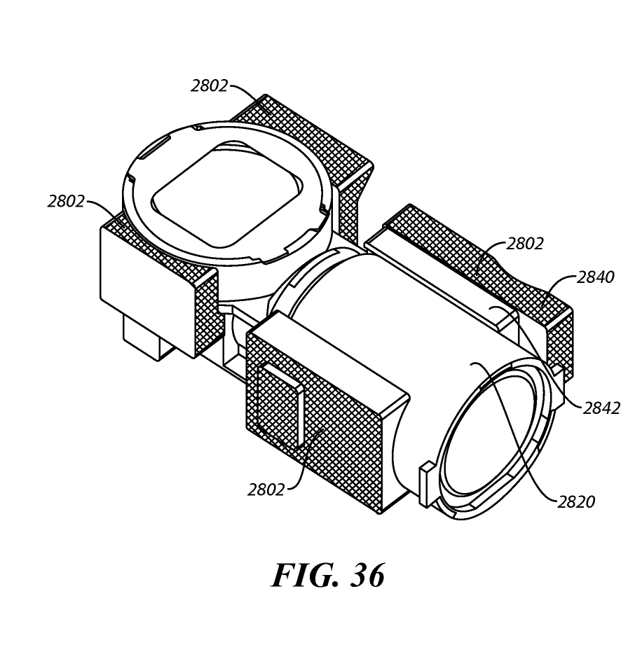

Referring now to FIGS. 28-40, an isolation structure according to the present approaches is now described. This structure includes an optical housing 2892, a barrel 2890, elastomeric pads or structures 2802, a surround structure 2806, and a pump 2812. The pump 2812 (and the motor within the pump) produces thermal and/or mechanical forces 2814 and its components are housed within a pump housing 2855. These components include a motor (e.g., a coil, magnets, magnetic flux return structure). As shown the optical housing 2892 and barrel 2890 are separate elements. In other examples, they may be integrally the same element. The deformable optical lens 2804 is contained in the barrel 2890.

The isolation structure isolates (e.g., absorbs or dissipates) the forces 2814 from the optics including a deformable optical lens 2804. A channel 2816 is generally formed between one of the elastomeric structures 2802 and the surround structure 2806. Fluid is exchanged between the reservoir 2810 and the lens 2804 via the channel 2816 as indicated by the arrow labeled 2818.

The volumetric coefficient of expansion of the optical fluid is very high compared to most solid materials, for example larger than 0.0010 per degree Celsius. Because of the high fluid thermal expansion, the deflection of the deformable lenses changes as the temperature of the system changes. This must be compensated for with additional motor travel (example pumps and motors are described elsewhere herein). Decreasing the effects of the fluid expansion is therefore desirable in order to decrease the amount of extra motor travel that is required. The volumetric coefficient of thermal expansion of the silicone and other elastomers is typically very high compared to most solid materials, for example 0.0009 L/L per ° C. This can be compared to the coefficient of thermal expansion of plastic, for example 0.0002 L/L per ° C. or aluminum alloys, for example 0.00007 L/L per ° C. The elastomeric structures are in one example constructed of silicone and therefore serve to partially compensate for the thermal growth of the fluid.

The long fluid channels described herein (e.g., channel 2816) increase the overall fluid volume of the system and therefore the effects of thermal expansion of the fluid are amplified. As mentioned, the volumetric coefficient of expansion of the optical fluid is very high compared to most solid materials, for example 0.0011. Because of the high fluid thermal expansion, the deflection of the deformable lenses changes as the temperature of the system changes. This is compensated for with additional motor travel. Decreasing the effects of the fluid expansion is therefore desirable in order to decrease the amount of extra motor travel that is required. The long fluid channel (e.g., channel 2816) may be constructed of any variety of materials or combination of materials. The volumetric coefficient of thermal expansion of the silicone is very high compared to most solid materials, for example 0.0009 L/L per ° C. This can be compared to the coefficient of thermal expansion of plastic, for example 0.0002 L/L per ° C. or aluminum alloys, for example 0.00007 L/L per ° C. The long fluid channel (e.g., channel 2816) may be made of a silicone tube which would largely compensate for the thermal expansion of the fluid. A silicone tube may not be ideal for ease of assembly. An alternate geometry may be used which combines silicone and a more rigid material, such as plastic. An example geometry is shown in FIGS. 28-40. The plastic serves to add rigidity to the structure and can help route the fluid channel. The effective volumetric thermal expansion of the composite plastic and silicone structure can be made such that it is nearly identical to the thermal expansion of silicone and therefore largely compensate for the thermal expansion of the fluid in the same way that a pure silicone tube does.

The example of FIG. 28 for simplicity shows one lens, one motor, and one reservoir. The surround structure 2806 forms part of the reservoir 2810 and, in one example, is constructed of a low thermal conductivity material such as siloxane, polycarbonate, or LCP. Other examples of materials may also be used. In another example, the surround structure 2806 may form all or portions of two reservoirs. A single part forming multiple reservoirs will be advantageous from a cost and assembly perspective.

The elastomeric structures 2802 can be constructed of various materials such as siloxane, foams, or gels. Other examples of materials may also be used. The elastomeric structures 2802 may allow for the transmission of UV light to allow for adhesive curing in creating seals in the channels and reservoirs. In some aspects, the elastomeric structures 2802 form one fluid channel while in other aspects the elastomeric structures 2802 form two fluid channels. In other aspects, the elastomeric structures 2802 form one reservoir while in other aspects the elastomeric structures form two reservoirs.

In one aspect, the surround structure 2806 and the pump housing 2855 form a rigid structure. The fluid pressure is supported in one aspect by the surround structure 2806 and the elastomeric structures 2802 although other elements may also support the fluid pressure. The reaction force is supported by the pump housing 2855. The surround structure and the motor housing are connected via an adhesive. The adhesive forms a pin so it will function after adhesive failure.

As the part deflects, additional contact is possible. For instance stop parts may be added into the surround structure 2806, elastometeric structures, 2802 or pump house 2855 to stop the piston from having excessive travel. This may be done to limit the range of focus of the optical apparatus or as further protection in the case of a shock load. If these features are placed in a reservoir area they would be designed as to minimize extra resistance of fluid flow. They would also be designed such as to ensure that the they would be located in an area that would not potential damage the actuator seal.

It will be appreciated that the lens 2804 may be a single lens. However, in some of the figures two lenses 2804A and 2804B are shown with 2804B being the top lens and 2804B being the bottom lens. The principle of operation of each of these lenses is the same. It will also be appreciated that there may be two pumps (one for each lens and each with a motor), two reservoirs, two channels, and so forth as shown in some of the figures. A first pump or actuator 2807 moves first fluid 2811 into the first lens 2804A. A second pump or actuator 2809 moves second fluid 2813 to the second lens 2804B. The optical housing 2833 includes a barrel 2835. The variable lens 2804B includes a membrane 2837.

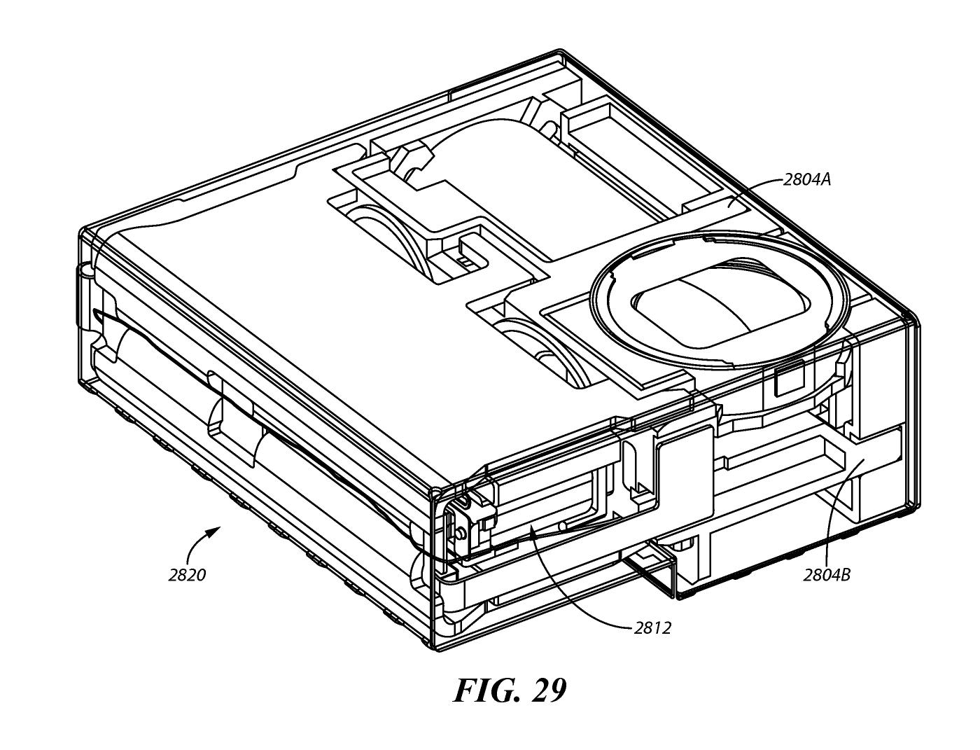

As shown especially in FIGS. 29-36, these components are part of an assembly 2820. The assembly 2820 may be a camera module. The optical assembly includes the variable lenses 2804 as well as fixed lenses 2830, 2832, 2834, 2836, and 2838.

The elastomeric structures 2802 are, in one aspect, elastomeric pads that isolate the lens barrel from external forces. Each elastomeric structure has a constrained area 2840. The unconstrained area 2842 allows for the pad to deform and protect the optical housing from external forces. The constrained area 2840 is the point of contact between two objects and does not move.

During manufacturing a needle can be used to pump fluid into any of the channels by inserting it through the elastomeric structures 2802. This can be accomplished because the elastomeric structures 2802 are flexible. The hole or opening made by the needle may be configured to self close in some examples based upon the material of the elastomeric structures 2802.

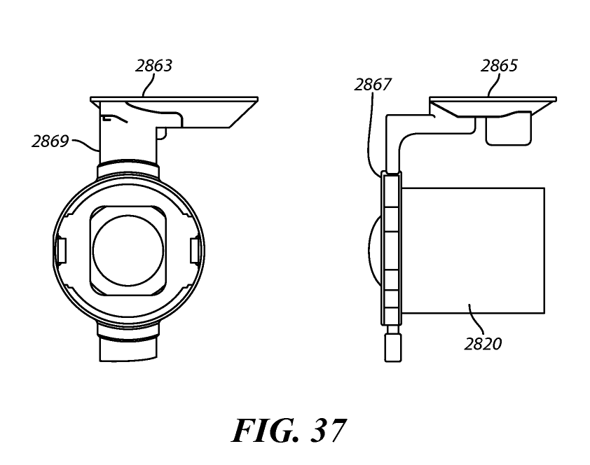

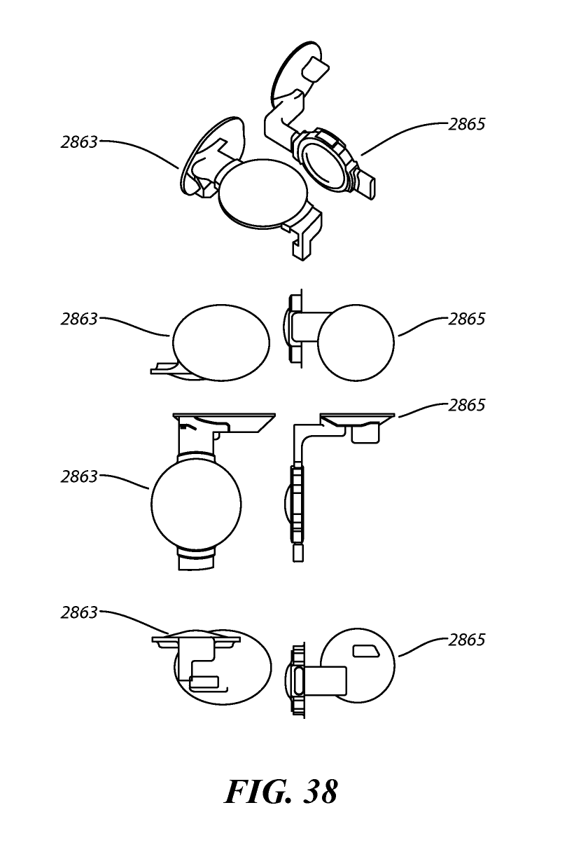

Referring now to FIGS. 37 and 38, the shape of the optical fluid within the apparatus is shown. That is, the shape of the fluid by itself without any enclosing structure is shown. As shown, there is a top fluid shape 2863 (with a first opening 2869 in the barrel connecting the reservoir to the top deformable optical lens) and a bottom fluid shape 2865 (with a second opening 2867 in housing connecting the reservoir to the bottom deformable optical lens). Other examples are possible.

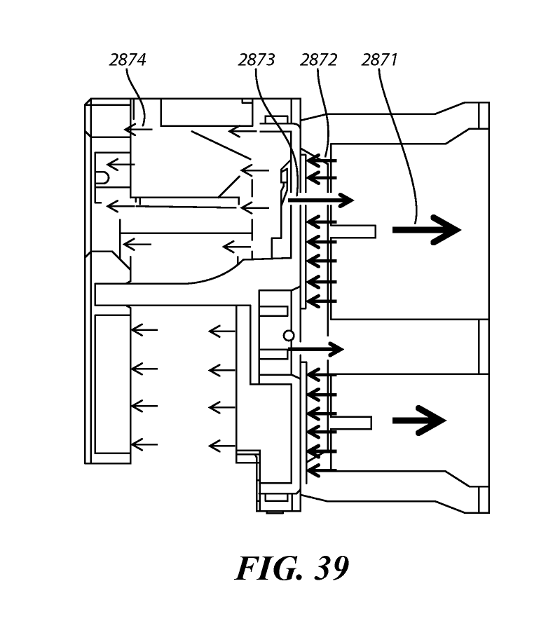

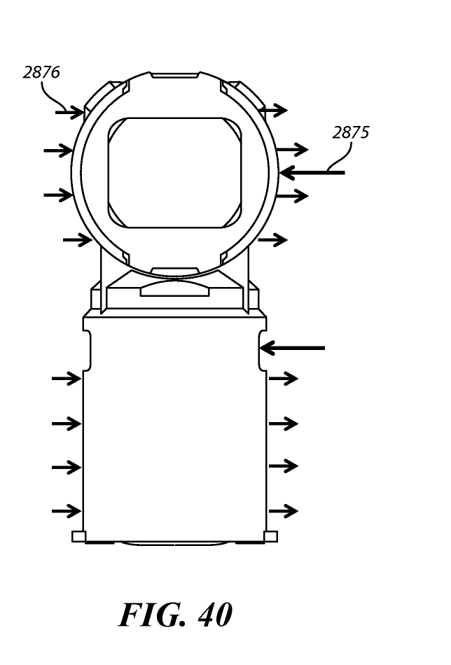

Referring now especially to FIG. 39 and FIG. 40, free body diagrams that show internally generated forces and reactions to these forces are described. The forces are generated by actuation of motor and pressurization of the fluid. Referring now especially to FIG. 39, forces 2871 are reactions from the actuator onto the rigid actuator structure. Forces 2872 are distributed forces from the actuator onto the surround structure. Forces 2873 are small fluid pressure forces caused by an opening in the fluid channel to provide fluid to the optics. Forces 2874 are distributed reaction forces from the small fluid pressure force. The surround structure and rigid actuator structure are considered a single body.

Referring now to FIG. 40, a free body diagram showing forces on the optical assembly (including barrels and the lenses) is described. The optical assembly including the housing, barrels, and lenses is considered a single body.

Force 2875 is a small force from the optical fluid pressure and is equal and opposite to the force 2873. Force 2876 is a distributed reaction force to the small pressure force and is equal and opposite to the force 2874. The reaction force is exerted by the elastomeric structures that support the optics.

The elastomeric mounting structure ensures that external loads on the module are carried by the rigid actuator structure and not the optics. Since the optics to not carry a significant portion of external forces the optical assembly does not deform and cause misalignment of the lenses. The elastomeric pads are of low thermal conductivity and therefore reduce the heat flow from the motor to the optical assembly.

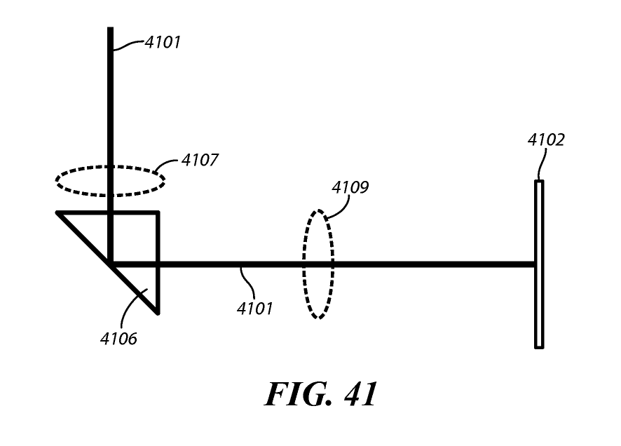

Referring now to FIG. 41-44, various optical topologies are described. In these figures (all side views of an optical apparatus), it can be seen that the various optical components can be arranged in different ways, orders, and configurations.

FIG. 41 shows a side view of an optical apparatus with a folded optical axis 4101, a sensor 4102, a reflective surface 4106, and a first deformable optical lens 4107 and a second deformable optical lens 4109.

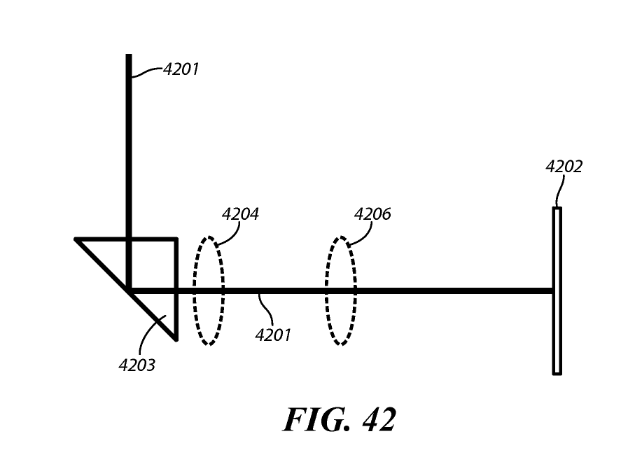

FIG. 42 shows a side view of an optical apparatus with a folded optical axis 4201, a sensor 4202, a reflective surface 4203, a first deformable optical lens 4204 and a second deformable optical lens 4206. As compared to the example of FIG. 41, this example includes the first deformable optical lens 4204 and a second deformable optical lens 4206. Also as compared to the example of FIG. 41, this example shows that the first deformable optical lens has been moved to a position after the reflective surface in the optical path. That is, rays of light impact the reflective surface first and then pass through the deformable optical lenses.

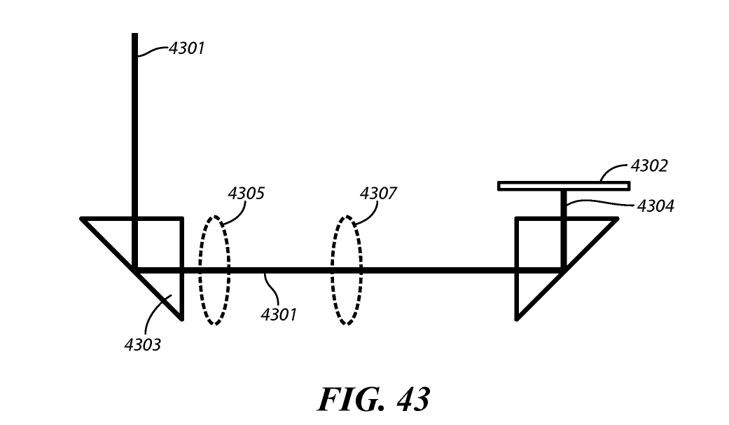

FIG. 43 shows a folded optical axis 4301, a sensor 4302, a first reflective surface 4303, a second reflective surface 4304, a first deformable optical lens 4305, and a second deformable optical lens 4306. As compared to the examples of FIG. 41 and FIG. 42, a second reflective surface has been added.

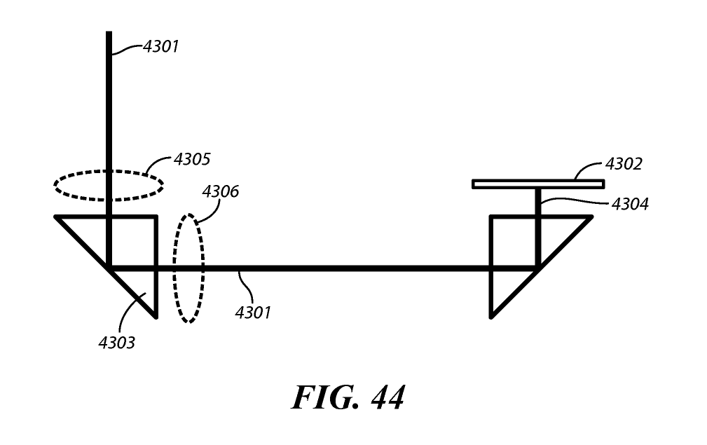

Referring now to FIG. 44, yet another optical topology is described. This topology includes a folded optical axis 4401, a sensor 4402, a first reflective surface 4403, a second reflective surface 4304, a first deformable optical lens 4305, and a second deformable optical lens 4306. In the example of FIG. 44, the first deformable optical lens 4405 is moved to a position as shown in FIG. 41.

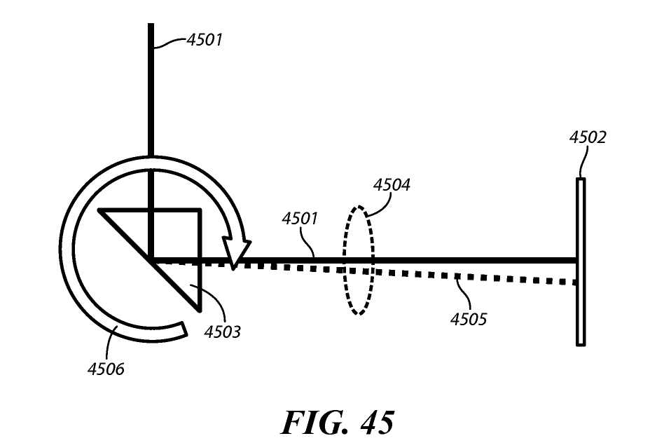

Referring now to FIGS. 45-50, examples of image stabilization achieved via the present approaches are described. Generally speaking, image stabilization may be achieved by automatic adjustment of positions of elements of an optical apparatus, and may or may not utilize feedback. More specifically, movement of the components or changes in the image position is detected and a compensation for this movement is provided. Detectors could be placed internal to the optical apparatus or external to camera module. Multiple detection and adjustment paths/algorithms may also be used. As will be described elsewhere herein, small motors may be used to move the components into an appropriate alignment.

FIG. 45 shows a side view of an optical apparatus including a folded optical axis 4501, a sensor 4502, a reflective surface 4503, at least one deformable optical lens 4504, and a tilted optical axis 4505. The reflective 4503 is rotated/tilted as shown by the arrow labeled 4506. As has been described elsewhere herein this adjustment is made in the θ direction. This movement is suitable to change the direction of the rays and compensate for unwanted movement.

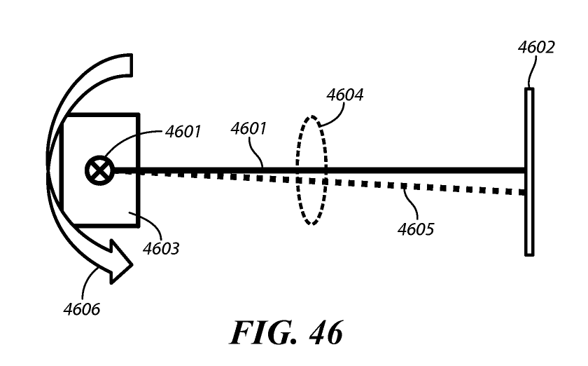

FIG. 46 shows a folded optical axis 4601, a sensor 4602, a reflective surface 4603, at least one deformable optical lens 4604, and a tilted optical axis 4605. The reflective surface 4603 is rotated/tilted in the direction indicated by the arrow labeled 4606. Consequently, the adjustment is being made in the Φ direction as has been described elsewhere herein. The view shown in FIG. 46 is shown looking down into the optical apparatus and is not a side view as in FIG. 45.

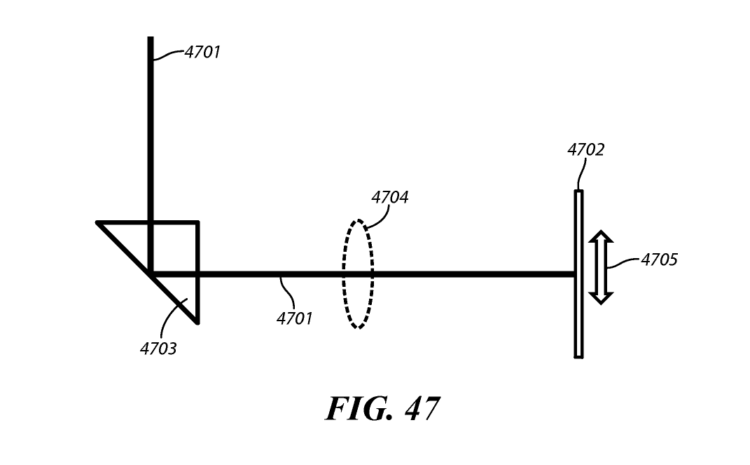

FIG. 47 shows a side view of an optical apparatus including a folded optical axis 4701, a sensor 4702, a reflective surface 4703, and at least one deformable optical lens 4704. The sensor 4702 can be translated in the direction indicated by the arrow labeled 4705.

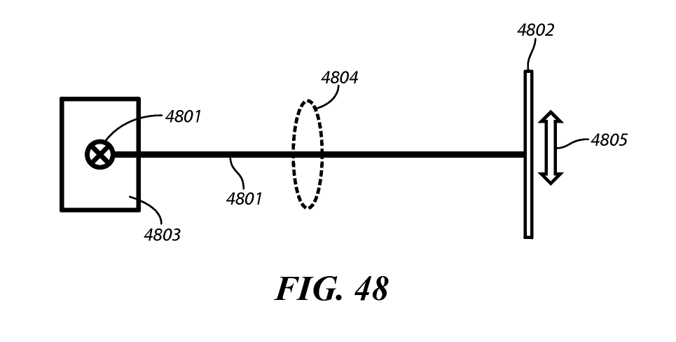

FIG. 48 shows a top view of an optical apparatus including a folded optical axis 4801, a sensor 4802, a reflective surface 4803, and at least one deformable optical lens 4804. The sensor 4802 may be translated in the direction indicated by the arrow labeled 4805. The view shown in FIG. 48 is shown looking down into the optical apparatus and is not a side view as in FIG. 45 or 47.

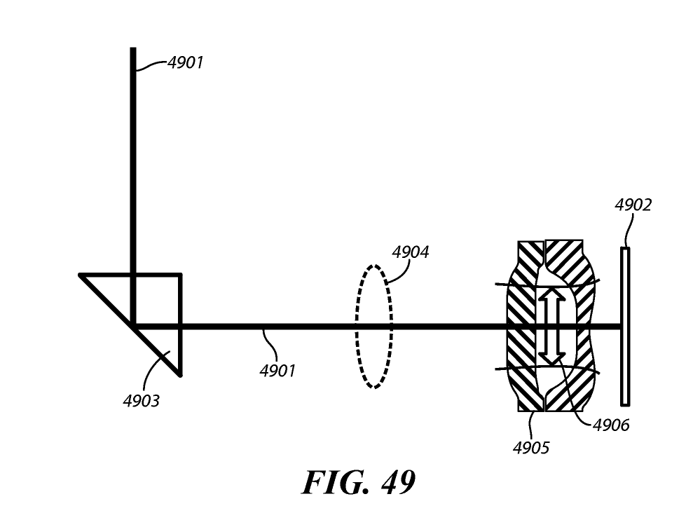

FIG. 49 shows a side view of an optical apparatus including a folded optical axis 4901, a sensor 4902, a reflective surface 4903, at least one deformable optical lens 4904, and a moving solid lens or lens group 4905. The lens 4905 may be moved according to the arrow labeled 4906.

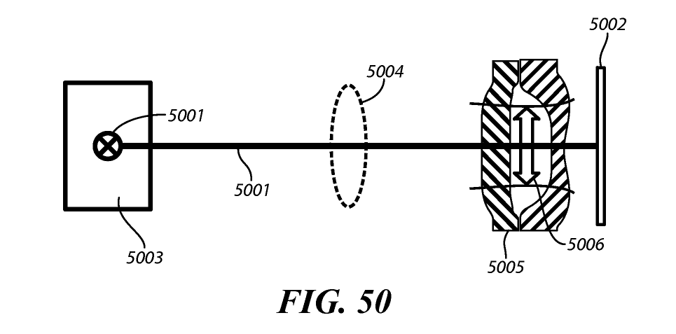

FIG. 50 shows a top view of an optical apparatus including a folded optical axis 5001, a sensor 5002, a prism 5003, at least one deformable optical lens 5004, a moving solid lens or lens group 5005. The lens 5005 may be moved according to the arrow labeled 5006. The view shown in FIG. 50 is shown looking down into the optical apparatus and is not a side view as in FIG. 45, 47, or 49.

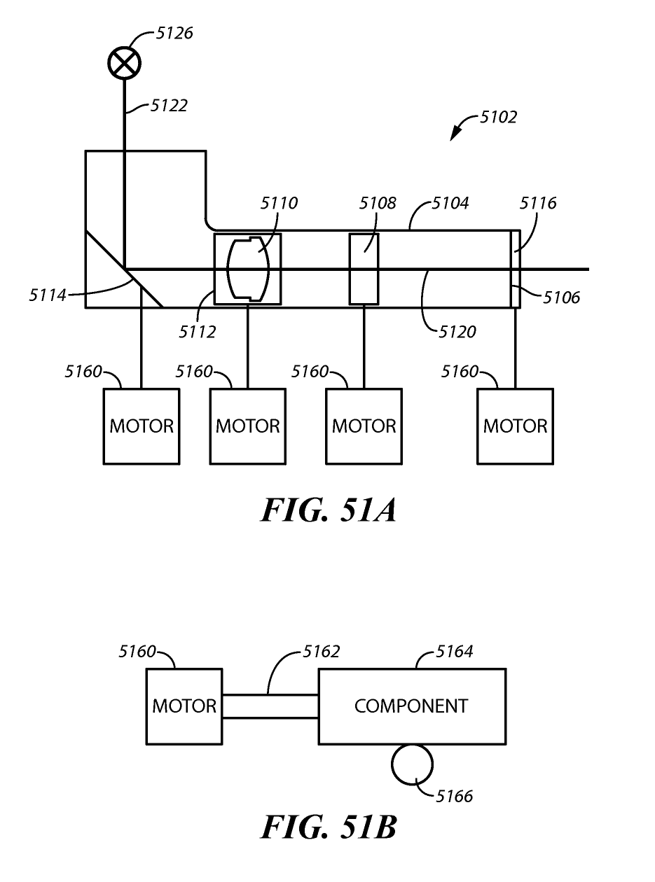

Referring now to FIGS. 51A-51B, optical image stabilization in an optical apparatus is further described. An optical apparatus 5102 includes an optical housing 5104 with an end 5106. A fixed lens 5108 is disposed within the optical housing 5104. A deformable optical lens 5110 is also disposed within the optical housing 5104.

A barrel 5112 is disposed within the optical housing 5104, and the deformable optical lens 5110 is disposed at least partially within the barrel 5112. A reflective surface 5114 is mounted to the optical housing 5104. A sensor 5116 is coupled to the end 5106 of the optical housing 5104.

A sensor axis 5120 passes through the sensor 5116 and the reflective surface 5114. An object axis 5122 is in the same plane and non-parallel to the sensor axis 5120 and passes through the reflective surface 5114.

An optical path 5124 (a folded optical path) exists and is disposed within the optical housing 5104. The optical path 5124 follows the object axis 5122 from an object 5126 external to the apparatus to the reflective surface 5114. The optical path 5124 is redirected at the reflective surface 5114 and then follows the sensor axis 5120 to the sensor 5116 at the end of the optical housing 5104. The optical path 5124 passes through the deformable optical lens 5110 and the fixed lens 5108. The reflective surface 5114, the sensor 5116, or the deformable optical lens 5110 are moved or adjusted so as to improve an image quality of an image that follows the optical path to the sensor 5116.

Each of the components (fixed lens 5108, deformable optical lens 5110, barrel 5112, reflector 5114, sensor 5116) or combinations of these components can be automatically adjusted in position to improve image quality and stabilize images at the sensor 5116. In these regards, a motor (or other actuator) 5160 has a connector 5162 to move a component (e.g., fixed lens 5108, deformable optical lens 5110, barrel 5112, reflector 5114, sensor 5116) on a roller or flexible rod 5166. Other actuation approaches may also be used. Various motors 5160 are coupled to various optical components in this example.

As has been described elsewhere herein, the various optical components may be housed in an optical housing. As also has been described, this housing may be a singled piece, molded structure. However, in other examples the structure may be broken into multiple, separate components that are coupled together. As will be described, certain advantages are obtainable when this approach is utilized.

Referring now to FIG. 52A-52E, one example of breaking the optical housing into separate portions is described. In this example, three portions are shown but it will be appreciated that any number of barrels may be used.

A first portion 5202 of the optical housing and a second portion 5204 of the optical housing are coupled together at a first interface 5206. The second portion 5204 and a third portion 5208 of the optical housing are coupled together at a second interface 5210. The apparatus includes a first fixed lens 5212, a second fixed lens 5214, a sensor 5216, a first deformable optical lens 5218 (that includes a first membrane 5220 and a first container or fixed lens 5222), a second deformable optical lens 5224 (that includes a second membrane 5126 and a second container or fixed lens 5228), and a reflective surface 5230 (e.g., a prism). Glue 5232 is applied between different components.

Because the portions are open before assembly is completed, parts of the apparatus (e.g., the deformable optical lenses) can be easily assembled and optical components easily inserted. Splitting the optical housing into separate portions also allows for a thin support at the fluid channel that locates both the lens shaper and the container lenses.

Referring now especially to FIGS. 52B and 52C and in another aspect, the interfaces 5206 and 5210 can be constructed in a variety of different ways. In a first approach a first flange 5240 is constructed on the first portion 5202 and a second flange 5242 is constructed on the second portion 5204. Each of the flanges 5240 and 5242 have holes (or openings) 5244 that are disposed in each corner of the flange. Pins 5246 are placed though each of the holes 5244. Consequently, alignment is easily achieved as the parts are coupled together. This approach can be applied as between all portions as well.

In a second approach, the second portion 5204 and the third portion 5208 are centered using a centering feature. In one example (between the second barrel and the sensor) each corner has a centering feature 5250. A tab 5252 sits between adjacent centering features 5250. As the two portions are connected, then they are automatically centered using the centering features 5250.

Referring now to FIG. 52E, a connection between the second portion 5204 and the sensor housing is shown. Each corner has a centering feature 5270. A clocking feature or tab 5272 is used to provide alignment by insertion into the centering feature 5270.

The present approaches eliminate the requirement of axisymmetric barrel alignment and instead align the portions of the optical housing in the corners of the interface. These approaches allows assembly of the apparatus from either end and allow the assembly of closely located sealed elements with a fluid channel.

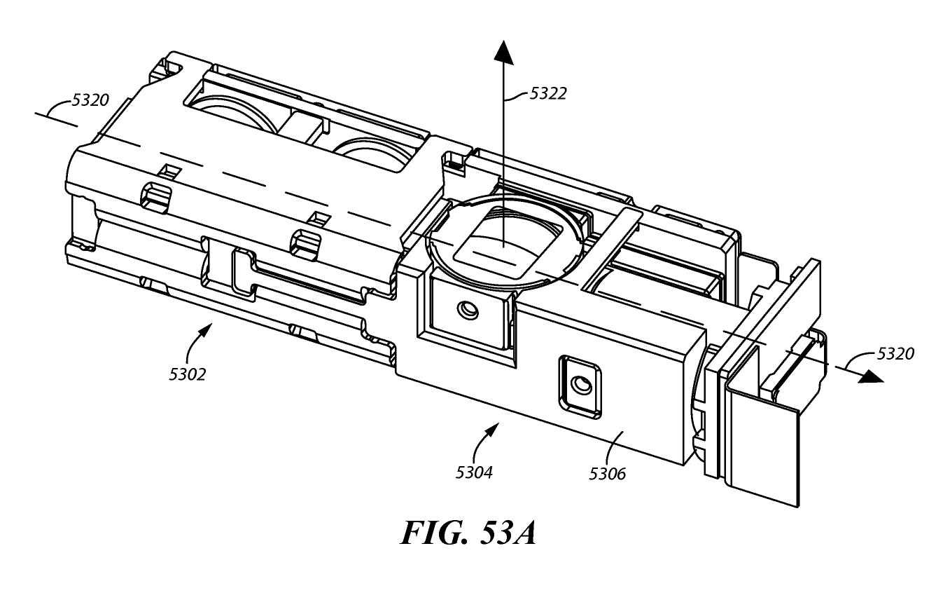

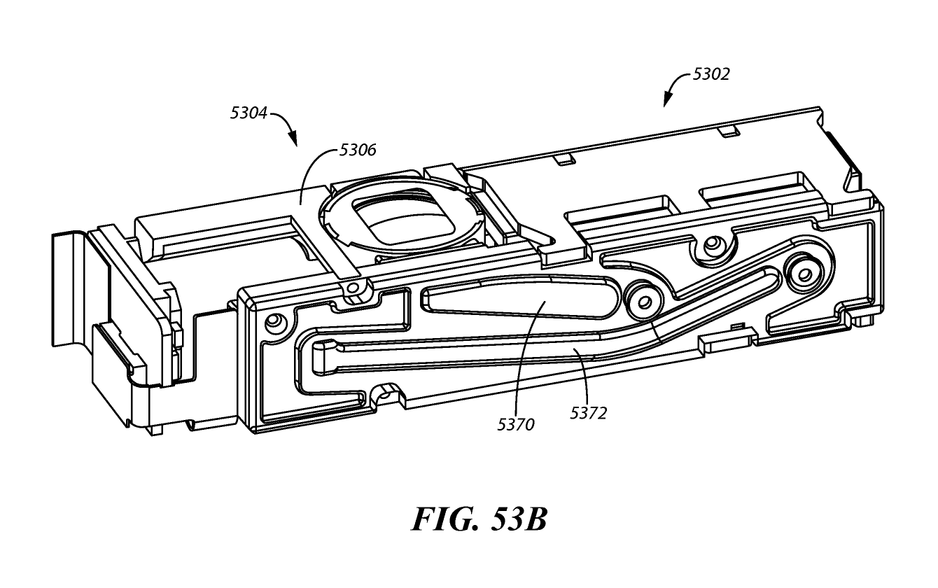

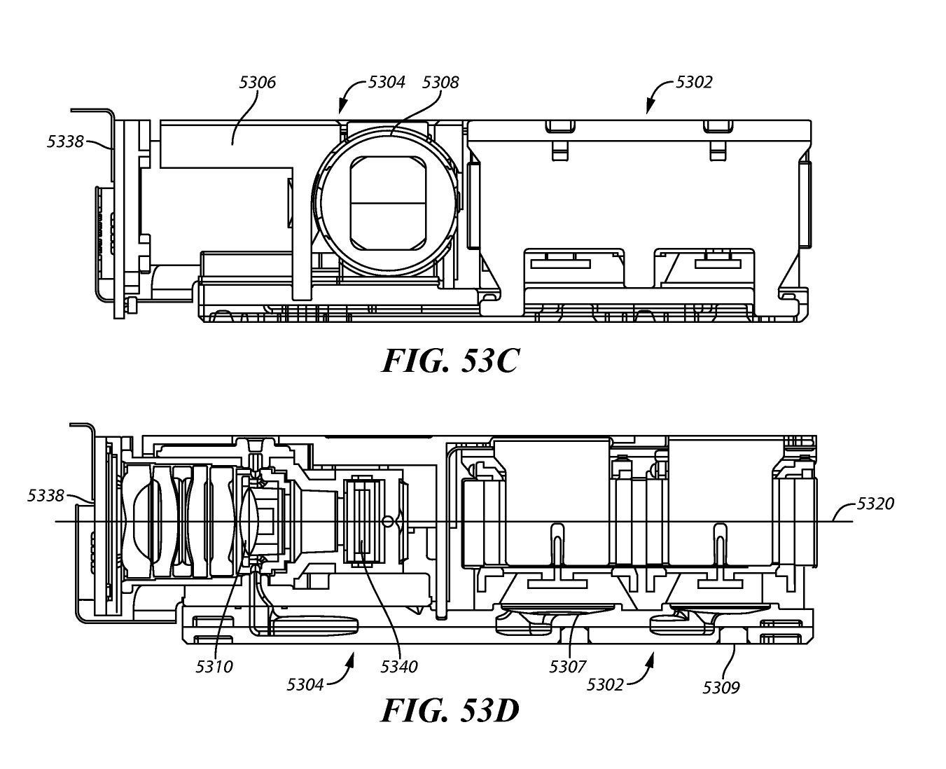

Referring now to FIG. 53, one example an optical apparatus 5300 that disposes a pump portion 5302 and an optical portion 5304 in an end-to-end adjustment is described. The pump portion 5302 generally includes electromechanical actuators that move a piston to cause fluid to be exchanged between reservoirs and deformable optical lenses. These actuators can be electromagnetic, piezoelectric, electrostatic, magnetostrictive to name a few examples. One example of a voice coil in magnetic field linear actuator is described elsewhere herein.

The optical portion 5304 includes an optical housing 5306, a first deformable optical lens 5308 and a second deformable optical lens 5310 that are disposed within the optical housing 5306. A reflective surface 5340 is disposed within the optical housing 5306. A sensor 5338 is disposed at an end of the optical housing 5306.

The pump portion 5302 is configured to cause a fluid exchange between a first fluid reservoir 5307 and the first deformable optical lens 5308. The pump portion 5302 is also configured to cause a fluid exchange between a second fluid reservoir 5309 and the second deformable optical lens 5310.

In one example of the operation of the systems of FIG. 53, a sensor axis 5320 passes through the sensor 5308 and the reflective surface 5340, and an object axis 5322 is generally perpendicular to the sensor axis and passes through the reflective surface 5340. An optical path for images is provided within the optical housing. The optical path follows the object axis from an object external to the apparatus to the reflective surface 5340. The optical path is bent at the reflective surface 5340 and then follows the sensor axis 5320 to the sensor 5338 at the end of the optical housing. The optical path passes through the deformable optical lens and the fixed lens.

The sensor axis extends through an entire length of the motor portion 5302 and an entire length of the optical portion 5304. A first fluid channel 5344 and a second fluid channel 5345 are formed and extend along a side of the motor portion 5302 and a side of the optical portion 5304 in a direction generally parallel to the sensor axis 5320. The fluid channels 5344, 5345 are configured to allow the exchange of fluid between the reservoirs 5307, 5309 in the motor portion 5302, and the first deformable lens and the second deformable lens.

Fluid channels 5370 and 5372 supply fluid between the reservoirs and the deformable optical lenses. The channels 5370 and 5372 may be foinied between a first structure 5374 and a second structure 5376. As used herein, “channel” refers to the empty space through which fluid passes and the structure that contains the empty space (forms the empty space).

In another example, an optical apparatus includes an axis. An optical portion includes at least one deformable optical lens arranged about the axis. A pump portion is configured to actuate the at least one deformable lens, the pump portion arranged about the axis. In some examples, the pump portion is disposed on one side of the optical portion. In other examples, the pump portion comprises a first part and a second part, and the optical portion is disposed between the first part and the second part.

In yet another example, an optical apparatus includes a pump portion and an optical portion. The optical portion comprising an optical housing, a first deformable optical lens and a second deformable optical lens that disposed within the optical housing; a reflective surface disposed within the optical housing; and a sensor disposed at an end of the optical housing. The pump portion is configured to cause a fluid exchange between at least one fluid reservoir and the first deformable optical lens and between the at least one fluid reservoir and the second deformable optical lens. The optical portion also includes an axis and the pump portion and the optical portion arranged about the axis.

In some examples, the pump portion is disposed on one side of the optical portion. In other examples, the pump portion comprises a first part and a second part, and optical portion is disposed between the first part and the second part. In other examples, the at least one reservoir comprises a first reservoir and a second reservoir, and the first reservoir and the second reservoir being disposed in the same plane.

In some aspects, the fluid channel is formed and extends along a first side portion of the pump portion and a second side of the optical portion in a direction generally parallel to the axis. The at least one fluid channel is configured to allow exchange of fluid between the at least one reservoir and the first deformable lens, and between the at least one reservoir and the second deformable lens.

In some examples, the at least one fluid channel is formed from a first material portion and a second material portion. In some aspects, the first material portion comprises a different material from the second material portion. In other aspects, the at least one fluid channel comprises a tube-like structure, the tube-like structure being constructed of a material that minimizes or eliminates the effects of thermal fluid expansion. These can parts can be glued together, welded together, co-molded, or made with a two shot process to mention a few examples.

In other examples, the at least one reservoir comprises a first reservoir and a second reservoir. A first movement of fluid from the first reservoir to the first deformable optical lens meets less fluid resistance than a second movement of fluid from the second reservoir to the second deformable optical lens.

In some aspects, a pump includes a magnetic circuit return structure having a central portion and an outer portion. The outer portion includes a first wall portion and a second wall portion. The central portion is disposed between the first wall portion and the second wall portion.

A first coil extends around a first portion of the central portion and a second coil extends around a second portion of the central portion. A first magnet and a second magnet are also included. A first actuator is at least partially movably disposed within the first coil and a second actuator is at least partially movably disposed within the second coil.

A first electrical current applied to the first coil produces a first force to produce a first movement of the first actuator, the first movement of the first actuator effective to move a first membrane that communicates with a first deformable optical lens;

A second electrical current applied to the second coil produces a second force to produce a second movement of the second actuator, the second movement of the second actuator effective to move a second membrane that communicates with a second deformable optical lens.

In some aspects, the first actuator and the second actuator are piston-like structures. In other examples, the first actuator and the second actuator are generally circular in the cross-section. The area of the piston has a strong impact on the amount of fluid pushed into the deformable optical lens. The desire is to have a motor structure with a minimized height so other piston cross sections with different aspect ratios can be important. Ellipses, ovals and racetrack shapes will be advantageous over a circle in a height restricted location that still requires a higher surface area of the piston.

In other examples, the first magnet and the second magnet are made from neodium-iron-boron or summarium cobalt magnets. Magnets are polarized towards the central portion. In other aspects, the first magnet and the second magnet are polarized away from the central portion. In both polarization instances the device is generally magnetically symmetric about the central structure. In other examples, the first magnet overhangs the first wall portion which will aid in assembly and all help optimize the amount of flux flowing through the coil.

In some other aspects, the first magnet is disposed between the first wall portion and the first coil, the first magnet is also disposed between the first wall portion and the second coil. The second magnet is disposed between the second wall portion and the first coil, the second magnet is also disposed between the second wall portion and the second coil.

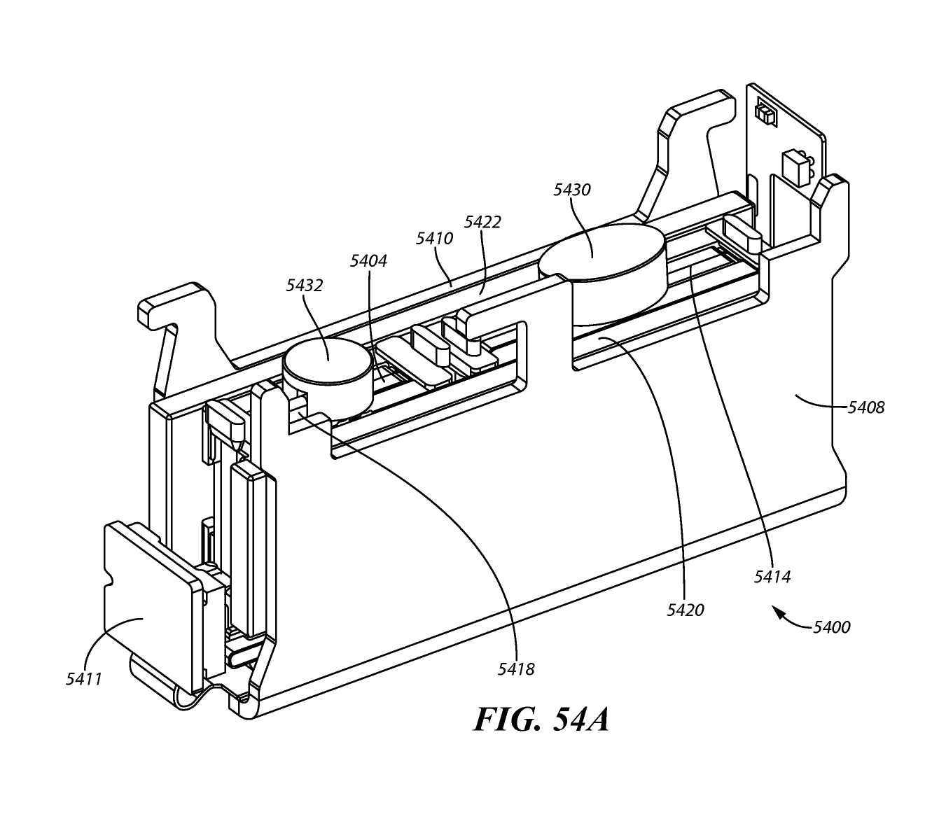

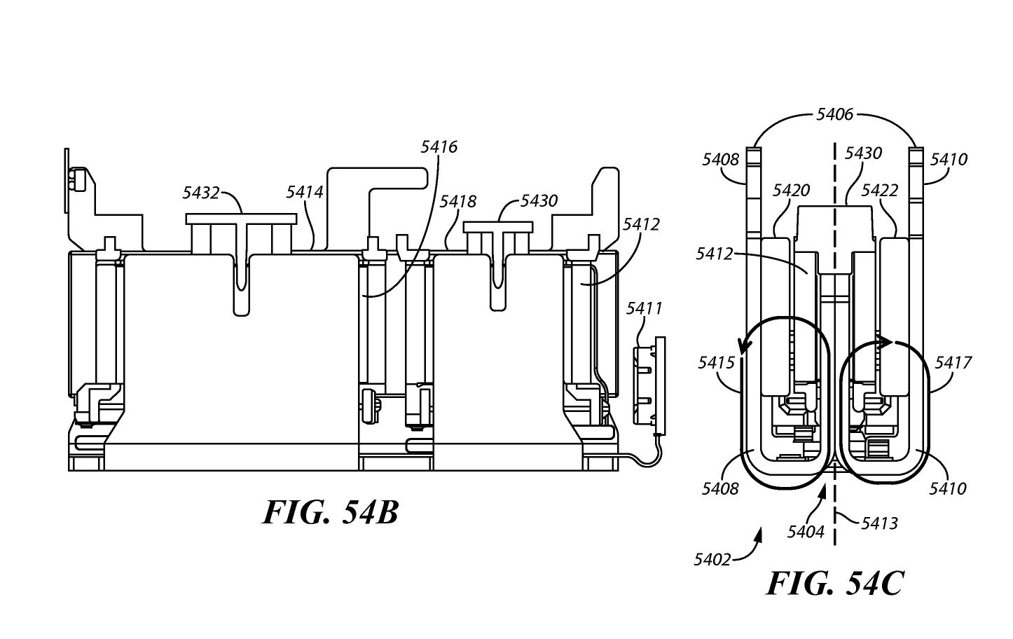

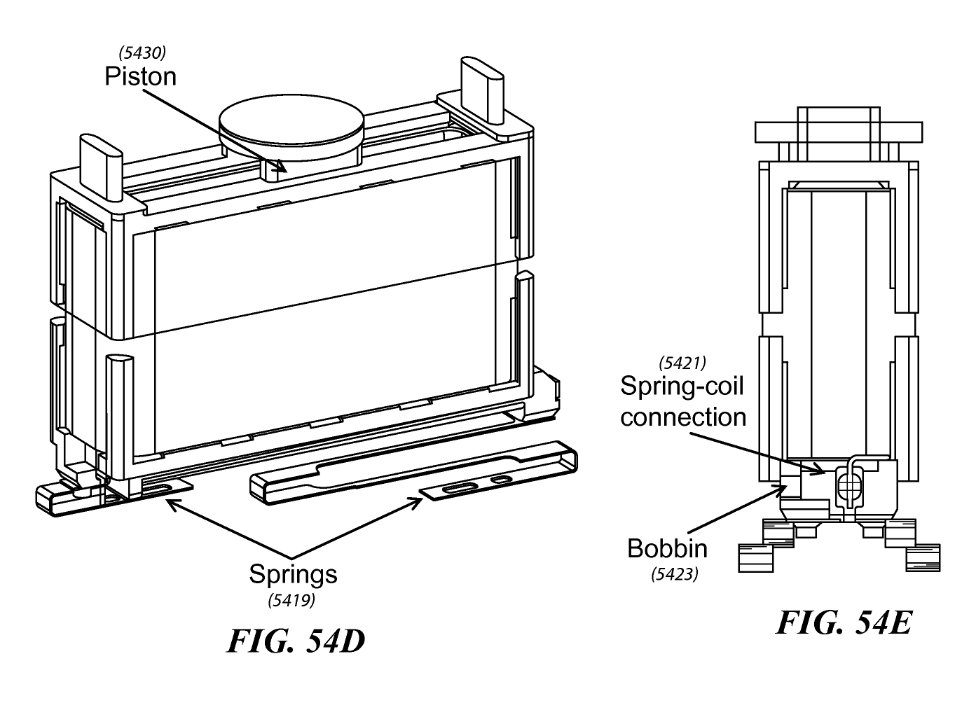

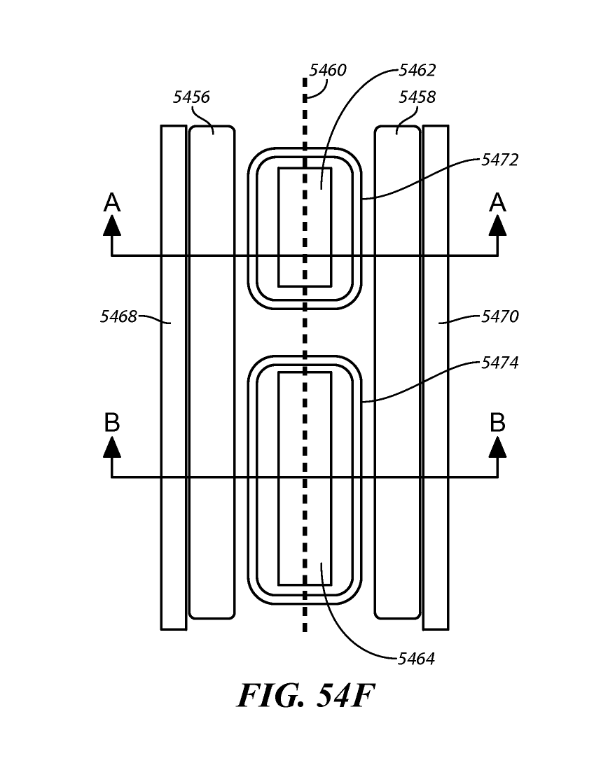

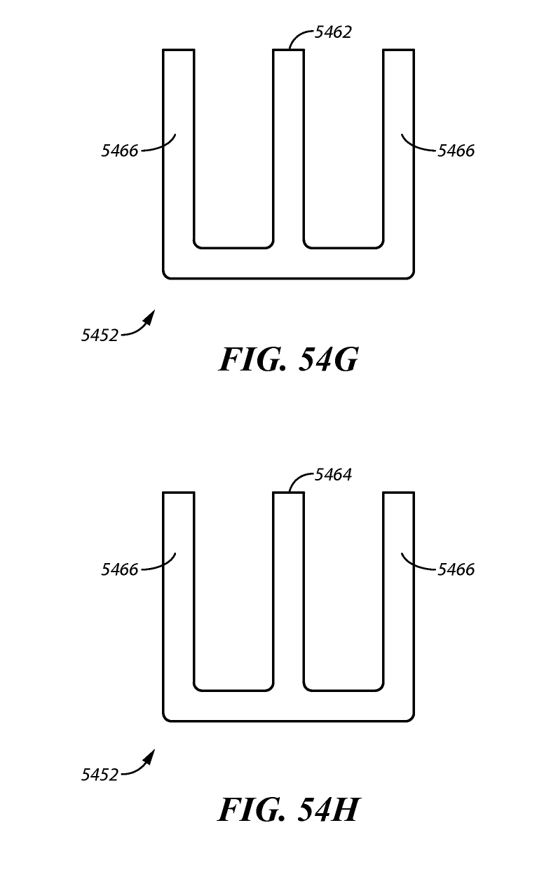

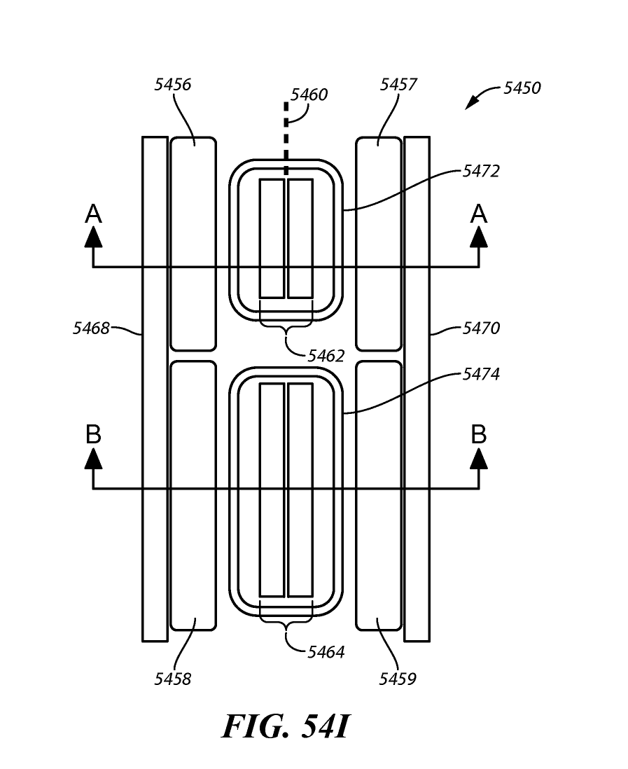

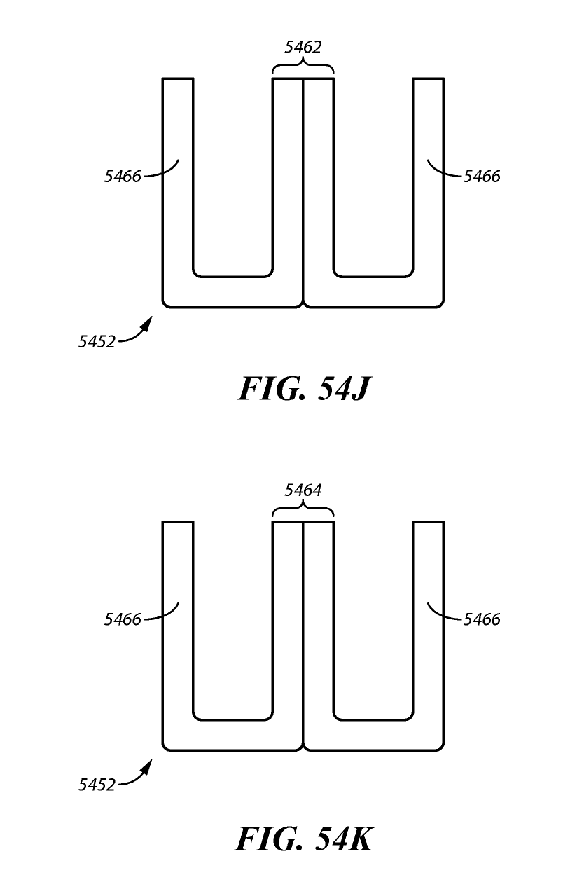

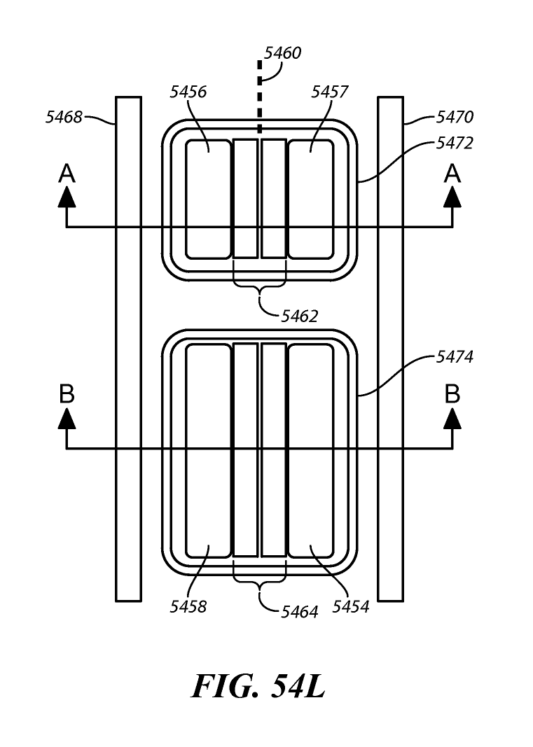

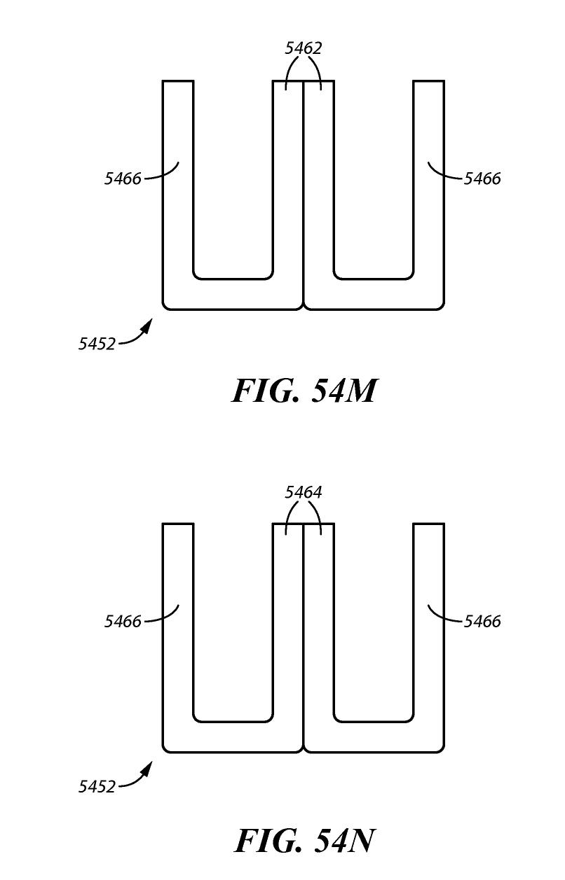

Referring now specifically to FIGS. 54A-54H, one specific example of optical motor apparatus 5400 is described. The motor apparatus 5400 includes a magnetic circuit return structure 5402 that is formed with a central portion 5404 and an outer portion 5406. The outer portion 5406 includes a first wall portion 5408 and a second wall portion 5410. A flex harness 5411 is an interface by which electrical current is supplied to the coils (described below). The flex harness 5411 may also contain thermal sensors, movement sensors, actuator driving chips, connectors and other components.

The central portion 5404 is disposed between the first wall portion 5408 and the second wall portion 5410. A first coil 5412 extends around a first portion 5414 of the central portion 5404 and a second coil 5416 extends around a second portion 5418 of the central portion 5404. A first magnet 5420 is disposed between the first wall portion 5408 and the first coil 5412. The first magnet 5420 is also disposed between the first wall portion 5408 and the second coil 5416. A second magnet 5422 is disposed between the second wall portion 5410 and the first coil 5412. The second magnet 5422 is also disposed between the second wall portion 5410 and the second coil 5416.

A first piston 5430 is at least partially movably disposed within the first coil 5412. A second piston 5432 is at least partially movably disposed within the second coil 5416. A first electrical current applied to the first coil 5412 produces a first force to produce a first movement of the first piston 5430. The first movement of the first piston 5430 is effective to move a first membrane or actuator seal that communicates with a first reservoir. Movement of the first membrane is effective to create an exchange of fluid between the first reservoir and a first deformable optical lens.

A second electrical current applied to the second coil 5416 produces a second force to produce a second movement of the second piston 5432. The second movement of the second piston 5432 is effective to move a second membrane or actuator seal that communicates with a second reservoir 5440. Movement of the second membrane is effective to create an exchange of fluid between the second reservoir and a second deformable optical lens.

A plane 5413 extends through the structure. Magnetic flux paths 5415 and 5417. Each motor may be mounted to another assembly by springs 5419, or by a spring coil 5421 and bobbin 5423.

Referring now to FIGS. 54F-N, various topologies of a pump having one or more motors are described. These figures include top views of the pump/motor (as well as side views of the magnetic return structure or yoke) and show various arrangements of the components. Other arrangements are possible. The magnetic return structure or yoke made from a magnetically soft material. These could include steels, nickel-irons, or nickel cobalt materials to mention a few examples.

Referring now to FIG. 54F, the apparatus 5450 includes a yoke (magnetic return structure) 5452, a first magnet 5456, and a second magnet 5458. A plane 5460 bisects the structure 5450. The yoke 5452 has a first central portion 5462 and a second central portion 5464. The yoke 5452 has an outer portion 5466 including a first wall 5468 and a second wall 5470. A first coil 5472 surrounds the first central portion 5462 and a second coil surrounds the second central portion 5464. The structure 5400 is symmetric about the plane 5460. In this example, the yoke 5452 is formed as a single piece. The structure can be two pieces with made from separate U-shaped elements. The structure can be a single piece. The structure can have the outer surfaces formed as the large wide U-shape, and the central piece being a separate piece. Many structures are possible for creating two gaps on the inside the structure. FIG. 54G shows a cross section of the apparatus of FIG. 54F along line A-A, while FIG. 54H shows a cross section of the apparatus of FIG. 54F along line B-B.

Referring now to FIG. 54I, the apparatus 5450 includes a yoke (magnetic return structure) 5452, a first magnet 5456, a second magnet 5457, a third magnet 5458, and a fourth magnet 5459. A plane 5460 bisects the structure 5450. The yoke 5452 has a first central portion 5462 and a second central portion 5464. The yoke 5452 has an outer portion 5466 including a first wall 5468 and a second wall 5470. A first coil 5472 surrounds the first central portion 5462 and a second coil surrounds the second central portion 5464. In this example, the yoke 5452 is formed of two pieces that are attached together (e.g., via glue, welding, or some other attachment procedure). FIG. 54J shows a cross section of the apparatus of FIG. 54I along line A-A, while FIG. 54K shows a cross section of the apparatus of FIG. 54I along line B-B.

Referring now to FIG. 54L, the apparatus 5450 includes a yoke (magnetic return structure) 5452, a first magnet 5456, a second magnet 5457, a third magnet 5458, and a fourth magnet 5459. A plane 5460 bisects the structure 5450. The yoke 5452 has a first central portion 5462 and a second central portion 5464. The yoke 5452 has an outer portion 5466 including a first wall 5468 and a second wall 5470. A first coil 5472 surrounds the first central portion 5462 and a second coil surrounds the second central portion 5464. In this example, the yoke 5452 is formed of two pieces that are attached together (e.g., via glue, welding, or some other attachment procedure). Compared to the example of FIGS. 54I-K, the coil is disposed outside the magnets. FIG. 54M shows a cross section of the apparatus of FIG. 54L along line A-A, while FIG. 54N shows a cross section of the apparatus of FIG. 54L along line B-B.

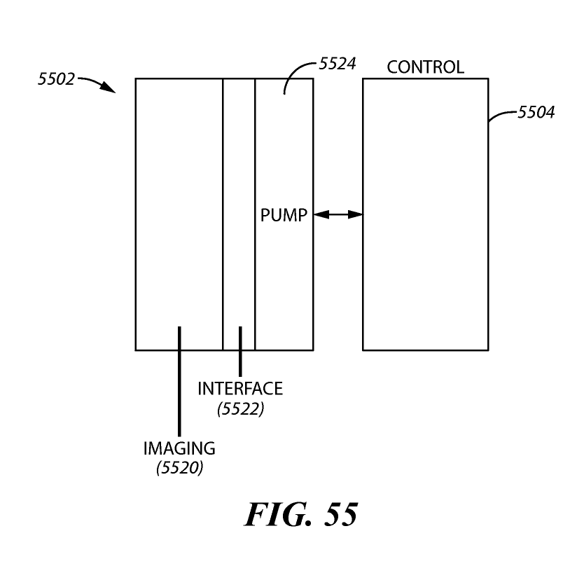

Referring now to FIG. 55, one example of an optical system 5500 is described. A camera module 5502 is coupled to control systems 5504. The control systems 5504 may be implemented in software internal to the camera module 5502 and/or external to the camera module 5502. The camera module 5502 includes all optics, motors, connectors and so forth. The camera module 5502 includes an imaging portion 5520, an interface portion 5522, and a pump portion 5524.

The imaging portion 5520 includes all components within the optical housing and the barrel. It includes all optical parts that are used to form an image. In one aspect, it includes the deformable optical lenses (barrels, fluid, fixed rigid lens, lens shaper, and membrane), the optical housing, other fixed rigid lenses, apertures, sensors, sensor housings, and cover glasses.

The interface portion 5522 includes the surround structures, elastomeric pads, contacts to other portions, and fluid. The pump portion 5524 includes motors (e.g., coils, magnets, magnetic return structure) to convert electrical energy into mechanical force and an actuator (e.g., piston) that moves. Movement of the actuator moves fluid (e.g., by moving a seal or membrane, which when moves liquid through a channel to a deformable optical lens).

In many of these embodiments, a deformable optical lens with a lens membrane has an optically active portion that is configured to be shaped over an air-membrane interface according to a spherical cap and Zernike polynomials. The spherical cap and the Zernike polynomials comprise a Zernike[4,0], (Noll[11]) polynomial and are sufficient to model the deformable optical lens to within approximately 2 micrometers.

In other aspects, the Zernike polynomials further comprise a Zernike[0,0], (Noll[1]) polynomial. In other examples, the Zernike polynomials further comprise a Zernike[2,0], (Noll[4]) polynomial.

In other examples, the Zernike polynomial has a normalized radial position equal to 1 when the radial position of the lens membrane equals the radius of the lens shaper.

In others of these embodiments, a deformable optical lens with a lens membrane has an optically active portion that is configured to be shaped over an air-membrane interface according to only a spherical cap and certain selected Zernike polynomials.

In one example, only a Spherical Cap, Zernike[0,0], (Noll[1]), Zernike[2,0], (Noll[4]), and Zernike[4,0], (Noll[11]) polynomials are sufficient to model the shape of the lens within 2 microns.

In another example, the Zernike polynomials comprise only a Spherical Cap, Zernike[0,0], (Noll[1]), and Zernike[4,0], (Noll[11]) polynomial and are sufficient to model the deformable optical lens to within approximately 2 micrometers.

In another example, if only concerned about the curvature of the lens and not its z-axis placement, the Zernike polynomials comprise only a Spherical Cap, and Zernike[4,0], (Noll[11]) polynomial and are sufficient to model the deformable optical lens to within approximately 2 micrometers.

Other examples are possible.

In still others of these embodiments, a deformable optical lens with a membrane has an optically active portion that is configured to be shaped according to a spherical cap and a Zernike[4,0] polynomial. The spherical cap has a spherical cap radius, and a magnitude of the Zernike[4,0] polynomial depends upon the spherical cap radius.

In other aspects, the spherical cap and the Zernike[4,0] polynomial are sufficient to model the deformable optical lens to within approximately 2 micrometers. In other examples, a rate of increase of a magnitude of the Zernike[4,0], (Noll[11]) polynomial depends upon a lens shaper edge diameter.

In others of these embodiments, a deformable optical lens subsystem includes a lens shaper with a well-defined lens shaper edge; a fixed solid lens concentric with the well-defined lens shaper edge; a barrel aligning the fixed sold lens; and a deformable lens membrane that is directly attached to the lens shaper in the absence of an adhesive, but allowing for an auxiliary chemical.

In some aspects, the lens shaper is comprised of silicon and the deformable lens membrane is comprised of siloxane. In other aspects, the lens shaper includes a layer of silicon dioxide.

In other examples, the deformable lens membrane includes an optically active portion that is configured to be shaped over an air-membrane interface according to a spherical cap and Zernike polynomials. The spherical cap and the Zernike polynomials comprise Zernike[0,0], (Noll[1]), Zernike[2,0], (Noll[4]), and Zernike[4,0], (Noll[11]) polynomials and are sufficient to model the deformable optical lens to within approximately 2 micrometers.

In other aspects, the barrel is formed into either the lens shaper or the fixed solid lens. In other examples, the diameter of well defined lens shaper edge is between 1 mm and 10 mm.

In still other examples, the deformable optical lens includes an optically active portion that is configured to be shaped according to a spherical cap and a Zernike[4,0] polynomial. The spherical cap has a spherical cap radius, a magnitude of the Zernike[4,0] polynomial depends upon the spherical cap radius.

In yet other examples, the lens shaper is constructed of a metalloid, metal, metal and metalloid alloys, metal and metalloid oxides, sulfide, nitride, phosphide, boride, glass or plastic material. In other examples, a rate of increase of a magnitude of the Zernike[4,0], (Noll[11]) polynomial depends upon a lens shaper edge diameter. In other aspects, the lens is bonded without an adhesive such that the lens can be tuned into a concave shape without losing contact with the lens shaper.

In others of these embodiments, a deformable optical lens subsystem includes: a lens shaper; and a deformable lens membrane that is indirectly attached to the lens shaper with the use of an intermediate material. The lens shaper is comprised of silicon and the deformable lens membrane is comprised of siloxane. The deformable lens membrane includes an optically active portion that is configured to be shaped over an air-membrane interface according to a spherical cap and Zernike polynomials wherein the spherical cap and the Zernike polynomials comprise a Zernike[4,0], (Noll[11]) polynomial and are sufficient to model the deformable optical lens to within approximately 2 micrometers.

In other aspects, the Zernike polynomials further comprise a Zernike[0,0], (Noll[1]) polynomial. In still other examples, the Zernike polynomials further comprise a Zernike[2,0], (Noll[4]) polynomial.

In yet other aspects, the deformable optical membrane includes an optically active portion that is configured to be shaped according to a spherical cap and a Zernike[4,0], polynomial. The spherical cap has a spherical cap radius, and a magnitude of the Zernike[4,0] polynomial depends upon the spherical cap radius.

In other examples, the spherical cap and the Zernike[4,0] polynomial are sufficient to model the deformable optical lens to within approximately 2 micrometers. In other aspects, a rate of increase of a magnitude of the Zernike[4,0], (Noll[11]) polynomial depends upon a lens shaper edge diameter.

In still others of these embodiments a deformable optical lens with a membrane that is configured to be shaped according to at least one Zernike polynomial is provided. The Zernike polynomials comprise a Zernike[4,0], (Noll[11]) polynomial. The two Zernike polynomials are used to provide a model of the deformable optical lens to within approximately 2 micrometers. The model of the deformable optical lens is used to configure at least a first fixed lens to serve in combination with the deformable optical lens.

In other aspects, the model of the deformable optical lens is used to configure at least a second fixed lens to serve in combination with the first fixed lens. In other examples, the at least one Zernike polynomial further comprises a Zernike[0,0], (Noll[1]) polynomial. In other examples, the at least one Zernike polynomial further comprises a Zernike[2,0], (Noll[4]) polynomial.

In yet others of these embodiments, a deformable optical lens includes: a deformable membrane having an index of refraction of about 1.4, where the membrane includes an optically active portion that is configured to be shaped over an air-membrane interface according to a spherical cap and Zernike polynomials, and where the spherical cap and the Zernike polynomials comprise a Zernike[4,0], (Noll[11]) polynomial and are sufficient to model the deformable optical lens to within approximately 2 micrometers; an optical fluid at least partially contained by the deformable membrane and having an index of refraction of between approximately 1.27-1.9, preferably about 1.29-1.6, and specifically about 1.3.

The optical fluid comprises a colorless, fluorinated liquid having a structure selected from the group consisting of: an organic structure, a semi-organic structure, and an inorganic backbone structure.

In other aspects, the optical fluid is selected from the group consisting of: perfluoro(hydro)carbons; perfluorpolyether; siloxanes, and fluorinated side chains. In yet other examples, the optical fluid comprises perfluoropolyether. In other examples, the optical fluid comprises a dispersion fluid.

In others of these embodiments, surface preparation of both a lens shaper and a deformable lens membrane are performed. Optionally, cleaning may also be performed. The deformable lens membrane is directly bonded to the lens shaper without use of third material such as adhesive.

In other aspects, the direct bonding between the deformable lens and the lens shaper occurs via a silicon dioxide layer in the lens shaper. In other examples, the direct bonding utilizes an auxiliary chemical to aid bonding. In other examples, the auxiliary chemical comprises an adhesion promoter or that chemical forms a thin smooth glassy coating to enhance the direct bonding.

In yet other aspects, the deformable lens membrane comprises a first side and a second side, and directly bonding the deformable lens membrane to the lens shaper comprises directly bonding the first side of the deformable lens membrane to the lens shaper, pristinely or treated with an auxiliary chemical.

In yet others of these embodiments, a multi-optical element assembly includes: a first deformable optical lens; a second deformable optical lens; a reflective surface; a folded optical axis defined by the first and second deformable optical lenses and the reflective surface; and an optical path that traverses along the folded optical axis.

In other examples, the reflective surface comprises a mirror, a prism, or an adaptive element. In other aspects, the reflective surface is disposed between the first deformable lens and the second deformable lens. In other examples, the reflective surface is disposed on either side of both the first deformable lens and the second deformable lens.

In still other examples, at least two fixed lenses are disposed between the second deformable optical lens and an image sensor. In other aspects, the first and deformable optical lenses include membranes with optically active portions that are configured to be shaped over a membrane-air interface according to a spherical cap and Zernike polynomials. The spherical cap and the Zernike polynomials comprise a Zernike[4,0], (Noll[11]) polynomial and are sufficient to model the deformable optical lens to within approximately 2 micrometers.

In other examples, the Zernike polynomials further comprise a Zernike[0,0], (Noll[1]) polynomial. In other aspects, the Zernike polynomials further comprise a Zernike[2,0], (Noll[4]) polynomial.

In other examples, the first and second deformable optical lenses are configured to be shaped according to a spherical cap and a Zernike[4,0] polynomial, the spherical cap having a spherical cap radius. A magnitude of the Zernike[4,0] polynomial depends upon the spherical cap radius.

In other aspects, the spherical cap and the Zernike[4,0] polynomial are sufficient to model the deformable optical lens to within approximately 2 micrometers. In other examples, a rate of increase of a magnitude of the Zernike[4,0], (Noll[11]) polynomial depends upon a lens shaper edge diameter.

In others of these embodiments, an optical apparatus includes: a deformable optical lens aligned with an axis that extends through an optical housing and the deformable optical lens, with the deformable optical lens being at least partially enclosed by the optical housing; at least one fluid reservoir at least partially containing a fluid; a surround structure; at least one elastomeric structure, with the elastomeric structure being disposed between the surround structure and the optical housing, the elastomeric structure being in at least partial contact with the optical housing.

The at least one elastomeric structure and the surround structure form at least a portion of a channel through which fluid is exchanged between the at least one fluid reservoir and the deformable optical lens. An arrangement of the surround structure and the at least one elastomeric pad is effective to reduce or prevent thermal energy and mechanical forces from being transferred between an external entity to the deformable optical lens.

In other aspects, a fixed lens is provided and the arrangement of the surround structure and the at least one elastomeric pad is effective to reduce or prevent thermal energy and mechanical forces from being transferred to the fixed lens. In other examples, the surround structure is configured to maintain an alignment of the fixed lens and the deformable optical lens. In other aspects, the entity comprises a pump. In other aspects, the surround structure and the elastomeric structure are molded in a two shot process so as to produce a single part.

In other examples, a pump is provided and is actuated to cause an exchange of fluid between the at least one fluid reservoir and the deformable optical lens. The pump has a pump housing and the pump housing and surround structure are mechanically coupled together.

In other aspects, the housing supports a reaction force from the pump. In other examples, the surround structure and the housing are coupled with an adhesive. In other aspects, a pressure of the fluid is supported at least partially by the surround structure. In other examples, the surround structure forms a portion of the at least one reservoir.

In other aspects, the at least one reservoir comprises a first reservoir and a second reservoir and wherein the surround structure forms at least part of the first reservoir and at least part of the second reservoir. In other examples, the surround structure is constructed of a material allowing a low thermal conductivity.

In other aspects, the pump housing forms a portion of an electromechanical transducer. In other examples, the pump housing is constructed of a magnetically soft material such as steels, nickel-irons, and cobalt-irons material.

In yet other aspects, the elastomeric structure is constructed from a material selected from the group consisting of: siloxane; a foam, and a gel. In other examples, the elastomeric structure allows for the transmission of ultraviolet light.

In still other aspects, the at least one reservoir comprises a first reservoir and a second reservoir. The elastomeric structure forms at least part of the first reservoir and at least part of the second reservoir.

In other examples, the elastomeric structure is constructed of a deformable material. In other aspects, the elastomeric structure comprises a plurality of surfaces and the elastomeric structure is mechanically unrestrained along at least one of the plurality of surfaces.

In other examples, the elastomeric pad is formed as a cuboid. In other aspects, the elastomeric structure comprises pockets to allow for deformation of the elastomeric structure or to lessen transmission of thermal energy to the optical housing. In other examples, stops are placed such as to limit the potential excursion of the pump. In other examples, the elastomeric structure is constructed of a self-healing or self-closing material to allow for a needle injection of optical fluid from the exterior to an interior of the optical apparatus.

In other examples, the elastomeric pad comprises pockets to allow for deformation of the elastomeric structure. In other aspects, the elastomeric structure comprises pockets to less transmission of thermal energy to the optical housing. In other examples, the elastomeric structure is constructed of a self-healing material to allow for a needle injection of optical fluid from the exterior to an interior of the optical apparatus. In other aspects, the elastomeric structure forms part of a channel and is in contact with the fluid. In other examples, the elastomeric structure is constructed from a material with a coefficient of thermal expansion of about 100*10̂6 m/m/c.

In other aspects, the elastomeric structure is constructed from a material with a coefficient of thermal expansion of above 200*10̂6 m/m/c. In other examples, the channel expands much less than in volume under pressure than the fluid that will enter the deformable optical lens under that same pressure, the channel expansion being less than about 10% of the fluid that enters the lens under the same pressure. In other aspects, the channel comprises a silicone tube or a composite tube made of silicone and a more rigid material. The tube has an effective volumetric thermal expansion that is effective to partially compensate for the high thermal expansion of the optical liquid thereby decreasing the amount of extra motor travel required to compensate for said fluid expansion.

In other examples, the at least one reservoir comprises a first reservoir and a second reservoir. The first reservoir and the second reservoir are disposed in the same plane.

In others of these embodiments, an optical apparatus includes: an optical housing having an end; a fixed lens; a first deformable optical lens; a barrel, with the barrel being disposed within the optical housing, and at least one of the fixed lens and the deformable optical lens being disposed at least partially within the barrel; a reflective surface, with the reflective surface mounted to the optical housing; a sensor that is disposed at the end of the optical housing; a sensor axis passing through the sensor and an object axis being arranged at two times the angle of incidence of the sensor axis with the object axis and the sensor axis passing through the reflective surface; an optical path disposed within the optical housing, the optical path following the object axis from an object external to the apparatus to the reflective surface, with the optical path being redirected at the reflective surface and then following the sensor axis to the sensor at the end of the optical housing, and the optical path passing through the deformable optical lens and the fixed lens. The optical housing is configured and arranged to align the deformable optical lens along the sensor axis and align the deformable optical lens in a direction that extends radially outward from the sensor axis.

In other aspects, the barrel and the optical housing are formed integrally together. In other examples, the reflective surface is an element selected from the group consisting of a prism, a mirror, and an adaptive element.

In yet other aspects, the reflective surface comprises a moving element. In other examples, the reflective surface deforms but remains in fixed position relative to other elements of the optical apparatus. In other examples, the optical housing and the barrel form an optical alignment structure, and the optical alignment structure is predominantly symmetric about a plane, the plane extending through the object axis and the sensor axis.

In still other aspects, a second deformable optical lens is provided that is constructed as a separate assembly from the first deformable optical lens. In other examples, the optical path is redirected at the reflective surface at an angle of approximately 90 degrees.

In other examples, a first reservoir and a second reservoir are provided. The first reservoir includes a first actuator seal and the second reservoir includes a second actuator seal, and the first actuator seal and the second actuator seal are substantially in the same plane.

In other examples, a first reservoir and a second reservoir are provided. The first reservoir includes a first actuator seal and the second reservoir includes a second actuator seal. The first actuator seal and the second actuator seal are on the same side of the cutting plane.

In yet other examples, the optical housing includes substantially symmetric fluid openings and such that the surround structure is disposed on opposite sides of the optical housing. In yet other examples, the optical housing is configured such that air in proximity to the first deformable lens follows an opening allowing the air to vent outside of the optical apparatus.

In other aspects, the opening is covered by a filter to prevent contaminants from entering the optical active area of membrane. In other examples, the optical apparatus further includes a second deformable lens. The first deformable lens and the second deformable lens share the same opening.

In other examples, the optical apparatus further includes an actuator seal that is effective to move a first membrane that communicates with the first deformable optical lens. In other aspects, the actuator seal is an element selected from the group consisting of: a membrane, an accordion structure element, a diaphragm, and a channel opening that seals when the viscosity of the fluid is too great to flow through the seal.

In still others of these embodiments, an optical apparatus includes an optical housing having an end; a fixed lens; a first deformable optical lens; a barrel, with the barrel being disposed within the optical housing, and at least one of the fixed lens and the deformable optical lens being disposed at least partially within the barrel; a reflective surface, with the reflective surface mounted to the optical housing; a sensor disposed at the end of the optical housing; a sensor axis passing through the sensor and an object axis being arranged in non-parallel relation to the sensor axis, the object axis and the sensor axis passing through the reflective surface; an optical path disposed within the optical housing, with the optical path following the object axis from an object external to the apparatus to the reflective surface, the optical path then following the sensor axis to the sensor at the end of the optical housing, the optical path passing through the deformable optical lens and the fixed lens. The optical housing is configured and arranged to align the deformable optical lens along the sensor axis and align the deformable optical lens in a direction that extends radially outward from the sensor axis.

In other aspects, the barrel and the optical housing are formed integrally together. In other examples, the reflective surface comprises an element selected from the group consisting of a prism, a mirror, and an adaptive element. In still other examples, the reflective surface comprises a moving element. In other examples, the reflective surface deforms but remains in fixed position relative to other elements of the optical apparatus.

In other aspects, the optical housing and the barrel form an optical alignment structure, and the optical alignment structure is predominantly symmetric about a plane. The plane extends through the object axis and the sensor axis.

In other examples, the optical apparatus further includes a second deformable optical lens than is constructed as a separate assembly from the first deformable optical lens. In other aspects, the optical path is redirected at the reflective surface at an angle of approximately 90 degrees.

In yet others of these embodiments, an optical apparatus includes: an optical housing; a reflector disposed in the optical housing; a deformable optical lens having a membrane and a lens shaper, a fluid and barrel the lens shaper; a lens shaper having defining a well-defined lens shaper edge, with the well-defined lens shaper edge being generally in a plane with a deformable optical lens axis centered to the edge and normal to the plane; a barrel in contact with the optical housing; an image object outside of the optical apparatus; and an optical path that extends from the image object to the reflector and from the reflector to a sensor.

In some aspects, the barrel and optical housing contact the other at a predetermined and a limited number of contact points provide a alignment of the deformable optical lens axis to the optical path. In other examples, the contact points are arranged to effect change of position along the optical path. In yet other examples, the contact points are separated angularly about the axis.

In other examples, the lens shaper comprises an inside surface and the inside surface is scalloped to scatter light. In other aspects, the membrane forms a membrane-air boundary on one side and a membrane-fluid boundary on another side, and the membrane is smoother at the membrane-air boundary than at the membrane-fluid boundary to minimize scattered light.

In other examples, the membrane has a smooth side and a rougher side and the smooth side is attached to the lens shaper. In still other examples, the lens shaper is constructed of a non-plastic material. In some other examples, the non-plastic material comprises steel or silicon.

In other aspects, the lens shaper further comprises a coating. In other examples, the lens shaper comprises an aperture or baffle. In still other aspects, the optical apparatus further includes a first actuator seal and a second actuator seal. The first actuator seal is in communication with the deformable optical lens through a first fluid, and the second actuator seal is in communication with a second deformable optical lens through a second fluid. In other aspects, the first and second actuator seals are molded into a roll structure.

In other examples, the first and second actuator seals are substantially flat when not subject to fluid pressure. In some aspects, the fluid is under pressure in the powered off state of the optical apparatus. In other aspects, the first and second actuator seals are curved when in the powered off state of the optical apparatus.

In others of these embodiments, an optical apparatus includes an optical housing having an end; a fixed lens; a first deformable optical lens; a second deformable optical lens; at least one barrel, with the at least barrel being disposed within the optical housing, with the first deformable optical lens and the second deformable optical lens being disposed at least partially within the at least one barrel; a first reflective surface, the reflective surface mounted to the optical housing; a sensor disposed at the end of the optical housing; a sensor axis passing through the sensor and an object axis being arranged at two times the angle of incidence of the sensor axis and a reflective surface, the object axis and the sensor axis co-located at the reflective surface; an optical path disposed within the optical housing, the optical path following the object axis from an object external to the apparatus to the reflective surface, the optical path being redirected at the reflective surface and then following the sensor axis to the sensor at the end of the optical housing, the optical path passing through the deformable optical lens and the fixed lens.

In other examples, the optical apparatus further includes a first pump and a second pump. The first pump moves first fluid from a first reservoir into the first deformable optical lens, and the second pump moves second fluid from a second reservoir to the second deformable optical lens.

In other aspects, the first deformable optical lens includes a membrane. In some examples, the membrane includes an optically active portion that is configured to be shaped over an air-membrane interface according to a spherical cap and Zernike polynomials. The spherical cap and the Zernike polynomials comprise a Zernike[4,0], (Noll[11]) polynomial and are sufficient to model the membrane to within approximately 2 micrometers.

In other aspects, the Zernike polynomials further comprise a Zernike[0,0], (Noll[1]) polynomial. In other examples, the Zernike polynomials further comprise a Zernike[2,0], (Noll[4]) polynomial.

In yet other examples, the membrane includes an optically active portion that is configured to be shaped according to a spherical cap and a Zernike[4,0], polynomial. The spherical cap has a spherical cap radius, and a magnitude of the Zernike[4,0] polynomial depends upon the spherical cap radius.

In still other examples, the spherical cap and Zernike[4,0] polynomial are sufficient to model the membrane to within approximately 2 micrometers. In other aspects, a rate of increase of a magnitude of the Zernike[4,0], (Noll[11]) polynomial depends upon a lens shaper edge diameter.

In other examples, the first deformable optical lens includes a membrane, and the membrane is controlled to assume any non-spherical shape. In other examples, the first reflective surface is an element selected from the group consisting of a prism, a mirror, and an adaptive element.

In other aspects, the optical path is redirected at the first reflective surface at an angle of approximately 90 degrees. In other examples, the optical apparatus further includes a second reflective surface, the second reflective surface being disposed at the end of the optical housing.

In still other examples, the first deformable lens comprises a first membrane and the second deformable lens comprises a second membrane. The first membrane and the second membrane are configurable to assume a plurality of convex shapes and concave shapes.

In yet others of these embodiments, an optical apparatus includes: an optical housing having an end; a fixed lens; a first deformable optical lens; a second deformable optical lens; at least one barrel, with the at least barrel being disposed within the optical housing, the first deformable optical lens and the second deformable optical lens being disposed at least partially within the at least one barrel; a first reflective surface, the reflective surface mounted to the optical housing; a sensor disposed at the end of the optical housing; a sensor axis passing through the sensor and an object axis being arranged in non-parallel relation to the other, the object axis and the sensor axis passing through the reflective surface; an optical path disposed within the optical housing, the optical path following the object axis from an object external to the apparatus to the reflective surface, the optical path then following the sensor axis to the sensor at the end of the optical housing, with the optical path passing through the deformable optical lens and the fixed lens.

In some examples, the optical apparatus further includes a first pump and a second pump. The first pump moves first fluid from a first reservoir into the first deformable optical lens, and the second pump moves second fluid from a second reservoir to the second deformable optical lens.

In other aspects, the first deformable optical lens includes a membrane. In some examples, the membrane includes an optically active portion that is configured to be shapeable over an air-membrane interface according to a spherical cap and Zernike polynomials. The spherical cap and the Zernike polynomials comprise a Zernike[4,0], (Noll[11]) polynomial and are sufficient to model the membrane to within approximately 2 micrometers.

In some examples, the Zernike polynomials further comprise a Zernike[0,0], (Noll[1]) polynomial. In other examples, the Zernike polynomials further comprise a Zernike[2,0], (Noll[4]) polynomial.

In some examples, the membrane has an optically active portion that is configured to be shaped according to a spherical cap and a Zernike[4,0], polynomial with the spherical cap having a spherical cap radius. A magnitude of the Zernike[4,0] polynomial depends upon the spherical cap radius.

In some examples, the spherical cap and the Zernike[4,0] polynomial are sufficient to model the membrane to within approximately 2 micrometers. In other examples, a rate of increase of a magnitude of the Zernike[4,0], (Noll[11]) polynomial depends upon a lens shaper edge diameter.

In other examples, the first deformable optical lens includes a membrane, and the membrane is controlled to assume any non-spherical shape. In other examples, the first reflective surface is an element selected from the group consisting of a prism, a mirror, and an adaptive element.

In other examples, the optical path is redirected at the first reflective surface at an angle of approximately 90 degrees. In still other examples, the optical apparatus includes a second reflective surface. The second reflective surface is disposed at the end of the optical housing. In yet other examples, the first deformable lens comprises a first membrane and the second deformable lens comprises a second membrane. The first membrane and the second membrane are configurable to assume a plurality of convex shapes and concave shapes.

In yet others of these embodiments, an optical apparatus includes: an axis; an optical portion including at least one deformable optical lens arranged about the axis; a pump portion, the pump portion configured to actuate the at least one deformable lens, the pump portion arranged about the axis.

In some examples, the pump portion is disposed on one side of the optical portion. In other examples, the pump portion comprises a first part and a second part, and optical portion is disposed between the first part and the second part.

In still others of these embodiments, an optical apparatus includes: a pump portion; an optical portion, with the optical portion comprising an optical housing, a first deformable optical lens and a second deformable optical lens disposed within the optical housing, a reflective surface disposed within the optical housing, a sensor disposed at an end of the optical housing. The pump portion is configured to cause a fluid exchange between at least one fluid reservoir and the first deformable optical lens and between the at least one fluid reservoir and the second deformable optical lens and an axis. The pump portion and the optical portion are arranged about the axis, such that the axis intersects portions of the pump.

In other aspects, the pump portion is disposed on one side of the optical portion. In yet other examples, the pump portion comprises a first part and a second part, and optical portion is disposed between the first part and the second part. In other aspects, the at least one reservoir comprises a first reservoir and a second reservoir, and the first reservoir and the second reservoir being disposed in the same plane.

In other examples, the at least one fluid channel is formed and extends along a first side portion of the pump portion and a second side portion of the optical portion in a direction generally parallel to the axis. The at least one fluid channel is configured to allow exchange of fluid between the at least one reservoir and the first deformable lens, and between the at least one reservoir and the second deformable lens.

In other examples, the at least one fluid channel is formed from a first material portion and a second material portion. In other aspects, the first material portion comprises a different material from the second material portion.

In other examples, the at least one fluid channel comprises a tube-like structure. The tube-like structure is constructed of a material that minimizes or eliminates the effects of thermal fluid expansion.

In other aspects, the at least one reservoir comprises a first reservoir and a second reservoir. A first movement of fluid from the first reservoir to the first deformable optical lens meets less fluid resistance than a second movement of fluid from the second reservoir to the second deformable optical lens.

In still others of these embodiments, an optical apparatus includes a deformable optical lens with a first axis extending there through; a fixed lens having a second axis extending there through; a sensor with a third axis extending there through; an optical path that follows along the first axis, the second axis, and the third axis. The first axis, the second axis, and the third axis are automatically aligned so as to improve an image quality of an image that follows the optical path to the sensor.

In some examples, the first axis, the second axis, and the third axis are automatically aligned with an optical path of images. In other aspects, the first axis, the second axis, and the third axis are automatically aligned in a direction radially outward from an optical path of images.

In still others of these embodiments, an optical apparatus includes: a deformable optical lens with a first axis extending there through; a sensor with a second axis extending there through; a fixed lens having a third axis extending there through; an optical path that follows along the first axis and the second axis, a reflective surface being aligned with the first axis, the second axis. The first axis, the second axis, and/or the third axis are automatically aligned so as to improve an image quality of an image that follows the optical path to the sensor.

In other examples, the angle between the first axis, and the second axis, is automatically varied to improve the image quality. In other aspects, the optical apparatus of claim 160, the third axis are automatically aligned in a direction radially outward from an optical path of images.

In others of these embodiments, an optical apparatus, includes an optical housing with an end; a solid lens disposed within the optical housing; a deformable optical lens disposed within the optical housing; a sensor coupled to the end of the optical housing; a sensor axis passing through the sensor and an object axis being arranged at two times the angle of incidence of the sensor axis, the object axis and the sensor axis passing through the reflective surface. At least one of the reflective surface, the sensor, solid lens, or the deformable optical lens are movable or adjustable so as to improve an image quality of an image that follows the optical path to the sensor.

In other examples, the optical apparatus further includes a barrel. The barrel is disposed within the optical housing, and the deformable optical lens is disposed at least partially within the barrel. In other aspects, the optical apparatus further includes a reflective surface. The reflective surface is mounted to the optical housing. In other examples, the reflective surface comprises an element selected from the group consisting of a prism, a mirror, and an adaptive element.

In other examples, an optical path is disposed within the optical housing. The optical path follows the object axis from an object external to the apparatus to the reflective surface. The optical path is redirected at the reflective surface and then follows the sensor axis to the sensor at the end of the optical housing, the optical path passing through the deformable optical lens and the fixed lens.

In others of these embodiments, a pump includes a magnetic circuit return structure, a first coil, a second coil, a first actuator, and a second actuator. The magnetic circuit return structure has a central portion and an outer portion. The outer portion includes a first wall portion and a second wall portion and the central portion is disposed between the first wall portion and the second wall portion. The first coil extends around a first portion of the central portion and a second coil extends around a second portion of the central portion. a first electrical current applied to the first coil produces a first force to produce a first movement of the first actuator, the first movement of the first actuator communicating with a first deformable optical lens. A second electrical current applied to the second coil produces a second force to produce a second movement of the second actuator, the second movement of the second actuator effective to move a second membrane that communicates with a second deformable optical lens.

In other aspects, the pump further includes a first actuator seal that is effective to move a first membrane that communicates with the first deformable optical lens. In other examples, the actuator seal is an element selected from the group consisting of: a membrane, an accordion structure element, a diaphragm, and a channel opening that seals when the viscosity of the fluid is too great to flow through the seal. In still other examples, the first actuator and the second actuator are piston-like structures.

In yet other aspects, the first actuator and the second actuator are generally circular in a plane parallel to the actuator seal. In still other examples, the first magnet and the second magnet are polarized towards the central portion. In other aspects, the first magnet and the second magnet are polarized away from the central portion. In still other examples, the first magnet overhangs the first wall portion. In other aspects, the first magnet is disposed between the first wall portion and the first coil, the first magnet also disposed between the first wall portion and the second coil and wherein the second magnet is disposed between the second wall portion and the first coil, the second magnet also disposed between the second wall portion and the second coil.

In others of these embodiments, an optical apparatus an optical housing with an end; a fixed lens and a deformable optical lens; a reflective surface, the reflective surface mounted to the optical housing; a sensor disposed at the end of the optical housing; a sensor axis passing through the sensor and the reflective surface, and an object axis being generally perpendicular to the sensor axis and passing through the reflective surface; and an optical path disposed within the optical housing, the optical path following the object axis from an object external to the apparatus to the reflective surface, the optical path being redirected at the reflective surface and then following the sensor axis to the sensor at the end of the optical housing, the optical path passing through the deformable optical lens and the fixed lens.

The optical housing comprises: a first portion, with the first portion including a first interface at a first end of the first portion; a second portion, with the second portion being non-integral with the first portion and including a second interface at a second end of the second portion. The first interface couples and mates to the second interface such that an alignment of the first portion with respect to the second portion is achieved.

In other examples, the reflective surface comprises an element selected from the group consisting of a prism, a mirror, and an adaptive element. In other aspects, the optical path is redirected at the reflective surface at an angle of approximately 90 degrees. In other examples, the interface comprises a first flange on the first portion and a second flange on the second portion.

In still other aspects, the interface comprises an alignment feature on the first portion. In other examples, a barrel is disposed within the first portion or the second portion. In yet other examples, the barrel holds the deformable optical lens. In still other examples, the barrel holds the fixed lens.

In others of these embodiments, an optical apparatus, the apparatus includes an optical housing with an end; a fixed lens and a deformable optical lens; a reflective surface, the reflective surface mounted to the optical housing; a sensor disposed at the end of the optical housing; a sensor axis passing through the sensor and the reflective surface, and an object axis being arranged in non-parallel relation to the sensor axis and passing through the reflective surface; and an optical path disposed within the optical housing, the optical path following the object axis from an object external to the apparatus to the reflective surface, the optical path then following the sensor axis to the sensor at the end of the optical housing, the optical path passing through the deformable optical lens and the fixed lens.

The optical housing includes: a first portion, with the first portion including a first interface at a first end of the first portion; a second portion, with the second portion being non-integral with the first portion and including a second interface at a second end of the second portion. The first interface couples and mates to the second interface such that an alignment of the first portion with respect to the second portion is achieved.

In other aspects, the reflective surface comprises an element selected from the group consisting of a prism, a mirror, and an adaptive element. In other examples, the optical path is redirected at the reflective surface at an angle of approximately 90 degrees. In other aspects, the second portion is disposed predominantly inside the first portion. In other examples, the interface comprises a first flange on the first portion and a second flange on the second portion.

In other examples, the interface comprises an alignment feature on the first portion. In yet other aspects, a barrel disposed within the first portion or the second portion. In other examples, each of the first portion and the second portion includes a deformable optical lens. In yet other examples, the barrel holds the deformable optical lens. In other aspects, the barrel holds the fixed lens.

In others of these embodiments, an optical apparatus includes a first deformable optical lens. The first deformable optical lens includes a lens shaper. The barrel is disposed within the optical housing and the deformable optical lens is disposed at least partially within the barrel. A first set of contact points is disposed between the lens shaper and the barrel. A second set of contact points is disposed between the barrel and the optical housing. The first set of contact points is separated from a second set of contact points by a distance. The distance is sufficient to allow for a mechanical stress or a thermal stress to be at last partially relieved

In other examples, the first set of contact points and the second set of contact points are disposed at a location, the location being selected from the group consisting of the barrel, the optical housing, and the barrel and the optical housing. In other examples, the distance is created by a difference in angular positions of elements. In other examples, the distance is created by a difference in axial positions of elements.

In others of these embodiments, an optical apparatus includes a deformable optical lens. The deformable optical lens has a membrane, a fluid and barrel. The lens shaper has a top surface, an inside surface, and an outside surface. A well defined lens shaper edge is disposed at the intersection of the inside surface, and the top surface. The lens shaper edge is generally in a plane with a deformable optical lens axis centered to the edge and normal to the plane. The inside surface of the lens shaper surrounds the deformable optical lens axis. The outside surface of the lens shaper surrounds the inside surface and the membrane is under tension and bonded to the top surface. An outside edge is formed by the top surface and the outside surface and the membrane is cut so that it is substantially inside the outside edge.

In other aspects, the lens shaper includes a bottom surface, and the bottom surface has an area that is less than the top surface. In other examples, the inside surface is scalloped. In other aspects, the largest diameter of the outside surface is at the outside edge. In other examples, the inside edge and the outside edge are concentric. The outside surface is configured to align the barrel to the axis.

In some examples, the membrane extends to the outside edge of the lens shaper and the membrane has a top surface and a bottom surface. In other examples, the bottom surface of the membrane is bonded to the top surface of the lens shaper and the top surface of the membrane is a smaller area than the bottom surface of the membrane.

In yet other examples, the membrane is cut so that it does not reach the outer edge of the lens shaper. The well-defined ledge shaper edge restrains the membrane as the fluid is pressurized and the membrane is deflected. The deflected membrane is axisymmetric to the axis.

Preferred embodiments of this invention are described herein, including the best mode known to the inventors for carrying out the invention. It should be understood that the illustrated embodiments are exemplary only, and should not be taken as limiting the scope of the invention. As but one example in these regards, the use of Zernike polynomial representations to describe a particular lens shape is but one approach in these regards; the present teachings will readily accommodate other approaches (such as other mathematical approaches) to describe a particular lens shape in support of the foregoing and to then support achieving that lens shape through the appropriate selection of materials, process controls, and precision application of the membrane to the lens shaper.

What is claimed is:

1. A deformable optical lens with a lens membrane having an optically active portion that is configured to be shaped over an air-membrane interface according to a spherical cap and Zernike polynomials, wherein the spherical cap and the Zernike polynomials comprise a Zernike[4,0], (Noll[11]) polynomial and are sufficient to model the deformable optical lens to within approximately 2 micrometers.

2. The deformable optical lens of claim 1 wherein the Zernike polynomials further comprise a Zernike[0,0], (Noll[1]) polynomial.

3. The deformable optical lens of claim 2 wherein the Zernike polynomials further comprise a Zernike[2,0], (Noll[4]) polynomial.

4. The deformable optical lens of claim 1, wherein the Zernike polynomial has a normalized radial position equal to 1 when the radial position of the lens membrane equals the radius of the lens shaper.

5. A deformable optical lens with a membrane having an optically active portion that is configured to be shaped according to a spherical cap and a Zernike[4,0] polynomial, the spherical cap having a spherical cap radius, and wherein a magnitude of the Zernike[4,0] polynomial depends upon the spherical cap radius.

6. The deformable optical lens of claim 5 wherein the spherical cap and the Zernike[4,0] polynomial are sufficient to model the deformable optical lens to within approximately 2 micrometers.

7. The deformable optical lens of claim 6 wherein a rate of increase of a magnitude of the Zernike[4,0], (Noll[11]) polynomial depends upon a lens shaper edge diameter.

8. A deformable optical lens subsystem comprising:
a lens shaper with a well-defined lens shaper edge;
a fixed solid lens concentric with the well-defined lens shaper edge;
a barrel aligning the fixed sold lens;
a deformable lens membrane that is directly attached to the lens shaper in the absence of an adhesive, but allowing for an auxiliary chemical.

9. The deformable optical lens subsystem of claim 8 wherein the lens shaper is comprised of silicon and the deformable lens membrane is comprised of siloxane.

10. The deformable optical lens subsystem of claim 9 wherein the lens shaper includes a layer of silicon dioxide.

11. The deformable optical lens subsystem of claim 8 wherein the deformable lens membrane includes an optically active portion that is configured to be shaped over an air-membrane interface according to a spherical cap and Zernike polynomials, wherein the spherical cap and the Zernike polynomials comprise Zernike[0,0], (Noll[1]), Zernike[2,0], (Noll[4]), and Zernike[4,0], (Noll[11]) polynomials and are sufficient to model the deformable optical lens to within approximately 2 micrometers.

12. The deformable optical lens subsystem of claim 8 wherein the barrel is formed into either the lens shaper or the fixed solid lens.

13. The deformable optical lens subsystem of claim 8 were the diameter of well defined lens shaper edge is between 1 mm and 10 mm.

14. The deformable optical lens subsystem of claim 8 wherein the deformable optical lens includes an optically active portion that is configured to be shaped according to a spherical cap and a Zernike[4,0] polynomial, the spherical cap having a spherical cap radius, and wherein a magnitude of the Zernike[4,0] polynomial depends upon the spherical cap radius.

15. The deformable optical lens subsystem of claim 14 wherein the lens shaper is constructed of a metalloid, metal, metal and metalloid alloys, metal and metalloid oxides, phosphide, boride, sulfide, nitride, glass or plastic material.

16. The deformable optical lens subsystem of claim 14 wherein a rate of increase of a magnitude of the Zernike[4,0], (Noll[11]) polynomial depends upon a lens shaper edge diameter.

17. The deformable optical lens subsystem of claim 8 wherein the lens is bonded without an adhesive such that the lens can be tuned into a concave shape without losing contact with the lens shaper.

18. A deformable optical lens subsystem comprising:
a lens shaper;
a deformable lens membrane that is indirectly attached to the lens shaper with the use of an intermediate material;
wherein the lens shaper is comprised of silicon and the deformable lens membrane is comprised of siloxane;
wherein the deformable lens membrane includes an optically active portion that is configured to be shaped over an air-membrane interface according to a spherical cap and Zernike polynomials wherein the spherical cap and the Zernike polynomials comprise a Zernike[4,0], (Noll[11]) polynomial and are sufficient to model the deformable optical lens to within approximately 2 micrometers.

19. The deformable optical lens subsystem of claim 18 wherein the Zernike polynomials further comprise a Zernike[0,0], (Noll[1]) polynomial.

20. The deformable optical lens subsystem of claim 19 wherein the Zernike polynomials further comprise a Zernike[2,0], (Noll[4]) polynomial.

21. The deformable optical lens subsystem of claim 18 wherein the deformable optical membrane includes an optically active portion that is configured to be shaped according to a spherical cap and a Zernike[4,0], polynomial, the spherical cap having a spherical cap radius, and wherein a magnitude of the Zernike[4,0] polynomial depends upon the spherical cap radius.

22. The deformable optical lens subsystem of claim 21 wherein the spherical cap and the Zernike[4,0] polynomial are sufficient to model the deformable optical lens to within approximately 2 micrometers.

23. The deformable optical lens subsystem of claim 22 wherein a rate of increase of a magnitude of the Zernike[4,0], (Noll[11]) polynomial depends upon a lens shaper edge diameter.

24. A method comprising:
providing a deformable optical lens with a membrane that is configured to be shaped according to at least one Zernike polynomial, the Zernike polynomials comprising a Zernike[4,0], (Noll[11]) polynomial;
using the two Zernike polynomials to provide a model of the deformable optical lens to within approximately 2 micrometers;
using the model of the deformable optical lens to configure at least a first fixed lens to serve in combination with the deformable optical lens.

25. The method of claim 24 further comprising using the model of the deformable optical lens to configure at least a second fixed lens to serve in combination with the first fixed lens.

26. The method of claim 24 wherein the at least one Zernike polynomial further comprises a Zernike[0,0], (Noll[1]) polynomial.

27. The deformable optical lens of claim 26 wherein the at least one Zernike polynomial further comprises a Zernike[2,0], (Noll[4]) polynomial.

28. A deformable optical lens comprising:
a deformable membrane having an index of refraction of about 1.4, wherein the membrane includes an optically active portion that is configured to be shaped over an air-membrane interface according to a spherical cap and Zernike polynomials, wherein the spherical cap and the Zernike polynomials comprise a Zernike[4,0], (Noll[11]) polynomial and are sufficient to model the deformable optical lens to within approximately 2 micrometers;
an optical fluid at least partially contained by the deformable membrane and having an index of refraction of between approximately 1.27-1.9, wherein the optical fluid comprises a colorless, fluorinated liquid having a structure selected from the group consisting of: an organic structure, a semi-organic structure, and an inorganic backbone structure.

29. The deformable optical lens of claim 28 wherein the optical fluid is selected from the group consisting of: perfluoro(hydro)carbons; perfluorpolyether; siloxanes, and fluorinated side chains.

30. The deformable optical lens of claim 28 wherein the optical fluid comprises perfluoropolyether.

31. The deformable optical lens of claim 28 wherein the optical fluid comprises a dispersion fluid.

32. A method comprising:
preparing the surface of both a lens shaper and a deformable lens membrane;
directly bonding the deformable lens membrane to the lens shaper without use of an adhesive.

33. The method of claim 32 wherein the direct bonding between the deformable lens and the lens shaper occurs via a silicon dioxide layer in the lens shaper.

34. The method of claim 32 wherein the lens shaper is constructed of a metalloid, metal, metal and metalloid oxide, sulfide, nitride, glass or plastic material, and the bonding utilizes an auxiliary chemical to aid direct bonding.

35. The method of claim 34 wherein the auxiliary chemical comprises an adhesion promoter or that chemical forms a thin smooth glassy coating to enhance the direct bonding.

36. The method of claim 32 wherein the deformable lens membrane comprises a first side and a second side, and wherein directly bonding the deformable lens membrane to the lens shaper comprises directly bonding the first side of the deformable lens membrane to the lens shaper, pristinely or treated with the auxiliary chemical.

37. A multi-optical element assembly comprising:
a first deformable optical lens;
a second deformable optical lens;
a reflective surface;
a folded optical axis defined by the first and second deformable optical lenses and the reflective surface;
an optical path that traverses along the folded optical axis.

38. The multi-optical element assembly of claim 37, wherein the reflective surface comprises a mirror, a prism, or an adaptive element.

39. The multi-optical element assembly of claim 37, wherein the reflective surface is disposed between the first deformable lens and the second deformable lens.

40. The multi-optical element assembly of claim 37, wherein the reflective surface is disposed on either side of both the first deformable lens and the second deformable lens.

41. The multi-optical element assembly of claim 37 further comprising:
at least two fixed lenses disposed between the second deformable optical lens and an image sensor.

42. The multi-optical element assembly of claim 37 wherein the first and deformable optical lenses include membranes with optically active portions that are configured to be shaped over a membrane-air interface according to a spherical cap and Zernike polynomials wherein the spherical cap and the Zernike polynomials comprise a Zernike[4,0], (Noll[11]) polynomial and are sufficient to model the deformable optical lens to within approximately 2 micrometers.

43. The multi-optical element assembly of claim 42 wherein the Zernike polynomials further comprise a Zernike[0,0], (Noll[1]) polynomial.

44. The multi-optical element assembly of claim 43 wherein the Zernike polynomials further comprise a Zernike[2,0], (Noll[4]) polynomial.

45. The multi-optical element assembly of claim 37 wherein the first and second deformable optical lenses are configured to be shaped according to a spherical cap and a Zernike[4,0] polynomial, the spherical cap having a spherical cap radius, and wherein a magnitude of the Zernike[4,0] polynomial depends upon the spherical cap radius.

46. The multi-optical element assembly of claim 45 wherein the spherical cap and the Zernike[4,0] polynomial are sufficient to model the deformable optical lens to within approximately 2 micrometers.

47. The multi-optical element assembly of claim 46 wherein a rate of increase of a magnitude of the Zernike[4,0], (Noll[11]) polynomial depends upon a lens shaper edge diameter.

48. An optical apparatus, the apparatus comprising:
a deformable optical lens aligned with an axis that extends through an optical housing and the deformable optical lens, the deformable optical lens being at least partially enclosed by the optical housing;
at least one fluid reservoir at least partially containing a fluid;
a surround structure;
at least one elastomeric structure, the elastomeric structure being disposed between the surround structure and the optical housing, the elastomeric structure being in at least partial contact with the optical housing;
wherein the at least one elastomeric structure and the surround structure form at least a portion of a channel through which fluid is exchanged between the at least one fluid reservoir and the deformable optical lens;
such that an arrangement of the surround structure and the at least one elastomeric pad is effective to reduce or prevent thermal energy and mechanical forces from being transferred between an external entity to the deformable optical lens.

49. The optical apparatus of claim 48, further comprising a fixed lens and wherein the arrangement of the surround structure and the at least one elastomeric pad is effective to reduce or prevent thermal energy and mechanical forces from being transferred to the fixed lens.

50. The optical apparatus of claim 48 wherein the surround structure and the elastomeric structure molded in a two shot process so as to produce a single part.

51. The optical apparatus of claim 48, wherein the external entity comprises a pump.

52. The optical apparatus of claim 48, further comprising a pump that is actuated to cause an exchange of fluid between the at least one fluid reservoir and the deformable optical lens, the pump having a pump housing, the pump housing and surround structure being mechanically coupled together.

53. The optical apparatus of claim 52, wherein the housing supports a reaction force from the pump.

54. The optical apparatus of claim 52, wherein the surround structure and the housing are coupled with an adhesive.

55. The optical apparatus of claim 48, wherein a pressure of the fluid is supported at least partially by the surround structure.

56. The optical apparatus of claim 48, wherein the surround structure forms a portion of the at least one reservoir.

57. The optical apparatus of claim 48, wherein the at least one reservoir comprises a first reservoir and a second reservoir and wherein the surround structure forms at least part of the first reservoir and at least part of the second reservoir.

58. The optical apparatus of claim 48, wherein the surround structure is constructed of a material allowing a low thermal conductivity.

59. The optical apparatus of claim 48, wherein the pump housing forms a portion of an electromechanical transducer.

60. The optical apparatus of claim 48, wherein the pump housing is constructed of a magnetically soft material selected from the group consisting of steels, nickel-irons, and cobalt-irons material.

61. The optical apparatus of claim 48, wherein the elastomeric structure is constructed from a material selected from the group consisting of: siloxane; a foam, and a gel.

62. The optical apparatus of claim 48, wherein the elastomeric structure allows for the transmission of ultraviolet light.

63. The optical apparatus of claim 48, wherein the at least one reservoir comprises a first reservoir and a second reservoir, and wherein the elastomeric structure forms at least part of the first reservoir and at least part of the second reservoir.

64. The optical apparatus of claim 48, wherein the elastomeric structure is constructed of a deformable material.

65. The optical apparatus of claim 48, wherein the elastomeric structure comprises a plurality of surfaces and the elastomeric structure is mechanically unrestrained along at least one of the plurality of surfaces.

66. The optical apparatus of claim 48, wherein the elastomeric structure is formed as a cuboid.

67. The optical apparatus of claim 48, wherein the elastomeric structure comprises pockets to allow for deformation of the elastomeric structure or to lessen transmission of thermal energy to the optical housing.

68. The optical apparatus of claim 48, wherein stops are placed such as to limit the potential excursion of the pump.

69. The optical apparatus of claim 48, wherein the elastomeric structure is constructed of a self-healing or self-closing material to allow for a needle injection of optical fluid from the exterior to an interior of the optical apparatus.

70. The optical apparatus of claim 48, wherein the elastomeric structure forms part of a channel and is in contact with the fluid.

71. The optical apparatus of claim 70, wherein the elastomeric structure is constructed from a material with a coefficient of thermal expansion of about 100*10̂6 m/m/c.

72. The optical apparatus of claim 70, wherein the elastomeric structure is constructed from a material with a coefficient of thermal expansion of above 200*10̂6 m/m/c.

73. The optical apparatus of claim 70, wherein the channel expands much less than in volume under pressure than the fluid that will enter the deformable optical lens under that same pressure, the channel expansion being less than about 10% of the fluid that enters the lens under the same pressure.

74. The optical apparatus of claim 70 wherein the channel comprises a silicone tube or a composite tube made of silicone and a more rigid material, the tube having an effective volumetric thermal expansion that is effective to partially compensate for the high thermal expansion of the optical liquid thereby decreasing the amount of extra motor travel required to compensate for the fluid expansion.

75. The optical apparatus of claim 70, wherein the at least one reservoir comprises a first reservoir and a second reservoir, the first reservoir and the second reservoir being disposed in the same plane.

76. An optical apparatus, the apparatus comprising:
an optical housing having an end;
a fixed lens;
a first deformable optical lens;
a barrel, the barrel being disposed within the optical housing, and at least one of the fixed lens and the deformable optical lens being disposed at least partially within the barrel;
a reflective surface, the reflective surface mounted to the optical housing;
a sensor disposed at the end of the optical housing;
a sensor axis passing through the sensor and an object axis being arranged at two times the angle of incidence of the sensor axis, the object axis and the sensor axis passing through the reflective surface;
an optical path disposed within the optical housing, the optical path following the object axis from an object external to the apparatus to the reflective surface, the optical path being redirected at the reflective surface and then following the sensor axis to the sensor at the end of the optical housing, the optical path passing through the deformable optical lens and the fixed lens;
such that the optical housing is configured and arranged to align the deformable optical lens along the sensor axis and align the deformable optical lens in a direction that extends radially outward from the sensor axis.

77. The optical apparatus of claim 76, wherein the barrel and the optical housing are formed integrally together.

78. The optical apparatus of claim 76, wherein the reflective surface is an element selected from the group consisting of a prism, a mirror, and an adaptive element.

79. The optical apparatus of claim 76, wherein the reflective surface comprises a moving element.

80. The optical apparatus of claim 76, wherein the reflective surface deforms but remains in fixed position relative to other elements of the optical apparatus.

81. The optical apparatus of claim 76, wherein the optical housing and the barrel form an optical alignment structure, and wherein the optical alignment structure is predominantly symmetric about a plane, the plane extending through the object axis and the sensor axis.

82. The optical apparatus of claim 76, further comprising a second deformable optical lens than is constructed as a separate assembly from the first deformable optical lens.

83. The optical apparatus of claim 76, wherein the optical path is redirected at the reflective surface at an angle of approximately 90 degrees.

84. The optical apparatus of claim 76, further comprising a first reservoir and a second reservoir, wherein the first reservoir includes a first actuator seal and the second reservoir includes a second actuator seal, and wherein the first actuator seal and the second actuator seal are substantially in the same plane.

85. The optical apparatus of claim 76, further comprising a first reservoir and a second reservoir, wherein the first reservoir includes a first actuator seal and the second reservoir includes a second actuator seal, and wherein the first actuator seal and the second actuator seal are on the same side of the cutting plane.

86. The optical apparatus of claim 76, wherein the optical housing includes substantially symmetric fluid openings and such that the surround structure is disposed on opposite sides of the optical housing.

87. The optical apparatus of claim 76, wherein the optical housing is configured such that air in proximity to the first deformable lens follows an opening allowing the air to vent outside of the optical apparatus.

88. The optical apparatus of claim 87, with the opening is covered by a filter to prevent contaminants from entering the optical active area of membrane.

89. The optical apparatus of claim 87, further comprising a second deformable lens, wherein the first deformable lens and the second deformable lens share the same opening.

90. The optical apparatus of claim 76, further comprising an actuator seal that is effective to move a first membrane that communicates with the first deformable optical lens.

91. The optical apparatus of claim 90, wherein the actuator seal is an element selected from the group consisting of: a membrane, an accordion structure element, a diaphragm, and a channel opening that seals when the viscosity of the fluid is too great to flow through the seal.

92. An optical apparatus, the apparatus comprising:
an optical housing having an end;
a fixed lens;
a first deformable optical lens;
a barrel, the barrel being disposed within the optical housing, and at least one of the fixed lens and the deformable optical lens being disposed at least partially within the barrel;
a reflective surface, the reflective surface mounted to the optical housing;
a sensor disposed at the end of the optical housing;
a sensor axis passing through the sensor and an object axis being arranged in non-parallel relation to the sensor axis, the object axis and the sensor axis passing through the reflective surface;
an optical path disposed within the optical housing, the optical path following the object axis from an object external to the apparatus to the reflective surface, the optical path then following the sensor axis to the sensor at the end of the optical housing, the optical path passing through the deformable optical lens and the fixed lens;
such that the optical housing is configured and arranged to align the deformable optical lens along the sensor axis and align the deformable optical lens in a direction that extends radially outward from the sensor axis.

93. The optical apparatus of claim 92, wherein the barrel and the optical housing are formed integrally together.

94. The optical apparatus of claim 92, wherein the reflective surface comprises an element selected from the group consisting of a prism, a mirror, and an adaptive element.

95. The optical apparatus of claim 92, wherein the reflective surface comprises a moving element.

96. The optical apparatus of claim 92, wherein the reflective surface deforms but remains in fixed position relative to other elements of the optical apparatus.

97. The optical apparatus of claim 92, wherein the optical housing and the barrel form an optical alignment structure, and wherein the optical alignment structure is predominantly symmetric about a plane, the plane extending through the object axis and the sensor axis.

98. The optical apparatus of claim 92, further comprising a second deformable optical lens than is constructed as a separate assembly from the first deformable optical lens.

99. The optical apparatus of claim 92, wherein the optical path is redirected at the reflective surface at an angle of approximately 90 degrees.

100. An optical apparatus, the apparatus comprising:
an optical housing;
a reflector disposed in the optical housing;
a deformable optical lens including a membrane, a lens shaper, a fluid and barrel;
wherein the lens shaper defines a well-defined lens shaper edge, the well-defined lens shaper edge being generally disposed in a plane with a deformable optical lens axis centered to the edge and normal to the plane;
wherein the barrel in contact with the optical housing;
such that an image object is located outside of the optical apparatus;
an optical path that extends from the image object to the reflector and from the reflector to a sensor.

101. The optical apparatus of claim 100 wherein the barrel and optical housing contact the other at a predetermined and limited number of contact points providing a alignment of the deformable optical lens axis to the optical path.

102. The optical apparatus of claim 101, wherein the contact points are arranged to effect change of position along the optical path.

103. The optical apparatus of claim 100, wherein the contact points are separated angularly about the axis.

104. The optical apparatus of claim 100, wherein the lens shaper comprises an inside surface and the inside surface is scalloped to scatter light.

105. The optical apparatus of claim 100, wherein the membrane forms a membrane-air boundary on one side and a membrane-fluid boundary on another side, and the membrane is smoother at the membrane-air boundary than at the membrane-fluid boundary to minimize scattered light.

106. The optical apparatus of claim 100, wherein the membrane has a smooth side, and a rougher side and wherein the smooth side is attached to the lens shaper.

107. The optical apparatus of claim 100, wherein the lens shaper is constructed of a non-plastic material.

108. The optical apparatus of claim 100, wherein the non-plastic material comprises steel or silicon.

109. The optical apparatus of claim 108, wherein the lens shaper further comprises a coating.

110. The optical apparatus of claim 100, wherein the lens shaper further comprises an aperture or baffle.

111. The optical apparatus of claim 100, further comprising a first actuator seal and a second actuator seal, the first actuator seal being in communication with the deformable optical lens through a first fluid, and the second actuator seal being in communication with a second deformable optical lens through a second fluid.

112. The optical apparatus of claim 111, wherein first and second actuator seals are molded into a roll structure.

113. The optical apparatus of claim 111, wherein the first and second actuator seals are substantially flat when not subject to fluid pressure.

114. The optical apparatus of claim 100, wherein the fluid is under pressure in the powered off state of the optical apparatus.

115. The optical apparatus of claim 113, wherein the first and second actuator seals are curved when the optical apparatus is in a powered off state.

116. An optical apparatus, the apparatus comprising:
an optical housing having an end;
a fixed lens;
a first deformable optical lens;
a second deformable optical lens;
at least one barrel, the at least barrel being disposed within the optical housing, the first deformable optical lens and the second deformable optical lens being disposed at least partially within the at least one barrel;
a first reflective surface, the reflective surface mounted to the optical housing;
a sensor disposed at the end of the optical housing;
a sensor axis passing through the sensor and an object axis being arranged at two times the angle of incidence of the sensor axis and a reflective surface, the object axis and the sensor axis co-located at the reflective surface;
an optical path disposed within the optical housing, the optical path following the object axis from an object external to the apparatus to the reflective surface, the optical path being redirected at the reflective surface and then following the sensor axis to the sensor at the end of the optical housing, the optical path passing through the deformable optical lens and the fixed lens.

117. The optical apparatus of claim 116, further comprising a first pump and a second pump, the first pump moving first fluid from a first reservoir into the first deformable optical lens, the second pump moving second fluid from a second reservoir to the second deformable optical lens.

118. The optical apparatus of claim 116, wherein the first deformable optical lens includes a membrane.

119. The optical apparatus of claim 118, wherein the membrane includes an optically active portion that is configured to be shaped over an air-membrane interface according to a spherical cap and Zernike polynomials, wherein the spherical cap and the Zernike polynomials comprise a Zernike[4,0], (Noll[11]) polynomial and are sufficient to model the membrane to within approximately 2 micrometers.

120. The optical apparatus of claim 119, wherein the Zernike polynomials further comprise a Zernike[0,0], (Noll[1]) polynomial.

121. The optical apparatus of claim 120, wherein the Zernike polynomials further comprise a Zernike[2,0], (Noll[4]) polynomial.

122. The optical apparatus of claim 118, wherein the membrane includes an optically active portion that is configured to be shaped according to a spherical cap and a Zernike[4,0], polynomial, the spherical cap having a spherical cap radius, and wherein a magnitude of the Zernike[4,0] polynomial depends upon the spherical cap radius.

123. The optical apparatus of claim 122, wherein the spherical cap and Zernike[4,0] polynomial are sufficient to model the membrane to within approximately 2 micrometers.

124. The optical apparatus of claim 123 wherein a rate of increase of a magnitude of the Zernike[4,0], (Noll[11]) polynomial depends upon a lens shaper edge diameter.

125. The optical apparatus of claim 116, wherein the first deformable optical lens includes a membrane, and the membrane is controlled to assume any non-spherical shape.

126. The optical apparatus of claim 116, wherein the first reflective surface is an element selected from the group consisting of a prism, a mirror, and an adaptive element.

127. The optical apparatus of claim 116, wherein the optical path is redirected at the first reflective surface at an angle of approximately 90 degrees.

128. The optical apparatus of claim 116, further comprising a second reflective surface, the second reflective surface being disposed at the end of the optical housing.

129. The optical apparatus of claim 116, wherein the first deformable lens comprises a first membrane and the second deformable lens comprises a second membrane, and the first membrane and the second membrane are configurable to assume a plurality of convex shapes and concave shapes.

130. An optical apparatus, the apparatus comprising:
an optical housing having an end;
a fixed lens;
a first deformable optical lens;
a second deformable optical lens;
at least one barrel, the at least barrel being disposed within the optical housing, the first deformable optical lens and the second deformable optical lens being disposed at least partially within the at least one barrel;
a first reflective surface, the reflective surface mounted to the optical housing;
a sensor disposed at the end of the optical housing;
a sensor axis passing through the sensor and an object axis being arranged in non-parallel relation to the other, the object axis and the sensor axis passing through the reflective surface;
an optical path disposed within the optical housing, the optical path following the object axis from an object external to the apparatus to the reflective surface, the optical path then following the sensor axis to the sensor at the end of the optical housing, the optical path passing through the deformable optical lens and the fixed lens.

131. The optical apparatus of claim 130, further comprising a first pump and a second pump, the first pump moving first fluid from a first reservoir into the first deformable optical lens, the second pump moving second fluid from a second reservoir to the second deformable optical lens.

132. The optical apparatus of claim 130, wherein the first deformable optical lens includes a membrane.

133. The optical apparatus of claim 132, wherein the membrane includes an optically active portion that is configured to be shapeable over an air-membrane interface according to a spherical cap and Zernike polynomials wherein the spherical cap and the Zernike polynomials comprise a Zernike[4,0], (Noll[11]) polynomial and are sufficient to model the membrane to within approximately 2 micrometers.

134. The optical apparatus of claim 133, wherein the Zernike polynomials further comprise a Zernike[0,0], (Noll[1]) polynomial.

135. The optical apparatus of claim 133, wherein the Zernike polynomials further comprise a Zernike[2,0], (Noll[4]) polynomial.

136. The optical apparatus of claim 132, wherein the membrane has an optically active portion that is configured to be shaped according to a spherical cap and a Zernike[4,0], polynomial the spherical cap having a spherical cap radius, and wherein a magnitude of the Zernike[4,0] polynomial depends upon the spherical cap radius.

137. The optical apparatus of claim 136, wherein the spherical cap and the Zernike[4,0] polynomial are sufficient to model the membrane to within approximately 2 micrometers.

138. The optical apparatus of claim 137, wherein a rate of increase of a magnitude of the Zernike[4,0], (Noll[11]) polynomial depends upon a lens shaper edge diameter.

139. The optical apparatus of claim 130, wherein the first deformable optical lens includes a membrane, and the membrane is controlled to assume any non-spherical shape.

140. The optical apparatus of claim 130, wherein the first reflective surface is an element selected from the group consisting of a prism, a mirror, and an adaptive element.

141. The optical apparatus of claim 130, wherein the optical path is redirected at the first reflective surface at an angle of approximately 90 degrees.

142. The optical apparatus of claim 130, further comprising a second reflective surface, the second reflective surface being disposed at the end of the optical housing.

143. The optical apparatus of claim 130, wherein the first deformable lens comprises a first membrane and the second deformable lens comprises a second membrane, and the first membrane and the second membrane are configurable to assume a plurality of convex shapes and concave shapes.

144. An optical apparatus, comprising:
an axis;
an optical portion including at least one deformable optical lens arranged about the axis;
a pump portion, the pump portion configured to actuate the at least one deformable lens, the pump portion arranged about the axis.

145. The optical apparatus of claim 144, wherein the pump portion is disposed on one side of the optical portion.

146. The optical apparatus of claim 144, wherein the pump portion comprises a first part and a second part, and optical portion is disposed between the first part and the second part.

147. An optical apparatus, the apparatus comprising:
a pump portion;
an optical portion, the optical portion comprising:
an optical housing;
a first deformable optical lens and a second deformable optical lens disposed within the optical housing;
a reflective surface disposed within the optical housing;
a sensor disposed at an end of the optical housing;
such that the pump portion is configured to cause a fluid exchange between at least one fluid reservoir and the first deformable optical lens and between the at least one fluid reservoir and the second deformable optical lens;
an axis, the pump portion and the optical portion arranged about the axis, such that the axis intersects portions of the pump.

148. The optical apparatus of claim 147, wherein the pump portion is disposed on one side of the optical portion.

149. The optical apparatus of claim 147, wherein the pump portion comprises a first part and a second part, and optical portion is disposed between the first part and the second part.

150. The optical apparatus of claim 147, wherein the at least one reservoir comprises a first reservoir and a second reservoir, and the first reservoir and the second reservoir being disposed in the same plane.

151. The optical apparatus of claim 147 wherein at least one fluid channel is formed and extends along a first side portion of the pump portion and a second side portion of the optical portion in a direction generally parallel to the axis, the at least one fluid channel being configured to allow exchange of fluid between the at least one reservoir and the first deformable lens, and between the at least one reservoir and the second deformable lens.

152. The optical apparatus of claim 151, wherein the at least one fluid channel is formed from a first material portion and a second material portion.

153. The optical apparatus of claim 152, wherein the first material portion comprises a different material from the second material portion.

154. The optical apparatus of claim 151, wherein the at least one fluid channel comprises a tube-like structure, the tube-like structure being constructed of a material that minimizes or eliminates the effects of thermal fluid expansion.

155. The optical apparatus of claim 147, wherein the at least one reservoir comprises a first reservoir and a second reservoir, and wherein a first movement of fluid from the first reservoir to the first deformable optical lens meets less fluid resistance than a second movement of fluid from the second reservoir to the second deformable optical lens.

156. An optical apparatus, the apparatus comprising:
a deformable optical lens with a first axis extending there through;
a fixed lens having a second axis extending there through;
a sensor with a third axis extending there through;
an optical path that follows along the first axis, the second axis, and the third axis;
wherein the first axis, the second axis, and the third axis are automatically aligned so as to improve an image quality of an image that follows the optical path to the sensor.

157. The optical apparatus of claim 156, wherein the first axis, the second axis, and the third axis are automatically aligned with an optical path of images.

158. The optical apparatus of claim 157, wherein the first axis, the second axis, and the third axis are automatically aligned in a direction radially outward from an optical path of images.

159. An optical apparatus, the apparatus comprising:
a deformable optical lens with a first axis extending there through;
a sensor with a second axis extending there through;
a fixed lens having a third axis extending there through;
an optical path that follows along the first axis and the second axis, a reflective surface being aligned with the first axis, the second axis, wherein one or more of the first axis, the second axis, and the third axis are automatically aligned so as to improve an image quality of an image that follows the optical path to the sensor.

160. The optical apparatus of claim 159, wherein angle between the first axis, and the second axis, is automatically varied to improve the image quality.

161. The optical apparatus of claim 160, wherein the third axis is automatically aligned in a direction radially outward from an optical path of images.

162. An optical apparatus, the apparatus comprising:
an optical housing with an end;
a solid lens disposed within the optical housing;
a deformable optical lens disposed within the optical housing;
a sensor coupled to the end of the optical housing;
a sensor axis passing through the sensor and an object axis being arranged at two times the angle of incidence of the sensor axis, the object axis and the sensor axis passing through the reflective surface;
such that at least one of the reflective surface, the sensor, solid lens, or the deformable optical lens are movable or adjustable so as to improve an image quality of an image that follows the optical path to the sensor.

163. The optical apparatus of claim 162, further comprising a barrel, the barrel being disposed within the optical housing, and the deformable optical lens being disposed at least partially within the barrel.

164. The optical apparatus of claim 163, further comprising a reflective surface, the reflective surface mounted to the optical housing.

165. The optical apparatus of claim 164, wherein the reflective surface comprises an element selected from the group consisting of a prism, a mirror, and an adaptive element.

166. The optical apparatus of claim 162, wherein an optical path is disposed within the optical housing, the optical path following the object axis from an object external to the apparatus to the reflective surface, the optical path being redirected at the reflective surface and then following the sensor axis to the sensor at the end of the optical housing, the optical path passing through the deformable optical lens and the fixed lens.

167. A pump, the pump comprising:
a magnetic circuit return structure having a central portion and an outer portion, the outer portion including a first wall portion and a second wall portion, the central portion disposed between the first wall portion and the second wall portion;
a first coil extending around a first portion of the central portion and a second coil extending around a second portion of the central portion;
a first magnet;
a second magnet;
a first actuator;
a second actuator;
such that a first electrical current applied to the first coil produces a first force to produce a first movement of the first actuator, the first movement of the first actuator communicating with a first deformable optical lens;
such that a second electrical current applied to the second coil produces a second force to produce a second movement of the second actuator, the second movement of the second actuator effective to move a second membrane that communicates with a second deformable optical lens.

168. The pump of claim 167, further comprising a first actuator seal that is effective to move a first membrane that communicates with the first deformable optical lens.

169. The pump of claim 168, wherein the actuator seal is an element selected from the group consisting of: a membrane, an accordion structure element, a diaphragm, and a channel opening that seals when the viscosity of the fluid is too great to flow through the seal.

170. The pump of claim 167, wherein the first actuator and the second actuator are piston-like structures.

171. The pump of claim 167, wherein the first actuator and the second actuator are generally circular in a plane parallel to the actuator seal.

172. The pump of claim 167, wherein the first magnet and the second magnet are polarized towards the central portion.

173. The pump of claim 167, wherein the first magnet and the second magnet are polarized away from the central portion.

174. The pump of claim 167, wherein the first magnet overhangs the first wall portion.

175. The pump of claim 167, wherein the first magnet is disposed between the first wall portion and the first coil, the first magnet also disposed between the first wall portion and the second coil and wherein the second magnet is disposed between the second wall portion and the first coil, the second magnet also disposed between the second wall portion and the second coil.

176. An optical apparatus, the apparatus comprising:
an optical housing with an end;
a fixed lens and a deformable optical lens;
a reflective surface, the reflective surface mounted to the optical housing;
a sensor disposed at the end of the optical housing;
a sensor axis passing through the sensor and the reflective surface, and an object axis being generally perpendicular to the sensor axis and passing through the reflective surface;
an optical path disposed within the optical housing, the optical path following the object axis from an object external to the apparatus to the reflective surface, the optical path being redirected at the reflective surface and then following the sensor axis to the sensor at the end of the optical housing, the optical path passing through the deformable optical lens and the fixed lens;
wherein the optical housing comprises:
a first portion, the first portion including a first interface at a first end of the first portion;
a second portion, the second portion being non-integral with the first portion and including a second interface at a second end of the second portion;
wherein the first interface couples and mates to the second interface such that an alignment of the first portion with respect to the second portion is achieved.

177. The optical apparatus of claim 176, wherein the reflective surface comprises an element selected from the group consisting of a prism, a mirror, and an adaptive element.

178. The optical apparatus of claim 176, wherein the optical path is redirected at the reflective surface at an angle of approximately 90 degrees.

179. The optical apparatus of claim 176, wherein the interface comprises a first flange on the first portion and a second flange on the second portion.

180. The optical apparatus of claim 176, wherein the interface comprises an alignment feature on the first portion.

181. The optical apparatus of claim 176, further comprising a barrel disposed within the first portion or the second portion.

182. The optical apparatus of claim 181 wherein the barrel holds the deformable optical lens.

183. The optical apparatus of claim 182 wherein the barrel holds the fixed lens.

184. An optical apparatus, the apparatus comprising:
an optical housing with an end;
a fixed lens and a deformable optical lens;
a reflective surface, the reflective surface mounted to the optical housing;
a sensor disposed at the end of the optical housing;
a sensor axis passing through the sensor and the reflective surface, and an object axis being arranged in non-parallel relation to the sensor axis and passing through the reflective surface;
an optical path disposed within the optical housing, the optical path following the object axis from an object external to the apparatus to the reflective surface, the optical path then following the sensor axis to the sensor at the end of the optical housing, the optical path passing through the deformable optical lens and the fixed lens;
wherein the optical housing comprises:
a first portion, the first portion including a first interface at a first end of the first portion;
a second portion, the second portion being non-integral with the first portion and including a second interface at a second end of the second portion;
wherein the first interface couples and mates to the second interface such that an alignment of the first portion with respect to the second portion is achieved.

185. The optical apparatus of claim 184, wherein the reflective surface comprises an element selected from the group consisting of a prism, a mirror, and an adaptive element.

186. The optical apparatus of claim 184, wherein the optical path is redirected at the reflective surface at an angle of approximately 90 degrees.

187. The optical apparatus of claim 184, wherein the second portion is disposed predominantly inside the first portion.

188. The optical apparatus of claim 184, wherein the interface comprises a first flange on the first portion and a second flange on the second portion.

189. The optical apparatus of claim 184, wherein the interface comprises an alignment feature on the first portion.

190. The optical apparatus of claim 184, further comprising a barrel disposed within the first portion or the second portion.

191. The optical apparatus of claim 184, wherein each of the first portion and the second portion includes a deformable optical lens.

192. The optical apparatus of claim 191 wherein the barrel holds the deformable optical lens.

193. The optical apparatus of claim 192 wherein the barrel holds the fixed lens.

194. An optical apparatus, the apparatus comprising:
a first deformable optical lens including a lens shaper,
a barrel, the barrel being disposed within the optical housing, the deformable optical lens being disposed at least partially within the barrel;
a first set of contact points disposed between the lens shaper and the barrel;
a second set of contact points disposed between the barrel and the optical housing;
wherein the first set of contact points is separated from the second set of contact points by a distance, and the distance is sufficient to allow for a mechanical stress or a thermal stress to be at last partially relieved.

195. The optical apparatus of claim 194 wherein the first set of contact points and the second set of contact points are disposed at a location, the location being selected from the group consisting of the barrel, the optical housing, and the barrel and the optical housing.

196. The optical apparatus of claim 194 wherein the distance is created by a difference in angular positions of elements.

197. The optical apparatus of claim 194 wherein the distance is created by a difference in axial positions of elements.

198. An optical apparatus, the apparatus comprising:
a deformable optical lens having a membrane and a lens shaper, a fluid and barrel, the lens shaper having a top surface, an inside surface, and an outside surface;
a well-defined lens shaper edge at the intersection of the inside surface, and the top surface;
wherein the lens shaper edge is generally in a plane;
with a deformable optical lens axis centered to the edge and normal to the plane;
wherein the inside surface of the lens shaper surrounds the deformable optical lens axis;
wherein the outside surface of the lens shaper surrounds the inside surface and the membrane is under tension and bonded to the top surface;
wherein an outside edge is formed by the top surface and the outside surface and the membrane is cut so that it is substantially inside the outside edge.

199. The optical apparatus of claim 198 wherein the lens shaper further includes a bottom surface, the bottom surface having an area that is less than the top surface of the lens shaper.

200. The optical apparatus of claim 198, wherein the inside surface is scalloped.

201. The optical apparatus of claim 198, wherein the largest diameter of the outside surface is at the outside edge.

202. The optical apparatus of claim 198, wherein the inside edge and the outside edge are concentric.

203. The optical apparatus of claim 198, wherein the outside surface is configured to align the barrel to the axis.

204. The optical apparatus of claim 198, wherein the membrane extends to the outside edge of the lens shaper, the membrane having a top surface and a bottom surface, the bottom surface of the membrane being bonded to the top surface of the lens shaper, the top surface of the membrane being of a smaller area than the bottom surface of the membrane.

205. The optical apparatus of claim 198, wherein the membrane is cut so that it does not reach the outer edge of the lens shaper.

206. The optical apparatus of claim 198, wherein the well-defined ledge shaper edge restrains the membrane as the fluid is pressurized and the membrane is deflected.

207. The optical apparatus of claim 206, wherein the deflected membrane is axisymmetric to the axis.
